(19) United States
(12) Patent Application Publication
(10) Pub. No.: US 2023/0247873 A1
(43) Pub. Date: Aug. 3, 2023

(54) DISPLAY APPARATUS, DISPLAY MODULE, AND ELECTRONIC DEVICE

(71) Applicant: SEMICONDUCTOR ENERGY LABORATORY CO., LTD., Atsugi-shi, Kanagawa-ken (JP)

(72) Inventors: Daisuke KUBOTA, Atsugi, Kanagawa (JP); Daiki NAKAMURA, Atsugi, Kanagawa (JP); Ryo HATSUMI, Hadano, Kanagawa (JP); Nozomu SUGISAWA, Isehara, Kanagawa (JP)

(21) Appl. No.: 18/012,513

(22) PCT Filed: Jun. 24, 2021
(86) PCT No.: PCT/IB2021/055589

§ 371 Date: Dec. 22, 2022

(30) Foreign Application Priority Data
Jul. 3, 2020 (JP) 2020-115385

(51) Int. Cl. H10K 59/131; H10K 59/123; H10K 59/65

(52) U.S. Cl. CPC H10K 59/131; H10K 59/123; H10K 59/65; H10K 59/40

(57) ABSTRACT

A display apparatus that has a light sensing function is provided. A display apparatus that has high light sensitivity is provided. The display apparatus includes a light-receiving element, a light-emitting element, a conductive layer, and a first wiring. The light-receiving element includes a first pixel electrode, a common layer, an active layer, and a common electrode. The light-emitting element includes a second pixel electrode, the common layer, a light-emitting layer, and the common electrode. The conductive layer is provided over the same surface as the first pixel electrode and the second pixel electrode, is positioned between the first pixel electrode and the second pixel electrode, is electrically connected to the common layer, and is electrically connected to the first wiring to which a first potential is supplied. The common layer includes a portion overlapping with the first pixel electrode, a portion overlapping with the second pixel electrode, and a portion overlapping with the conductive layer. The common electrode includes a portion overlapping with the first pixel electrode and a portion overlapping with the second pixel electrode. The first wiring is provided over a surface different from the surface where the conductive layer is provided.

### TECHNICAL FIELD

One embodiment of the present invention relates to a display apparatus, a display module, and an electronic device. One embodiment of the present invention relates to a display apparatus that includes a light-emitting element (also referred to as a light-emitting device) and a light-receiving element (also referred to as a light-receiving device). One embodiment of the present invention relates to a display apparatus that has an authentication function. One embodiment of the present invention relates to a touch panel. One embodiment of the present invention relates to a system that includes a display apparatus.

Note that one embodiment of the present invention is not limited to the above technical field. Examples of the technical field of one embodiment of the present invention disclosed in this specification and the like include a semiconductor device, a display apparatus, a light-emitting apparatus, a power storage device, a memory device, an electronic device, a lighting device, an input device, an input/output device, an imaging apparatus, a driving method thereof, and a manufacturing method thereof. A semiconductor device refers to any device that can function by utilizing semiconductor characteristics.

### BACKGROUND ART

In recent years, display apparatuses have been expected to be applied to a variety of uses. Examples of uses for a large display apparatus include a television device for home use (also referred to as a TV or a television receiver), digital signage, and a PID (Public Information Display). In addition, a smartphone and a tablet terminal including a touch panel are being developed as portable information terminals.

Light-emitting apparatuses including light-emitting elements have been developed, for example, as display apparatuses. Light-emitting elements (also referred to as EL elements) utilizing an electroluminescence (hereinafter referred to as EL) phenomenon have features such as ease of reduction in thickness and weight, high-speed response to an input signal, and driving with a direct-constant voltage source, and have been used in display apparatuses. For example, Patent Document 1 discloses a flexible light-emitting apparatus including an organic EL element.

### REFERENCE

### Patent Document

### [Patent Document 1] Japanese Published Patent Application No. 2014-197522

### SUMMARY OF THE INVENTION

### Problems to be Solved by the Invention

An object of one embodiment of the present invention is to provide a display apparatus that has a light sensing function. Another object is to provide a display apparatus that has a light sensing function and high reliability. Another object is to provide a multifunctional display apparatus. Another object is to provide a display apparatus that has high display quality. Another object is to provide a display apparatus with high light sensitivity. Another object is to provide a novel display apparatus.

Another object of one embodiment of the present invention is to provide a display apparatus that has high light sensing accuracy. Another object is to provide a display apparatus that is capable of capturing a clear image. Another object is to provide a display apparatus that functions as a touch panel.

Note that the description of these objects does not preclude the existence of other objects. One embodiment of the present invention does not need to achieve all these objects. Objects other than these can be derived from the description of the specification, the drawings, the claims, and the like.

### Means for Solving the Problems

One embodiment of the present invention is a display apparatus that includes a light-receiving element, a light-emitting element, a conductive layer, and a first wiring. The light-receiving element includes a first pixel electrode, a common layer over the first pixel electrode, an active layer over the common layer, and a common electrode over the active layer. The light-emitting element includes a second pixel electrode, the common layer over the second pixel electrode, a light-emitting layer over the common layer, and the common electrode over the light-emitting layer. The conductive layer is provided over the same surface as the first pixel electrode and the second pixel electrode, is positioned between the first pixel electrode and the second pixel electrode, is electrically connected to the common layer, and is electrically connected to the first wiring to which a first potential is supplied. The common layer includes a portion overlapping with the first pixel electrode, a portion overlapping with the second pixel electrode, and a portion overlapping with the conductive layer. The common electrode includes a portion overlapping with the first pixel electrode and a portion overlapping with the second pixel electrode. The first wiring is provided over a surface different from the surface where the conductive layer is provided.

In the above, a first transistor and a second transistor are preferably included. The first pixel electrode is preferably supplied with a second potential lower than or equal to the first potential through the first transistor. The second pixel electrode is preferably supplied with a third potential higher than or equal to the first potential through the second transistor. Furthermore, the common electrode is preferably supplied with the first potential.

In the above, the first pixel electrode is preferably supplied with a fourth potential higher than or equal to the first potential through the first transistor. The second pixel electrode is preferably supplied with a fifth potential higher than or equal to the first potential through the second transistor. The fifth potential is preferably higher than the fourth potential.

In the above, the conductive layer preferably includes a first portion with a ring shape. In that case, the first pixel electrode is preferably positioned inside the first portion when seen from above. Alternatively, the second pixel electrode is preferably positioned inside the first portion.

In the above, when a plurality of the first pixel electrodes and a plurality of the second pixel electrodes are included, the conductive layer preferably includes a first portion with a ring shape, a second portion with a ring shape, and a third portion. In that case, one of the plurality of the first pixel electrodes is preferably positioned inside the first portion when seen from above. Another of the plurality of the first pixel electrodes is preferably positioned inside the second portion when seen from above. The third portion is preferably positioned between the first portion and the second portion when seen from above. Alternatively, one of the plurality of the second pixel electrodes is preferably positioned inside the first portion when seen from above. Another of the plurality of the second pixel electrodes is preferably positioned inside the second portion when seen from above. The third portion is preferably positioned between the first portion and the second portion when seen from above.

In the above, when a plurality of the first pixel electrodes and a plurality of the second pixel electrodes are included, the plurality of the first pixel electrodes are preferably arranged in a first direction and the plurality of the second pixel electrodes are preferably arranged in the first direction. The conductive layer is extended in the first direction and preferably includes portions positioned between the plurality of the first pixel electrodes and the plurality of the second pixel electrodes.

In the above, a display region and a non-display region are preferably included. The plurality of the first pixel electrodes and the plurality of the second pixel electrodes are preferably provided in the display region. In that case, the conductive layer is preferably provided across the display region and the non-display region and is preferably electrically connected to the first wiring in the non-display region. It is further preferable that the conductive layer be electrically connected to the first wiring in the display region. Alternatively, the conductive layer is preferably provided in the display region and is preferably electrically connected to the first wiring in the display region.

In the above, the first wiring preferably includes a portion overlapping with the first pixel electrode and a portion overlapping with the second pixel electrode. Alternatively, the first wiring preferably includes a portion positioned between the first pixel electrode and the second pixel electrode.

One embodiment of the present invention is a module that includes the display apparatus having any of the above structures. Examples of the module include a module provided with a connector such as a flexible printed circuit (hereinafter referred to as an FPC) or a TCP (Tape Carrier Package) or a module mounted with an integrated circuit (IC) by a COG (Chip On Glass) method, a COF (Chip On Film) method, or the like.

One embodiment of the present invention is an electronic device including the above-described module and at least one of an antenna, a battery, a housing, a camera, a speaker, a microphone, and an operation button.

### Effect of the Invention

According to one embodiment of the present invention, a display apparatus that has a light sensing function can be provided. Alternatively, a display apparatus that has a light sensing function and high reliability can be provided. Alternatively, multifunctional display apparatus can be provided. Alternatively, a display apparatus that has high display quality can be provided. Alternatively, a display apparatus that has high light sensitivity can be provided. Alternatively, a novel display apparatus can be provided.

According to one embodiment of the present invention, a display apparatus that has high light sensing accuracy can be provided. Alternatively, a display apparatus that can capture a clear image can be provided. Alternatively, a display apparatus that functions as a touch panel can be provided.

Note that the description of these effects does not preclude the existence of other effects. One embodiment of the present invention does not need to have all these effects. Effects other than these can be derived from the description of the specification, the drawings, the claims, and the like.

### BRIEF DESCRIPTION OF THE DRAWINGS

FIG. 1A and FIG. 1B are diagrams showing structure examples of display apparatuses.

FIG. 2A is a schematic diagram showing the relation between voltage and current density. FIG. 2B is a diagram illustrating potentials to be supplied to a display apparatus.

FIG. 3A to FIG. 3D are diagrams showing structure examples of display apparatuses.

FIG. 4A to FIG. 4C are diagrams showing structure examples of display apparatuses.

FIG. 5A and FIG. 5B are diagrams showing structure examples of display apparatuses.

FIG. 6A to FIG. 6C are diagrams showing structure examples of display apparatuses.

FIG. 7A and FIG. 7B are diagrams showing structure examples of display apparatuses.

FIG. 8A is a diagram showing a structure example of a display apparatus. FIG. 8B is a cross-sectional view showing a structure example of the display apparatus.

FIG. 9A and FIG. 9B are diagrams showing structure examples of display apparatuses.

FIG. 10A and FIG. 10B are cross-sectional views showing structure examples of display apparatuses.

FIG. 11A and FIG. 11B are cross-sectional views showing structure examples of display apparatuses.

FIG. 12 is a diagram showing a structure example of a display apparatus.

FIG. 13A and FIG. 13B are diagrams showing structure examples of display apparatuses.

FIG. 14A, FIG. 14B, and FIG. 14D are cross-sectional views each showing an example of a display apparatus. FIG. 14C and FIG. 14E are diagrams showing examples of images captured by the display apparatuses. FIG. 14F to FIG. 14H are top views showing examples of pixels.

FIG. 15A is a cross-sectional view showing a structure example of a display apparatus. FIG. 15B to FIG. 15D are top views showing examples of pixels.

FIG. 16A is a cross-sectional view showing a structure example of a display apparatus. FIG. 16B to FIG. 16I are top views showing examples of pixels.

FIG. 17A and FIG. 17B are diagrams showing structure examples of display apparatuses.

FIG. 18A to FIG. 18G are diagrams showing structure examples of display apparatuses.

FIG. 19A to FIG. 19C are diagrams showing structure examples of display apparatuses.

FIG. 20A and FIG. 20B are diagrams showing structure examples of display apparatuses.

FIG. 21A and FIG. 21B are diagrams showing structure examples of display apparatuses.

FIG. 22 is a diagram showing a structure example of a display apparatus.

FIG. 23A is a diagram showing a structure example of a display apparatus. FIG. 23B and FIG. 23C are diagrams showing structure examples of transistors.

FIG. 24A and FIG. 24B are diagrams showing structure examples of pixels. FIG. 24C to FIG. 24E are diagrams showing structure examples of pixel circuits.

FIG. 25A and FIG. 25B are diagrams showing structure examples of electronic devices.

FIG. 26A to FIG. 26D are diagrams showing structure examples of electronic devices.

FIG. 27A to FIG. 27F are diagrams showing structure examples of electronic devices.

### MODE FOR CARRYING OUT THE INVENTION

Hereinafter, embodiments will be described with reference to the drawings. Note that the embodiments can be implemented in many different modes, and it is readily understood by those skilled in the art that modes and details thereof can be changed in various ways without departing from the spirit and scope thereof. Thus, the present invention should not be construed as being limited to the following description of the embodiments.

Note that in structures of the invention described below, the same portions or portions having similar functions are denoted by the same reference numerals in different drawings, and the description thereof is not repeated. Furthermore, the same hatch pattern is used for the portions having similar functions, and the portions are not especially denoted by reference numerals in some cases.

Note that in each drawing described in this specification, the size, the layer thickness, or the region of each component is exaggerated for clarity in some cases. Therefore, the size, the layer thickness, or the region is not necessarily limited to the illustrated scale.

Note that in this specification and the like, the ordinal numbers such as “first” and “second” are used in order to avoid confusion among components and do not limit the number.

In this specification and the like, a display panel that is one embodiment of a display apparatus has a function of displaying (outputting) an image or the like on (to) a display surface. Therefore, the display panel is one embodiment of an output device.

In this specification and the like, a substrate of a display panel to which a connector such as an FPC (Flexible Printed Circuit) or a TCP (Tape Carrier Package) is attached, or a substrate on which an IC is mounted by a COG (Chip On Glass) method or the like is referred to as a display panel module, a display module, or simply a display panel or the like in some cases.

Note that in this specification and the like, a touch panel that is one embodiment of a display apparatus has a function of displaying an image or the like on a display surface and a function of a touch sensor that senses the contact, press, approach, or the like of a sensing target such as a finger or a stylus with or to the display surface. Thus, the touch panel is one embodiment of an input/output device.

A touch panel can be referred to as, for example, a display panel (or a display apparatus) with a touch sensor, or a display panel (or a display apparatus) having a touch sensor function. A touch panel can include a display panel and a touch sensor panel. Alternatively, a touch panel can have a function of a touch sensor in the display panel or on the surface of the display panel.

In this specification and the like, a substrate of a touch panel on which a connector, an IC, or the like is mounted is referred to as a touch panel module, a display module, or simply a touch panel or the like in some cases.

### Embodiment 1

In this embodiment, structure examples of embodiments of the present invention will be described.

A device of one embodiment of the present invention includes a plurality of light-receiving elements and a plurality of light-emitting elements. The light-receiving element functions as a photoelectric conversion element that senses light incident on the light-receiving element and generates charge.

The device of one embodiment of the present invention is capable of performing imaging with the plurality of light-receiving elements and thus functions as an imaging apparatus. In this case, the light-emitting elements can be used as a light source for imaging. Moreover, one embodiment of the present invention is capable of displaying an image with the plurality of light-emitting elements and thus functions as a display apparatus. Accordingly, one embodiment of the present invention can be regarded as a display apparatus that has an imaging function or an imaging apparatus that has a display function.

For example, in the display apparatus of one embodiment of the present invention, light-emitting elements are arranged in a matrix in a display portion, and light-receiving elements are also arranged in a matrix in the display portion. Hence, the display portion has a function of displaying an image and a function of a light-receiving portion. An image can be captured with the plurality of light-receiving elements provided in the display portion, so that the display apparatus can function as an image sensor, a touch panel, or the like. That is, the display portion can capture an image and sense an object approaching or touching, for example. For example, the display apparatus can be used as an image scanner. Furthermore, since the light-emitting elements provided in the display portion can be used as a light source at the time of receiving light, a light source does not need to be provided separately from the display apparatus; thus, a highly functional display apparatus can be provided without increasing the number of electronic components.

In the display apparatus of one embodiment of the present invention, when an object reflects (or scatters) not only external light but also light emitted by the light-emitting element included in the display portion, the light-receiving element can sense the reflected light (or the scattered light); thus, imaging, sensing of touch operation (including hover touch operation), and the like are possible even in a dark place.

Furthermore, when a finger, a palm, or the like touches the display portion in the display apparatus of one embodiment of the present invention, an image of the fingerprint or the palm print can be captured. Thus, an electronic device including the display apparatus of one embodiment of the present invention can perform personal authentication by using the captured image of the fingerprint, the palm print, or the like. Accordingly, an imaging apparatus for fingerprint authentication, palm-print authentication, or the like does not need to be additionally provided, and the number of components of the electronic device can be reduced. Since the light-receiving elements are arranged in a matrix in the display portion, an image of a fingerprint, a palm print, or the like can be captured in any position in the display portion, which can provide a highly convenient electronic device.

As the light-emitting element, an EL element such as an OLED (Organic Light Emitting Diode) or a QLED (Quantum-dot Light Emitting Diode) is preferably used. Examples of a light-emitting substance contained in the EL element include a substance exhibiting fluorescence (a fluorescent material), a substance exhibiting phosphorescence (a phosphorescent material), a substance exhibiting thermally activated delayed fluorescence (a thermally activated delayed fluorescence (TADF) material), and an inorganic compound (such as a quantum dot material).

As the light-receiving element, a pn photodiode or a pin photodiode can be used, for example. The light-receiving element functions as a photoelectric conversion element that senses light incident on the light-receiving element and generates charge. The amount of generated charge in the photoelectric conversion element is determined depending on the amount of incident light. It is particularly preferable to use an organic photodiode including a layer containing an organic compound as the light-receiving element. An organic photodiode, which is easily made thin, lightweight, and large in area and has a high degree of freedom for shape and design, can be used in a variety of display apparatuses.

An organic compound is preferably used for an active layer of the light-receiving element. In that case, it is preferable that one electrode of the light-emitting element and one electrode of the light-receiving element (the electrodes are also referred to as pixel electrodes) be provided over the same surface. It is further preferable that the other electrode of the light-emitting element and the other electrode of the light-receiving element be an electrode (also referred to as a common electrode) formed using continuous (one) conductive layer. It is still further preferable that the light-emitting element and the light-receiving element include a common layer. The common layer is shared by the light-emitting element and the light-receiving element. It is further preferable that the common layer be provided continuously (be provided as one layer) across the light-emitting element and the light-receiving element.

For example, at least one of a hole-injection layer, a hole-transport layer, an electron-transport layer, and an electron-injection layer is preferably a layer shared by the light-receiving element and the light-emitting element. As another example, the light-receiving element and the light-emitting element can have the same structure except that the light-receiving element includes an active layer and the light-emitting element includes a light-emitting layer. In other words, the light-receiving element can be manufactured by only replacing the light-emitting layer of the light-emitting element with an active layer. When the light-receiving element and the light-emitting element include a common layer in such a manner, the number of film formation steps and the number of masks can be reduced, thereby reducing the number of manufacturing steps and the manufacturing cost of the display apparatus. Furthermore, the display apparatus including the light-receiving element can be manufactured using an existing manufacturing apparatus and an existing manufacturing method for the display apparatus.

By contrast, in the case where a common layer is provided between the pixel electrode (also referred to as a first pixel electrode) of the light-receiving element and the active layer thereof and between the pixel electrode (also referred to as a second pixel electrode) of the light-emitting element and the light-emitting layer thereof and where the light-emitting element and the light-receiving element include a common electrode, a difference between potentials supplied to the pixel electrodes might cause a current flowing from the second pixel electrode to the first pixel electrode through the common layer. Such a current flowing between the pixel electrodes through the common layer is hereinafter referred to as a side leakage current. Since the light-receiving element converts received light into an electric signal and outputs the electric signal, the side leakage current ends up as noise of the light-receiving element, causing a reduction in an S/N ratio (Signal-to-Noise ratio). Thus, a clear image cannot be captured because of the side leakage current in some cases. Accordingly, the side leakage current is preferably suppressed while providing the common layer to reduce the number of times of separate formation.

The light-emitting element and the light-receiving element each have diode characteristics. A forward bias voltage is applied to the light-emitting element, whereby a current flows and light is emitted. By contrast, a reverse bias voltage is applied to the light-receiving element, whereby charge corresponding to the intensity of received light is generated by photoelectric conversion. Therefore, in the case where the common electrode is shared by the light-emitting element and the light-receiving element, one of the potential supplied to the first pixel electrode for photoelectric conversion in the light-receiving element and the potential supplied to the second pixel electrode for light emission of the light-emitting element is higher and the other is lower than the potential supplied to the common electrode, causing a large potential difference in some cases. This potential difference might cause a side leakage current between the first pixel electrode and the second pixel electrode.

For example, in the case where the common electrode serves as a cathode of the light-receiving element and the light-emitting element, a potential lower than that supplied to the common electrode is supplied to the first pixel electrode of the light-receiving element, and a potential higher than that supplied to the common electrode is supplied to the second pixel electrode of the light-emitting element. In this case, a side leakage current flows from the second pixel electrode to the first pixel electrode through the common layer. Note that different transistors are preferably connected to the pixel electrodes. In that case, a given potential can be supplied to the pixel electrodes through the transistors.

In view of the above, in one embodiment of the present invention, a conductive layer electrically connected to the common layer is provided between the first pixel electrode and the second pixel electrode. The conductive layer is positioned on the path of a side leakage current flowing from the second pixel electrode to the first pixel electrode so that the side leakage current flows into the conductive layer. This can block the side leakage current.

The conductive layer is preferably provided over the same surface as the first pixel electrode and the second pixel electrode. The conductive layer is electrically connected to a wiring (also referred to as a first wiring) and is preferably supplied with a first potential through the wiring. By setting the first potential lower than the potential supplied to the second pixel electrode, the side leakage current flowing from a second pixel to a first pixel can flow into the conductive layer. As a results, the side leakage current can be effectively suppressed, noise of the light-receiving element can be reduced, and the sensing accuracy can be increased.

The first potential is preferably closer to the potential supplied to the first pixel electrode. In that case, a potential difference between the first pixel electrode and the conductive layer can be reduced, so that the side leakage current flowing through the common layer between the first pixel electrode and the conductive layer can be sufficiently reduced. Furthermore, the common electrode is preferably supplied with the same first potential as the conductive layer. In that case, one circuit can supply potentials to the common electrode and the conductive layer, resulting in a simplified circuit structure.

The conductive layer is provided between the first pixel electrode and the second pixel electrode when seen from above. Specifically, the conductive layer can be provided on the shortest straight line connecting the first pixel electrode and the second pixel electrode. In the case where the common layer that causes a side leakage current is ideally uniform, the side leakage current is likely to flow along the shortest straight line connecting the pixel electrodes. Thus, by providing the conductive layer in such a position, the side leakage current that might flow between the first pixel electrode and the second pixel electrode can be effectively blocked.

It is preferable that the conductive layer have a ring-shaped portion and the first pixel electrode be positioned inside the ring-shaped portion. It is further preferable that the conductive layer be electrically connected to the wiring in the display portion. With this structure, the first pixel electrode is surrounded by the conductive layer, so that a current path from the second pixel electrode can be blocked by the conductive layer. Accordingly, the side leakage current can be effectively suppressed. The conductive layer may have a first portion with a ring shape, a second portion with a ring shape, and a third portion, and the third portion may be positioned between the first and second portions with the ring shapes. In that case, one of a plurality of the first pixel electrodes may be positioned inside the first portion and another may be positioned inside the second portion. In addition, the conductive layer is preferably provided in the display portion or across the display portion and a non-display portion and is preferably electrically connected to the wiring in the display portion or the non-display portion. With this structure, the first pixel electrode is surrounded by the conductive layer, so that the side leakage current can be effectively suppressed as described above. Furthermore, the number of wirings in the display portion can be reduced, resulting in miniaturized pixels.

Note that the first pixel electrode positioned inside the ring-shaped conductive layer may be replaced with the second pixel electrode. In that case, the second pixel electrode is surrounded by the conductive layer, so that a current path from the second pixel electrode can be blocked by the conductive layer. Accordingly, a side leakage current can be effectively suppressed.

In one embodiment of the present invention, the plurality of first pixel electrodes and the plurality of second pixel electrodes are provided and the pixel electrodes are arranged in a first direction. It is preferable that the conductive layer be extended in the first direction to be provided between the plurality of first pixel electrodes and the plurality of second pixel electrodes. The conductive layer is preferably electrically connected to the wiring in the display portion or the non-display portion. With these structures, the plurality of first pixel electrodes and the plurality of second pixel electrodes can be separated by one continuous conductive layer, resulting in a simplified layout on the substrate.

A conductive material with high conductivity is preferably used for the conductive layer. The same material can be used for the conductive layer and the pixel electrodes. The conductive layer, the first pixel electrode, and the second pixel electrode are formed using the same film in the same step, whereby the manufacturing process can be simplified. A conductive material with high visible light reflectance and high conductivity such as aluminum or silver is preferably used for the conductive layer, the first pixel electrode, and the second pixel electrode. Alternatively, an alloy containing aluminum and one or more selected from titanium, neodymium, nickel, and lanthanum can be used. Further alternatively, an alloy containing silver and one or more selected from yttrium, magnesium, ytterbium, aluminum, titanium, gallium, zinc, indium, tungsten, manganese, tin, iron, nickel, copper, palladium, iridium, and gold may be used.

The wiring is provided over a surface different from the surface where the conductive layer is provided. Examples of conductive materials that can be used for the wiring include metals such as aluminum, titanium, chromium, nickel, copper, yttrium, zirconium, molybdenum, silver, tantalum, and tungsten, and an alloy containing any of these metals as its main component.

The wiring can have a single-layer or stacked-layer structure of a film containing any of these materials.

The display apparatus of one embodiment of the present invention will be specifically described below with reference to drawings.

### [Structure Example 1 of Display Apparatus]

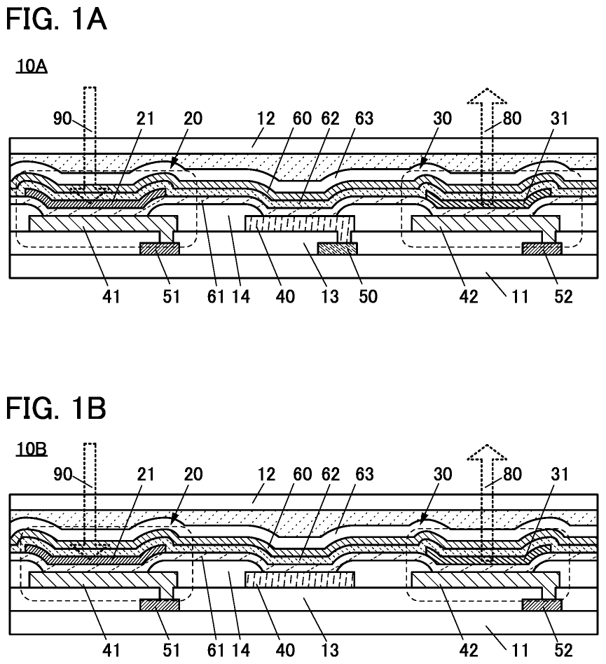

FIG. 1A is a cross-sectional schematic diagram of a display portion of a display apparatus 10A of one embodiment of the present invention.

The display apparatus 10A includes a light-receiving element 20, a light-emitting element 30, a conductive layer 40, a wiring 50, and the like.

The light-receiving element 20, the light-emitting element 30, and the conductive layer 40 are provided over the same surface between a substrate 11 and a substrate 12. The light-receiving element 20, the light-emitting element 30, and the conductive layer 40 are each positioned over an insulating layer 13. The wiring 50 is provided over the substrate 11 and is provided over a surface different from the surface where the light-receiving element 20, the light-emitting element 30, and the conductive layer 40 are provided. As shown in FIG. 1A, the wiring 50 is preferably provided below the light-receiving element 20, the light-emitting element 30, and the conductive layer 40 (on the substrate 11 side).

The light-receiving element 20 has a function of receiving light 90 incident from the substrate 12 side and converting the light 90 into an electric signal. The light-receiving element 20 functions as a photoelectric conversion element.

The light-receiving element 20 has a structure in which a pixel electrode 41, a common layer 61, a light-receiving layer 21, and a common electrode 60 are stacked. In addition, a transistor 51 electrically connected to the pixel electrode 41 is preferably provided over the substrate 11. The pixel electrode 41 is electrically connected to a source or a drain of the transistor 51 through an opening provided in the insulating layer 13. A common layer 62 is preferably provided between the light-receiving layer 21 and the common electrode 60. Furthermore, the common electrode 60 is preferably covered with a protective layer 63.

The light-emitting element 30 has a function of emitting light 80 to the substrate 12 side.

The light-emitting element 30 has a structure in which a pixel electrode 42, the common layer 61, a light-emitting layer 31, and the common electrode 60 are stacked. In addition, a transistor 52 electrically connected to the pixel electrode 42 is preferably provided over the substrate 11. The pixel electrode 42 is electrically connected to a source or a drain of the transistor 52 through an opening provided in the insulating layer 13. In addition, the common layer 62 is preferably provided between the light-emitting layer 31 and the common electrode 60. Furthermore, the common electrode 60 is preferably covered with the protective layer 63.

The light-emitting element 30 can be a light-emitting element that emits light of any one of red (R), green (G), and blue (B), for example. Alternatively, the light-emitting element 30 may be a light-emitting element that emits light of white (W), yellow (Y), or the like. The emission spectrum of the light-emitting element 30 may have two or more peaks.

The conductive layer 40 has a function of preventing a side leakage current from flowing into the pixel electrode 41. The conductive layer 40 is electrically connected to the common layer 61. The common layer 61 and the common electrode 60 are stacked over the conductive layer 40. The conductive layer 40 is electrically connected to the wiring 50 in a display portion or a non-display portion to be supplied with the first potential. As described above, the wiring 50 is provided over the substrate 11 and is provided over a surface different from the surface where the light-receiving element 20, the light-emitting element 30, and the conductive layer 40 are provided.

A partition 14 has a function of electrically isolating (separating) the pixel electrode 41, the pixel electrode 42, and the conductive layer 40 from one another. End portions of the pixel electrode 41, the pixel electrode 42, and the conductive layer 40 are covered with the partition 14.

An organic insulating film is suitable for the partition 14. Examples of materials that can be used for the organic insulating film include an acrylic resin, a polyimide resin, an epoxy resin, a polyamide resin, a polyimide-amide resin, a siloxane resin, a benzocyclobutene-based resin, a phenol resin, and precursors of these resins. The partition 14 is a layer that transmits visible light. A partition that blocks visible light may be provided instead of the partition 14.

Here, the pixel electrode 41, the pixel electrode 42, and the conductive layer 40 are preferably formed by processing the same conductive film. The common layer 61 includes portions overlapping with the pixel electrode 41, the pixel electrode 42, and the conductive layer 40. The common layer 62 and the common electrode 60 include a portion overlapping with the pixel electrode 41 with the light-receiving layer 21 and the common layer 61 therebetween, a portion overlapping with the pixel electrode 42 with the light-emitting layer 31 and the common layer 61 therebetween, and a portion overlapping with the conductive layer 40 with the common layer 61 therebetween. With such a structure, components of the light-receiving element 20 and the light-emitting element 30 other than the light-receiving layer 21 and the light-emitting layer 31 can be manufactured through common steps, so that the manufacturing cost can be reduced.

FIG. 1B is a cross-sectional view of a display portion of a display apparatus 10B. As shown in FIG. 1B, the wiring 50 is not necessarily provided in the display portion.

The wiring 50 is preferably formed using the same conductive film as the electrodes included in the transistor 51 and the transistor 52. For example, the wiring 50 is preferably formed by processing the same conductive film as gate electrodes, back gate electrodes, source electrodes, or drain electrodes of the transistor 51 and the transistor 52, other electrodes, or wirings. In that case, the wiring 50 can be formed without an increase in the number of steps.

### [Setting of Potential]

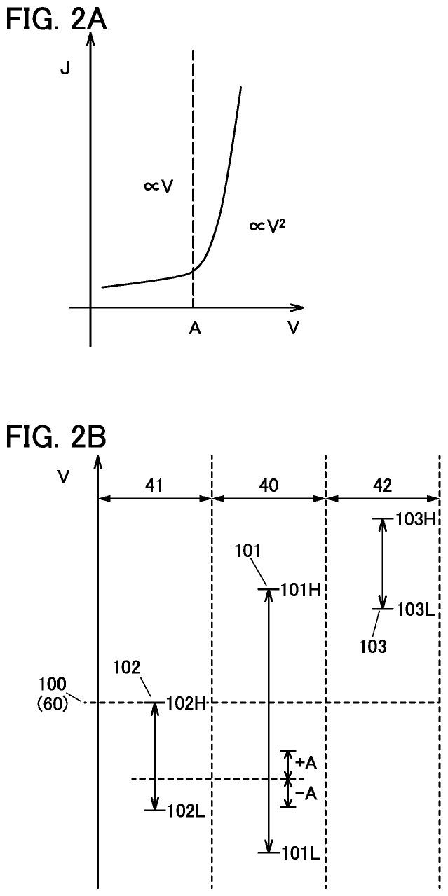

As described above, a difference between potentials supplied to the pixel electrode 41 and the pixel electrode 42 might cause a side leakage current flowing from the pixel electrode 42 to the pixel electrode 41 through the common layer 61. Here, FIG. 2A schematically shows the relation between current density (J) of a current flowing through an organic thin film and voltage (V). At a voltage lower than a voltage A, an ohmic current (current flowing mainly according to Ohm's law) proportional to the voltage flows, whereas at a voltage above the voltage A, a current proportional to the square of the voltage flows according to Langmuir-Child law. Since an organic thin film used as the common layer 61 has a low carrier density, the current flowing through the layer has voltage dependence as shown in FIG. 2A. The light-receiving element is driven with a negative bias voltage and the light-emitting element is driven with a positive bias voltage; thus, the potentials supplied to the pixel electrodes have an extremely large difference and Langmuir-Child law is applied in some cases to a side leakage current flowing between the pixel electrodes through the common layer 61. In other words, a large amount of side leakage current might be generated between the pixel electrode 41 and the pixel electrode 42.

In view of the above, in one embodiment of the present invention, the conductive layer 40 is provided between the pixel electrode 41 and the pixel electrode 42. By supplying an appropriate potential to the conductive layer 40, a side leakage current generated between the pixel electrode 41 and the pixel electrode 42 can be made to flow through the conductive layer 40.

In that case, the potential of the conductive layer 40 is set such that a side leakage current generated between the pixel electrode 41 and the conductive layer 40 is extremely small compared to the side leakage current that might be generated between the pixel electrode 41 and the pixel electrode 42. According to FIG. 2A, by setting a potential difference between the pixel electrode 41 of the light-receiving element 20 and the conductive layer 40 to the voltage A or lower, the amount of side leakage current between the pixel electrode 41 and the conductive layer 40 can be within the range of ohmic current. Thus, the side leakage current can be effectively suppressed.

The voltage A can be estimated by measuring current-voltage characteristics between the pixel electrode 41 and the conductive layer 40. For example, the voltage A is a value determined by a material of the common layer 61, a stacked-layer structure of the common layer 61, the thickness of the common layer 61, or the distance between two electrodes.

FIG. 2B is a schematic diagram showing examples of potentials supplied to the pixel electrode 41, the pixel electrode 42, and the conductive layer 40. In FIG. 2B, the vertical axis represents the potential (V) and vertical arrows indicate the ranges of potentials that each pixel electrode, the conductive layer 40, and the like can have.

A potential 100 is supplied to the common electrode 60. A potential 101 can be supplied to the conductive layer 40 and can take values from a potential 101L to a potential 101H. A potential 102 can be supplied to the pixel electrode 41 of the light-receiving element 20 and can take values from a potential 102L to a potential 102H. A potential 103 can be supplied to the pixel electrode 42 of the light-emitting element 30 and can take values from a potential 103L to a potential 103H.

To drive the light-receiving element 20 with a reverse bias voltage, the potential 102H is set to the potential 100 or lower when the common electrode 60 is a cathode. To drive the light-emitting element 30 with a forward bias voltage, the potential 103L is set to the potential 100 or higher. To suppress a side leakage current flowing from the pixel electrode 42 to the pixel electrode 41, the potential 101H is set to the potential 103H or lower. With such a structure, a side leakage current flowing from the conductive layer 40 to the pixel electrode 41 can be smaller than a side leakage current flowing from the pixel electrode 42 to the pixel electrode 41 in the case where the conductive layer 40 is not provided. In other words, the side leakage current flowing from the pixel electrode 42 to the pixel electrode 41 can be blocked by the conductive layer 40.

Furthermore, the potential 101 supplied to the conductive layer 40 is preferably equal to the potential 100. By setting potentials supplied to the common electrode 60 and the conductive layer 40 to be equal to each other, the number of circuits for generating potentials can be reduced. The potential 101 supplied to the conductive layer 40 is further preferably set within the range of ±A of the potential 102. Within this range, a side leakage current flowing to the first pixel electrode can be kept within the range of ohmic current. Consequently, noise of the light-receiving element can be effectively reduced, which leads to clear imaging.

### [Arrangement of Pixel Electrodes and Conductive Layer]

As described above, an image can be captured with a plurality of light-receiving elements in one embodiment of the present invention. Furthermore, an image can be displayed with a plurality of light-emitting elements. Light-emitting elements of three colors, e.g., red (R), green (G), and blue (B), are arranged in one pixel included in a display apparatus, whereby a full-color display apparatus can be obtained. An example of arrangement of pixel electrodes and a conductive layer included in a display apparatus will be described below.

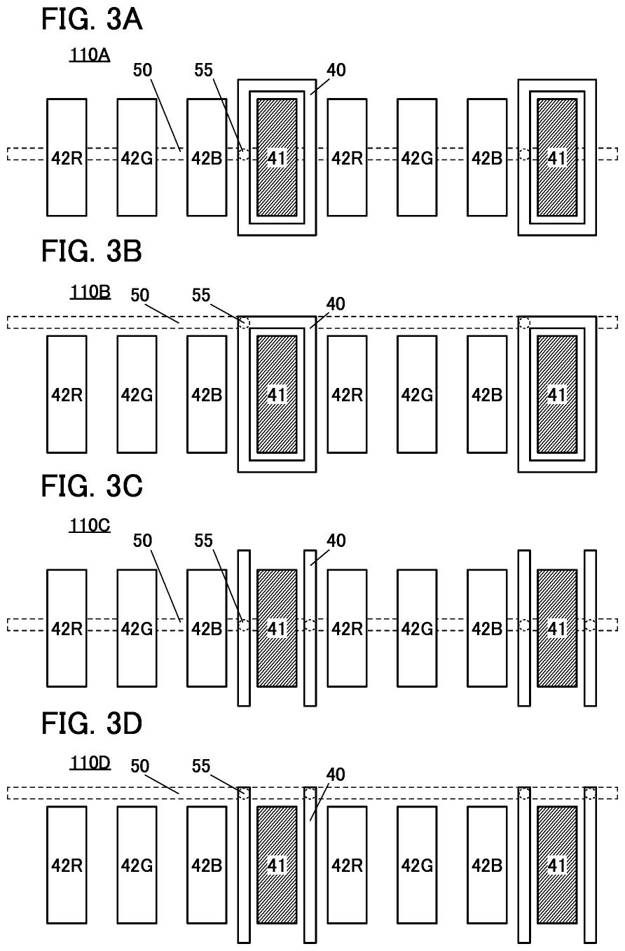

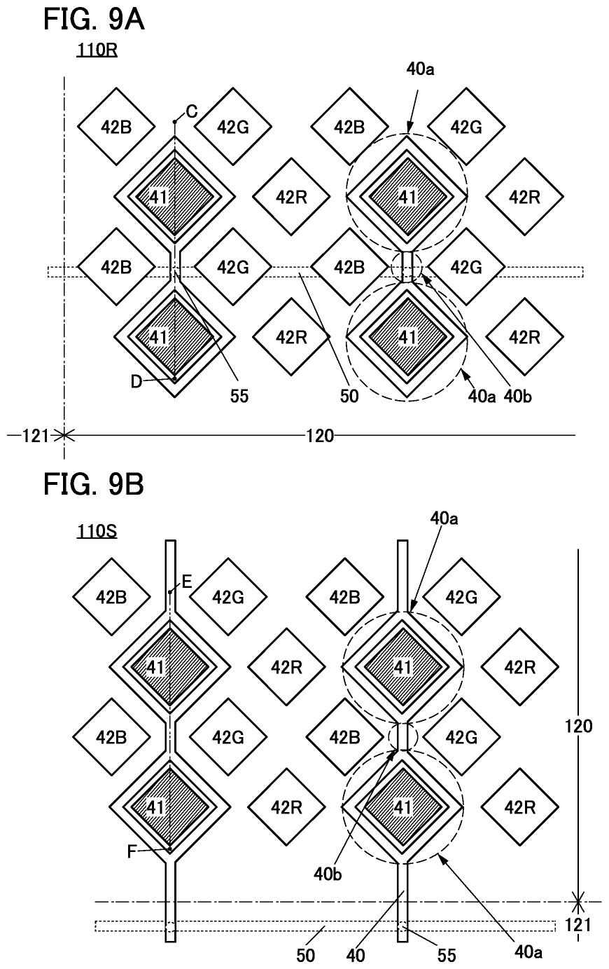

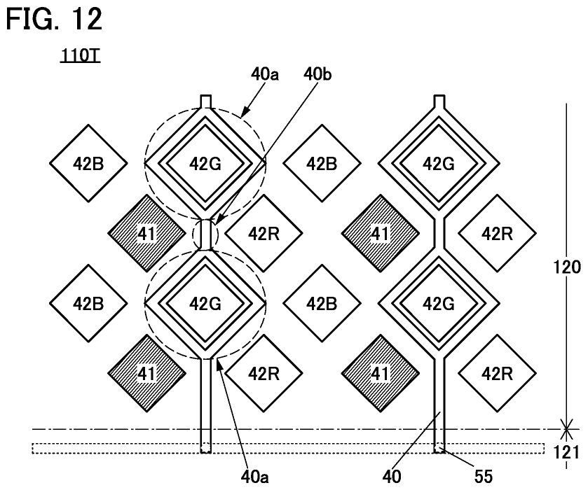

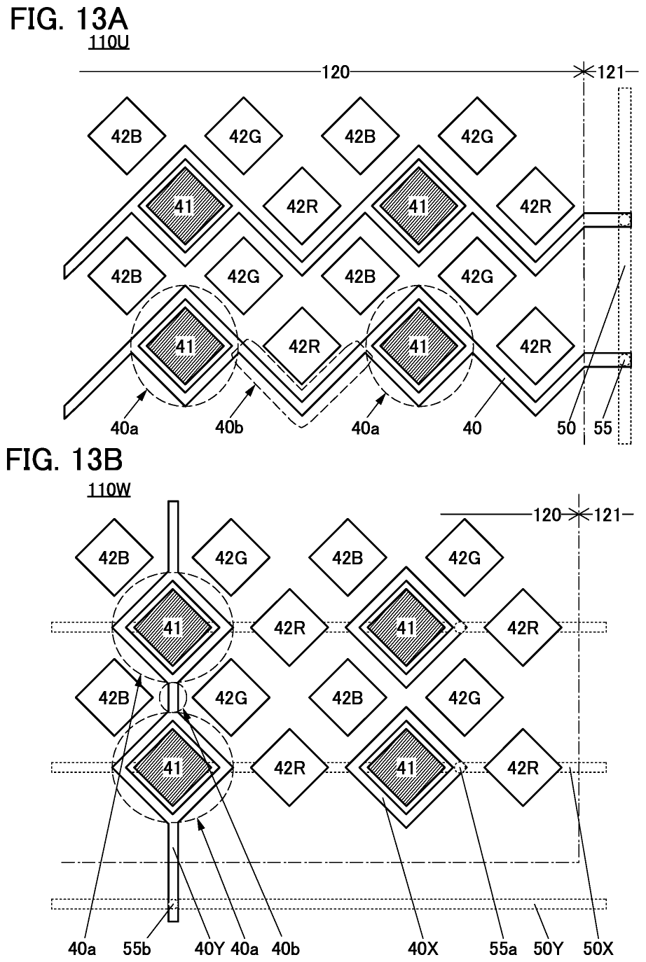

FIG. 3A to FIG. 8A, FIG. 9A and FIG. 9B, and FIG. 12 to FIG. 13B show structure examples of planar layouts of the pixel electrode 41, the pixel electrode 42, the conductive layer 40, and the like. The pixel electrode 41 is a pixel electrode of the light-receiving element, a pixel electrode 42R is a pixel electrode of a red light-emitting element, a pixel electrode 42G is a pixel electrode of a green light-emitting element, and a pixel electrode 42B is a pixel electrode of a blue light-emitting element. Note that in the following description, the term “pixel electrode 42” may be used when the pixel electrode 42R, the pixel electrode 42G, and the pixel electrode 42B are not distinguished from one another.

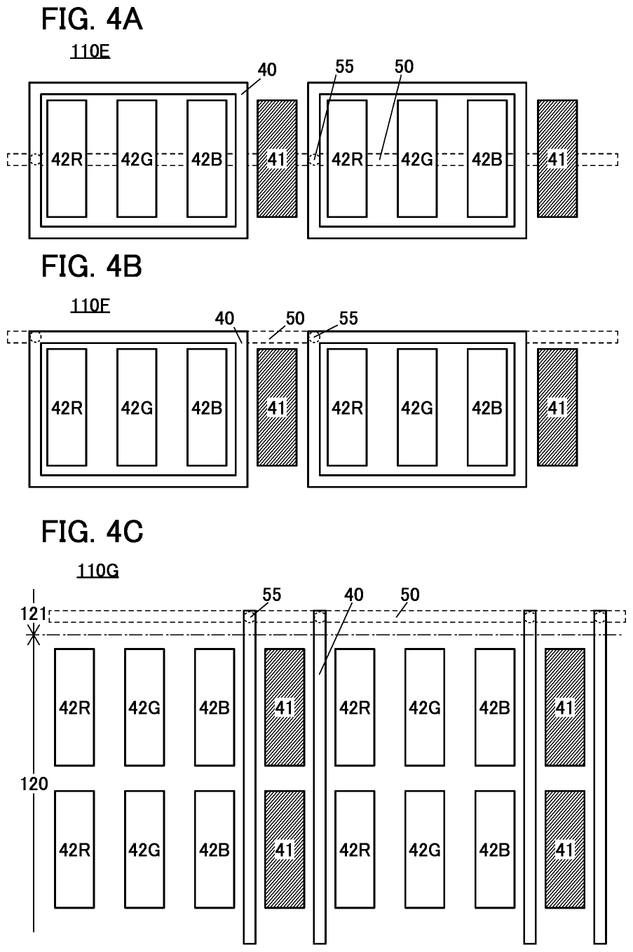

In the structure examples shown in FIG. 3A to FIG. 4C, three light-emitting elements and one light-receiving element are arranged in a line.

FIG. 3A shows a display apparatus 110A. In the display apparatus 110A, the pixel electrode 41 is positioned inside the conductive layer 40 with a ring shape when seen from above. The wiring 50 is provided under the pixel electrode 41 and the pixel electrode 42. The conductive layer 40 is electrically connected to the wiring 50 through a connection portion 55 that overlaps with the conductive layer 40. The conductive layer 40 is supplied with the potential 101 through the wiring 50. With such a structure, the pixel electrode 41 is separated from the pixel electrode 42 by the conductive layer 40; thus, a side leakage current flowing from the pixel electrode 42 to the pixel electrode 41 can be effectively blocked by the conductive layer 40. Consequently, noise of the light-receiving element is reduced, which leads to clear imaging. In addition, since the wiring 50 overlaps with the pixel electrode 41 and the pixel electrode 42, the space of the display portion can be effectively used. Therefore, pixels can be miniaturized and the aperture ratio of the pixel electrode can be increased.

A display apparatus 110B shown in FIG. 3B is different from the display apparatus 110A mainly in that the wiring 50 does not overlap with the pixel electrode 41 or the pixel electrode 42. Accordingly, the parasitic capacitance between the wiring 50 and each pixel electrode can be reduced, which leads to high-speed driving.

A display apparatus 110C shown in FIG. 3C is different from the display apparatus 110A mainly in that the conductive layer 40 with a stick shape (also referred to as a strip shape) is included. The conductive layer 40 is positioned between the pixel electrode 41 and the pixel electrode 42. The conductive layer 40 with a stick shape may be in a straight line form or a curved line form.

As in a display apparatus 110D shown in FIG. 3D, the wiring 50 does not necessarily overlap with the pixel electrode 41 and the pixel electrode 42.

A display apparatus 110E shown in FIG. 4A is different from the display apparatus 110A mainly in that the pixel electrode 42R, the pixel electrode 42G, and the pixel electrode 42B are positioned inside the conductive layer 40 with the ring shape. In this manner, the pixel electrode 41 is separated from the pixel electrode 42 by the conductive layer 40 also when the pixel electrode 42 of the light-emitting element is surrounded by the conductive layer 40, which enables a side leakage current flowing from the pixel electrode 42 to the pixel electrode 41 to be effectively blocked. Consequently, noise of the light-receiving element is reduced, which leads to clear imaging.

Although FIG. 4A shows the example in which the wiring 50 overlaps with the pixel electrode 41 and the pixel electrode 42, the wiring 50 does not necessarily overlap with the pixel electrode 41 or the pixel electrode 42 as in a display apparatus 110F shown in FIG. 4B.

Although the wiring 50 is provided in the display portion in the above examples, the wiring 50 can be provided in a region (non-display portion) on an outer side of the display portion. A dashed-dotted line in FIG. 4C indicates the boundary between a display portion 120 and a non-display portion 121 in a display apparatus 110G. The pixel electrode 41 and the pixel electrode 42 are positioned in the display portion 120.

In the display apparatus 110G shown in FIG. 4C, three light-emitting elements and one light-receiving element, which are arranged in a line, are arranged repeatedly in the vertical direction. The conductive layer 40 is electrically connected to the wiring 50 through the connection portion 55 positioned in the non-display portion 121. In addition, the conductive layer 40 is positioned between the pixel electrode 41 and the pixel electrode 42 that are adjacent to each other and is provided across the display portion 120 and the non-display portion 121. Furthermore, the wiring 50 does not overlap with the pixel electrode 41 and the pixel electrode 42 and is provided in the non-display portion 121.

The pixel electrode 41 and the pixel electrode 42 are separated from each other by the conductive layer 40 in the display apparatus 110G, which leads to clear imaging. In addition, since the wiring 50 is provided in the non-display portion 121, pixels in the display portion 120 can be miniaturized, which leads to display of an image with higher resolution. Furthermore, one wiring 50 can be provided with the connection portions 55 for a plurality of the conductive layers 40, resulting in a simplified circuit.

Although not shown here, the non-display portion 121 is preferably provided so as to surround the display portion 120. In addition, each of a pair of portions of the non-display portions 121 between which the display portion 120 is sandwiched is preferably provided with the wiring 50. In that case, FIG. 4C corresponds to one of the pair of portions of the non-display portions 121. Furthermore, in that case, the other of the pair of portions of the non-display portions 121 can have a structure obtained by turning upside down the structure shown in FIG. 4C.

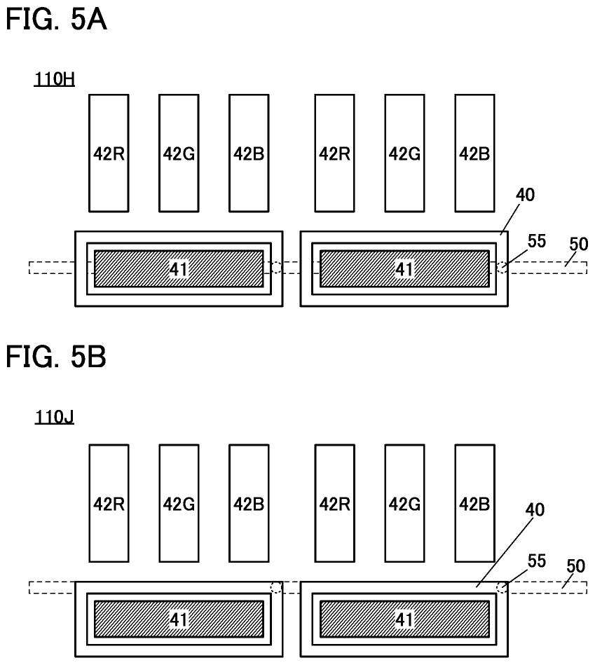

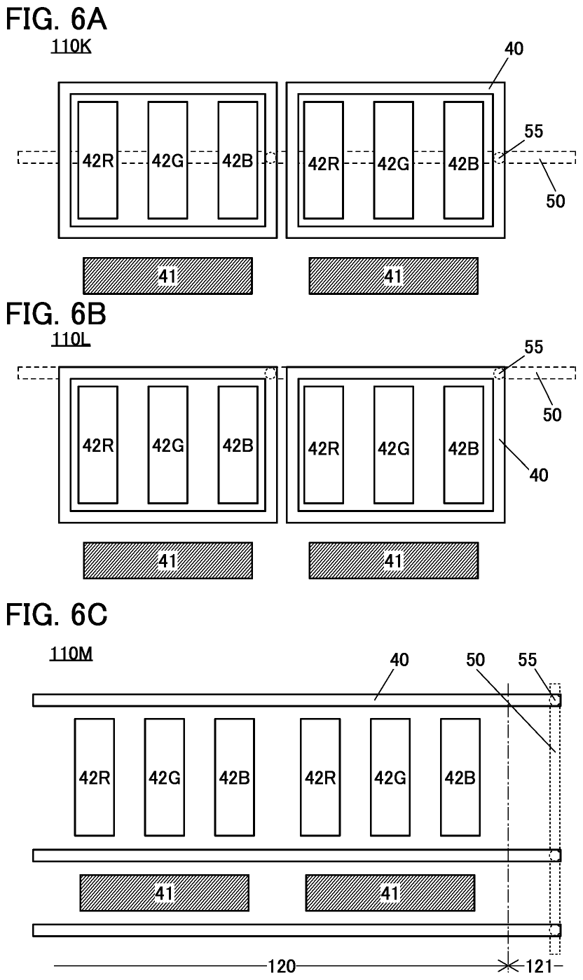

In structure examples shown in FIG. 5A to FIG. 6C, three light-emitting elements are arranged in a line and one laterally long light-receiving element is provided thereunder.

FIG. 5A shows a display apparatus 110H. As in the display apparatus 110A, the pixel electrode 41 in the display apparatus 110H is positioned inside the conductive layer 40 with the ring shape. In addition, as in a display apparatus 110J shown in FIG. 5B, the wiring 50 does not necessarily overlap with the pixel electrode 41.

FIG. 6A shows a display apparatus 110K. As in the display apparatus 110E, the pixel electrode 42R, the pixel electrode 42G, and the pixel electrode 42B of the display apparatus 110K are positioned inside a conductive layer 49 with a ring shape; as in a display apparatus 110L shown in FIG. 6B, the wiring 50 does not necessarily overlap with the pixel electrode 42.

A display apparatus 110M shown in FIG. 6C is different from the display apparatus 110G mainly in that three light-emitting elements arranged in a line and one laterally long light-receiving element provided thereunder are arranged repeatedly.

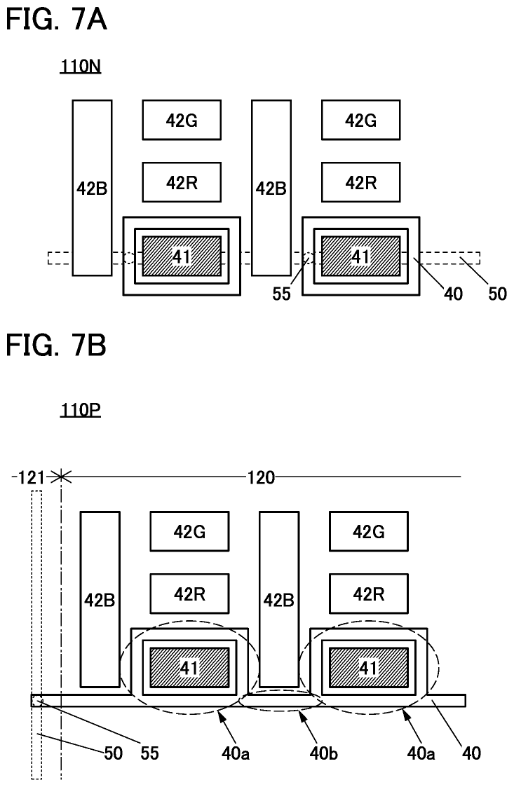

In structure examples shown in FIG. 7A and FIG. 7B, a green light-emitting element, a red light-emitting element, and a light-receiving element are arranged in a vertical line and a vertically long blue light-emitting element is provided on the side.

FIG. 7A shows a display apparatus 110N. As in the display apparatus 110A, the pixel electrode 41 in the display apparatus 110N is positioned inside the conductive layer 40 with the ring shape.

FIG. 7B shows a display apparatus 110P. A dashed-dotted line in FIG. 7B indicates the boundary between the display portion 120 and the non-display portion 121 in the display apparatus 110P.

Unlike in the display apparatus 110N, the conductive layer 40 is electrically connected to the wiring 50 in the display apparatus 110P through the connection portion 55 that overlaps with the conductive layer 40 in the non-display portion 121. In addition, the conductive layer 40 includes a first portion 40a with a ring shape and a second portion 40b and is provided across the display portion 120 and the non-display portion 121. Furthermore, another main difference is that the wiring 50 is positioned in the non-display portion 121.

The first portion 40a includes a ring-shaped portion, and the pixel electrode 41 is positioned inside the ring-shaped portion. In addition, the second portion 40b is positioned between a pair of the first portions 40a to connect the pair of the first portions 40a. Furthermore, the conductive layer 40 is provided across the display portion 120 and the non-display portion 121 and is electrically connected to the wiring 50 through the connection portion 55 that overlaps with the conductive layer 40 in the non-display portion 121.

With such a structure, the pixel electrode 41 is separated from the pixel electrode 42 by the conductive layer 40, which leads to clear imaging. In addition, since the wiring 50 is provided in the non-display portion, pixels in the display portion can be miniaturized, which leads to display of an image with higher resolution. Furthermore, such a structure is preferably employed, in which case one wiring 50 can be provided with the connection portions 55 for the plurality of the conductive layers 40, resulting in a simplified circuit.

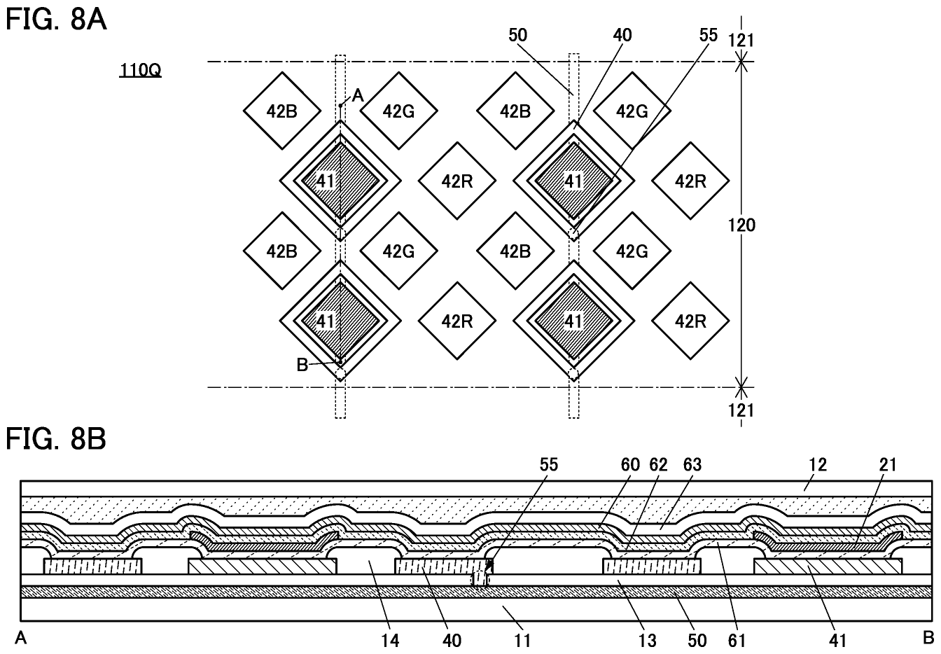

In structure examples shown in FIG. 8A, FIG. 9, FIG. 12, and FIG. 13, three light-emitting elements and one light-receiving element are arranged repeatedly in a matrix. Dashed-dotted lines in the figures each indicate the boundary between the display portion 120 and the non-display portion 121 in the display apparatus.

FIG. 8A shows a display apparatus 110Q. As in the display apparatus 110A, the pixel electrode 41 in the display apparatus 110Q is positioned inside the conductive layer 40 with the ring shape.

FIG. 8B corresponds to a cross-sectional view of a cut plane taken along a dashed double-dotted line A-B in FIG. 8A.

In the cross-sectional view, the wiring 50 is positioned between the substrate 11 and the pixel electrode 41 and the conductive layer 40. In addition, the wiring 50 is provided over the substrate 11 from one non-display portion 121 to another non-display portion 121 across the display portion 120 and includes portions overlapping with the pixel electrode 41, the conductive layer 40, and the light-receiving layer 21. Furthermore, the conductive layer 40 is electrically connected to the wiring 50 through the connection portion 55. Furthermore, although the wiring 50 and transistors connected to the pixel electrode 41 and the pixel electrode 42 are positioned over the same surface, they are provided so as not to interfere with each other.

A display apparatus 110R shown in FIG. 9A is different from the display apparatus 110Q shown in FIG. 8A mainly in that the conductive layer 40 includes the first portion 40a and the second portion 40b.

The first portion 40a includes a ring-shaped portion, and the pixel electrode 41 is positioned inside the ring-shaped portion. In addition, the second portion 40b is positioned between a pair of the first portions 40a to connect the pair of the portions 40a. Such a structure enables the number of wirings 50 in the display portion 120 to be reduced by half or more of that in the case where the first portions 40a are not connected by the second portion 40b, which results in effective utilization of the space of the display portion. Accordingly, pixels can be miniaturized or the aperture ratio of the pixel electrode can be increased.

FIG. 9B shows a display apparatus 110S. As in the display apparatus 110P, the pixel electrode 41 in the display apparatus 110S is positioned inside the first portion 40a with the ring shape of the conductive layer 40.

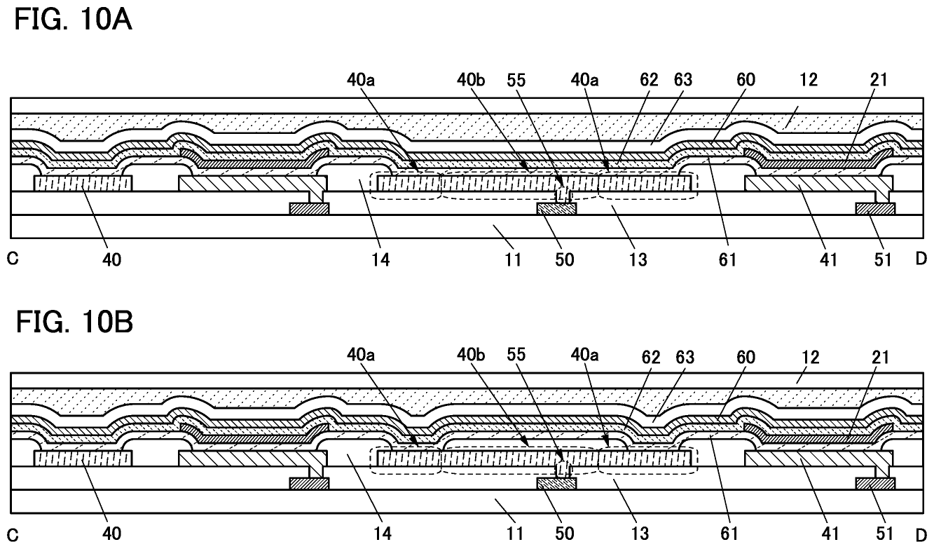

FIG. 10A and FIG. 10B each correspond to a cross-sectional view of a cut plane taken along a dashed double-dotted line C-D in FIG. 9A. In each of the cross-sectional views of FIG. 10A and FIG. 10B, the second portion 40b is positioned between the pair of the first portions 40a.

FIG. 10A shows an example in which the partition 14 is not provided over the second portion 40b of the conductive layer 40; FIG. 10B shows an example in which the partition 14 is provided over the second portion 40b. As shown in FIG. 10B, the partition 14 may cover not only an end portion of the first portion 40a but also part of an upper portion of the second portion 40b. In other words, the first portion 40a or the second portion 40b may be electrically connected to the common layer 61 at two or more portions.

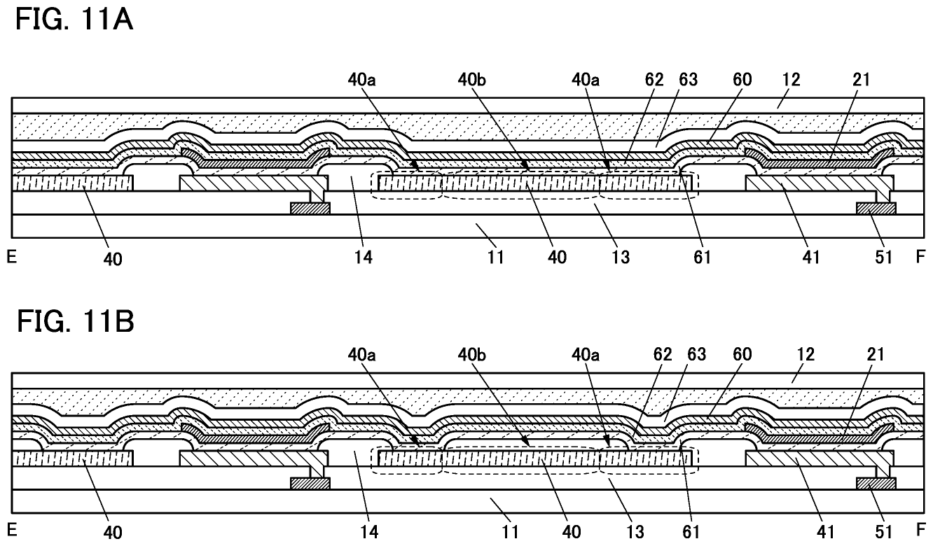

FIG. 11A and FIG. 11B each correspond to a cross-sectional view of a cut plane taken along a dashed double-dotted line E-F in FIG. 9B. The cross-sectional view of FIG. 11A and the cross-sectional view of FIG. 11B are different from FIG. 10A and FIG. 10B, respectively mainly in that the wiring 50 is not provided in the display portion 120.

A display apparatus 110T shown in FIG. 12 is different from the display apparatus 110S mainly in that the pixel electrode 42G is positioned inside the first portion 40a with the ring shape.

The light-emitting element provided in the display portion 120 can be used as a light source for imaging. In the case where a green light-emitting element is used as the light source, a side leakage current that flows from the pixel electrode 42G to the pixel electrode 41 might be generated. Therefore, as in the display apparatus 110T, the pixel electrode 42G may be positioned inside the first portion 40a with the ring shape. With the structure in which the pixel electrode 42G is surrounded by the conductive layer 40, the side leakage current described above can be suppressed. In the case where a red light-emitting element is used as the light source, the pixel electrode 42R may be positioned inside the first portion 40a. Similarly, in the case where a blue light-emitting element is used as the light source, the pixel electrode 42B may be positioned inside the first portion 40a.

A display apparatus 110U shown in FIG. 13A is an example in which the shape of the second portion 40b in the display apparatus 110S is changed. The second portion 40b is provided so as not to be in contact with the pixel electrode 41 or the pixel electrode 42. For example, the second portion 40b may have a shape with one or more inflection points as in the display apparatus 110U. For example, the second portion 40b may partly have a V-shape, an L-shape, or a U-shape when viewed from above.

A display apparatus 110W shown in FIG. 13B is a structure example in which the arrangement of the display apparatus 110Q and the arrangement of the display apparatus 110S are combined. In the display apparatus 110W, the pixel electrode 41 is positioned inside a conductive layer 40X with a ring shape. A conductive layer 40Y includes the first portion 40a and the second portion 40b. The first portion 40a has a ring-shaped portion, and the pixel electrode 41 is positioned inside the ring-shaped portion. The second portion 40b is positioned between the pair of the first portions 40a.

The conductive layer 40X is electrically connected to a wiring 50X through a connection portion 55a positioned in the display portion 120. The conductive layer 40Y is electrically connected to the wiring 50 through a connection portion 55b positioned in the non-display portion 121. The conductive layer 40X and the conductive layer 40Y are supplied with the potential 101 through the wiring 50X and the wiring 50Y, respectively. With such a structure, the pixel electrode 41 is separated from the pixel electrode 42 by the conductive layer 40, which enables a side leakage current that flows from the pixel electrode 42 to the pixel electrode 41 to be blocked by the conductive layer 40.

At least part of this embodiment can be implemented in combination with the other embodiments described in this specification as appropriate.

### Embodiment 2

In this embodiment, a specific structure example of the display apparatus of one embodiment of the present invention will be described. Note that the description given below partly overlaps the description of Embodiment 1.

A display portion of the display apparatus of one embodiment of the present invention includes light-receiving elements and light-emitting elements. The display portion has a function of displaying an image with the use of the light-emitting element. Furthermore, the display portion has one or both of a function of capturing an image with the use of the light-receiving element and a sensing function.

Alternatively, the display apparatus of one embodiment of the present invention may includes light-emitting/receiving elements (also referred to as light-emitting/receiving devices) and light-emitting elements.

Embodiment 1 can be referred to for an overview of the display apparatus including the light-receiving elements and the light-emitting elements.

For example, when the light-receiving elements are used as an image sensor, the display apparatus can capture an image using the light-receiving elements. For example, the display apparatus can be used as a scanner.

An electronic device including the display apparatus of one embodiment of the present invention can acquire data related to biological information such as a fingerprint or a palm print by using a function of an image sensor. In other words, a biometric authentication sensor can be incorporated in the display apparatus. When the display apparatus incorporates a biometric authentication sensor, the number of components of an electronic device can be reduced as compared with the case where a biometric authentication sensor is provided separately from the display apparatus; thus, the size and weight of the electronic device can be reduced.

When the light-receiving elements are used as a touch sensor, the display apparatus can sense a touch operation of an object by using the light-receiving elements.

In one embodiment of the present invention, organic EL elements (also referred to as organic EL devices) are used as the light-emitting elements, and organic photodiodes are used as the light-receiving elements. The organic EL elements and the organic photodiodes can be formed over one substrate. Thus, the organic photodiodes can be incorporated in the display apparatus including the organic EL elements.

In the case where all the layers of the organic EL elements and the organic photodiodes are formed separately, the number of deposition steps becomes extremely large. However, a large number of layers of the organic photodiodes have a structure in common with the EL elements; thus, concurrently forming the layers that can have a common structure can inhibit an increase in the number of deposition steps.

For example, one of a pair of electrodes (a common electrode) can be a layer shared by the light-receiving element and the light-emitting element. For example, at least one of a hole-injection layer, a hole-transport layer, an electron-transport layer, and an electron-injection layer is preferably a layer shared by the light-receiving element and the light-emitting element. As another example, the light-receiving element and the light-emitting element can have the same structure except that the light-receiving element includes an active layer and the light-emitting element includes a light-emitting layer. In other words, the light-receiving element can be manufactured by only replacing the light-emitting layer of the light-emitting element with an active layer. When the light-receiving element and the light-emitting element include common layers in such a manner, the number of deposition steps and the number of masks can be reduced, thereby reducing the number of manufacturing steps and the manufacturing cost of the display apparatus. Furthermore, the display apparatus including the light-receiving element can be manufactured using an existing manufacturing apparatus and an existing manufacturing method for the display apparatus.

Note that a layer shared by the light-receiving element and the light-emitting element might have functions different between the light-receiving element and the light-emitting element. In this specification, the name of a component is based on its function in the light-emitting element. For example, a hole-injection layer functions as a hole-injection layer in the light-emitting element and functions as a hole-transport layer in the light-receiving element. Similarly, an electron-injection layer functions as an electron-injection layer in the light-emitting element and functions as an electron-transport layer in the light-receiving element. A layer shared by the light-receiving element and the light-emitting element may have the same functions in the light-receiving element and the light-emitting element. A hole-transport layer functions as a hole-transport layer in both of the light-emitting element and the light-receiving element, and an electron-transport layer functions as an electron-transport layer in both of the light-emitting element and the light-receiving element.

Next, a display apparatus including light-emitting/receiving elements and light-emitting elements will be described. Note that functions, behavior, effects, and the like similar to those in the above are not described in some cases.

In the display apparatus of one embodiment of the present invention, a subpixel exhibiting one color includes a light-emitting/receiving element instead of a light-emitting element, and subpixels exhibiting the other colors each include a light-emitting element. The light-emitting/receiving element has both a function of emitting light (a light-emitting function) and a function of receiving light (a light-receiving function). For example, in the case where a pixel includes three subpixels of a red subpixel, a green subpixel, and a blue subpixel, at least one of the subpixels includes a light-emitting/receiving element, and the other subpixels each include a light-emitting element. Thus, the display portion of the display apparatus of one embodiment of the present invention has a function of displaying an image by using both a light-emitting/receiving element and a light-emitting element.

The light-emitting/receiving element functions as both a light-emitting element and a light-receiving element, whereby the pixel can be provided with a light-receiving function without an increase in the number of subpixels included in the pixel. Thus, the display portion of the display apparatus can be provided with one or both of an imaging function and a sensing function while keeping the aperture ratio of the pixel (aperture ratio of each subpixel) and the resolution of the display apparatus. Accordingly, in the display apparatus of one embodiment of the present invention, the aperture ratio of the pixel can be higher and the resolution can be increased more easily than in a display apparatus provided with a subpixel including a light-receiving element separately from a subpixel including a light-emitting element.

In the display portion of the display apparatus of one embodiment of the present invention, the light-emitting/receiving elements and the light-emitting elements are arranged in a matrix, and an image can be displayed on the display portion. The display portion can be used as an image sensor, a touch sensor, or the like. In the display apparatus of one embodiment of the present invention, the light-emitting elements can be used as a light source of the sensor. Thus, imaging and touch operation sensing are possible even in a dark place.

The light-emitting/receiving element can be manufactured by combining an organic EL element and an organic photodiode. For example, by adding an active layer of an organic photodiode to a layered structure of an organic EL element, the light-emitting/receiving element can be manufactured. Furthermore, in the light-emitting/receiving element formed of a combination of an organic EL element and an organic photodiode, concurrently forming layers that can be shared with the organic EL element can inhibit an increase in the number of deposition steps.

For example, one of a pair of electrodes (a common electrode) can be a layer shared with the light-emitting/receiving element and the light-emitting element. For example, at least one of a hole-injection layer, a hole-transport layer, an electron-transport layer, and an electron-injection layer is preferably a layer shared with the light-emitting/receiving element and the light-emitting element. As another example, the light-emitting/receiving element and the light-emitting element can have the same structure except for the presence or absence of an active layer of the light-receiving element. In other words, the light-emitting/receiving element can be manufactured by only adding the active layer of the light-receiving element to the light-emitting element. When the light-emitting/receiving element and the light-emitting element include common layers in such a manner, the number of deposition steps and the number of masks can be reduced, thereby reducing the number of manufacturing steps and the manufacturing cost of the display apparatus. Furthermore, the display apparatus including the light-emitting/receiving element can be manufactured using an existing manufacturing apparatus and an existing manufacturing method for the display apparatus.

Note that a layer included in the light-emitting/receiving element may have a different function between the case where the light-emitting/receiving element functions as a light-receiving element and the case where the light-emitting/receiving element functions as a light-emitting element. In this specification, the name of a component is based on its function in the case where the light-emitting/receiving element functions as a light-emitting element.

The display apparatus of this embodiment has a function of displaying an image by using the light-emitting elements and the light-emitting/receiving elements. In other words, the light-emitting element and the light-emitting/receiving element function as display elements.

The display apparatus of this embodiment has a function of sensing light by using the light-emitting/receiving elements. The light-emitting/receiving element can sense light having a shorter wavelength than light emitted by the light-emitting/receiving element itself.

When the light-emitting/receiving elements are used as an image sensor, the display apparatus of this embodiment can capture an image by using the light-emitting/receiving elements. When the light-emitting/receiving elements are used as a touch sensor, the display apparatus of this embodiment can sense a touch operation of an object by using the light-emitting/receiving elements.

The light-emitting/receiving element functions as a photoelectric conversion element. The light-emitting/receiving element can be manufactured by adding an active layer of the light-receiving element to the above-described structure of the light-emitting element. In the light-emitting/receiving element, an active layer of a pn photodiode or a pin photodiode can be used, for example.

It is particularly preferable to use, for the light-emitting/receiving element, an active layer of an organic photodiode including a layer containing an organic compound. An organic photodiode, which is easily made thin, lightweight, and large in area and has a high degree of freedom for shape and design, can be used in a variety of display apparatus.

Here, even between the light-emitting/receiving element and the light-emitting element, a side leakage current might be generated through the common layer. For this reason, a conductive layer electrically connected to the common layer is provided between the light-emitting/receiving element and the light-emitting element when seen from above. The arrangement, shape, and the like of the conductive layer can be similar to those in the case where the light-receiving element is used; a variety of structures given as examples in Embodiment 1 above can be employed.

The display apparatus of one embodiment of the present invention will be specifically described below with reference to drawings.

### [Structure Example 1 of Display Apparatus]

### Structure Example 1-1

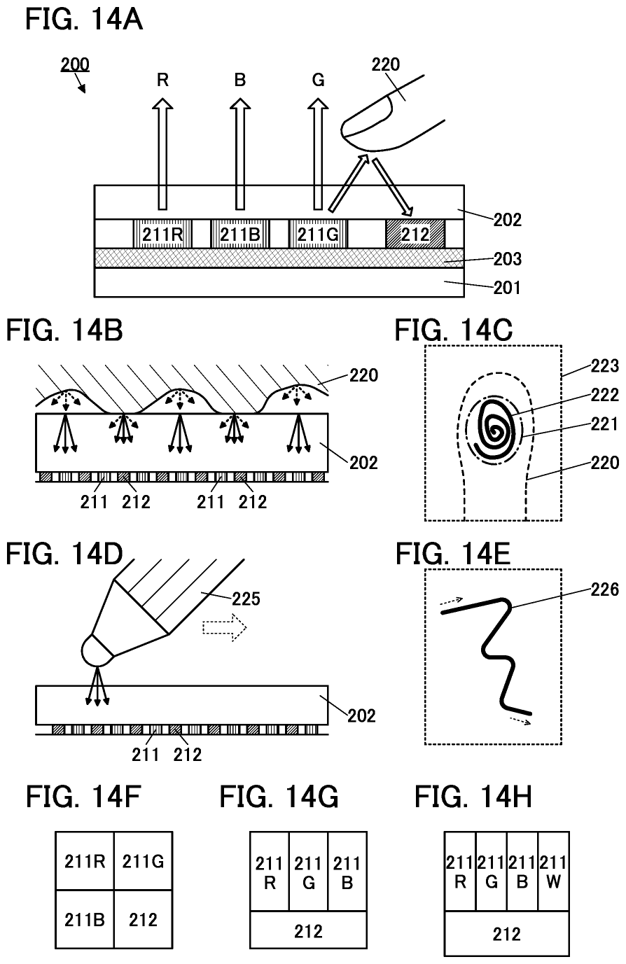

FIG. 14A is a schematic diagram of a display panel 200. The display panel 200 includes a substrate 201, a substrate 202, a light-receiving element 212, a light-emitting element 211R, a light-emitting element 211G, a light-emitting element 211B, a functional layer 203, and the like.

The light-emitting element 211R, the light-emitting element 211G, the light-emitting element 211B, and the light-receiving element 212 are provided between the substrate 201 and the substrate 202. The light-emitting element 211R, the light-emitting element 211G, the light-emitting element 211B emit red (R) light, green (G) light, and blue (B) light, respectively. Note that in the following description, the term “light-emitting element 211” may be used when the light-emitting element 211R, the light-emitting element 211G, the light-emitting element 211B are not distinguished from one another.

The display panel 200 includes a plurality of pixels arranged in a matrix. One pixel includes one or more subpixels. One subpixel includes one light-emitting element. For example, the pixel can have a structure including three subpixels (e.g., three colors of R, G, and B or three colors of yellow (Y), cyan (C), and magenta (M)) or four subpixels (e.g., four colors of R, G, B, and white (W) or four colors of R, G, B, and Y). The pixel further includes the light-receiving element 212. The light-receiving element 212 may be provided in all the pixels or may be provided in some of the pixels. Alternatively, one pixel may include a plurality of the light-receiving elements 212.

FIG. 14A shows a finger 220 approaching a surface of the substrate 202. Part of light emitted by the light-emitting element 211G is reflected by the finger 220. When part of the reflected light is incident on the light-receiving element 212, the approach of the finger 220 to above the substrate 202 can be sensed. In other words, the display panel 200 can function as a contactless touch panel. Since the contact of the finger 220 with the substrate 202 can also be sensed, the display panel 200 can also function as a contact touch panel (also simply referred to as a touch panel).

The functional layer 203 includes a circuit for driving the light-emitting element 211R, the light-emitting element 211G, and the light-emitting element 211B and a circuit for driving the light-receiving element 212. The functional layer 203 is provided with a switch, a transistor, a capacitor, a wiring, and the like. Note that in the case where the light-emitting element 211R, the light-emitting element 211G, the light-emitting element 211B, and the light-receiving element 212 are driven by a passive-matrix method, a switch, a transistor, and the like are not necessarily provided.

The display panel 200 preferably has a function of capturing an image of a fingerprint of the finger 220. FIG. 14B schematically shows an enlarged view of the contact portion in a state where the finger 220 touches the substrate 202. FIG. 14B shows the light-emitting elements 211 and the light-receiving elements 212 that are alternately arranged.

The fingerprint of the finger 220 is formed of depressions and projections. Accordingly, as shown in FIG. 14B, the projections of the fingerprint touch the substrate 202.

Reflection of light from a surface or an interface is categorized into regular reflection and diffuse reflection. Regularly reflected light is highly directional light with an angle of reflection equal to the angle of incidence. Diffusely reflected light has low directionality and low angular dependence of intensity. As for regular reflection and diffuse reflection, diffuse reflection components are dominant in the light reflected from the surface of the finger 220. Meanwhile, regular reflection components are dominant in the light reflected from the interface between the substrate 202 and the air.

The intensity of light that is reflected from contact surfaces or non-contact surfaces between the finger 220 and the substrate 202 and enters the light-receiving elements 212 which are positioned directly below the contact surfaces or the non-contact surfaces is the sum of intensities of regularly reflected light and diffusely reflected light. As described above, regularly reflected light (indicated by solid arrows) is dominant near the depressions of the finger 220, where the finger 220 is not in contact with the substrate 202; whereas diffusely reflected light (indicated by dashed arrows) from the finger 220 is dominant near the projections of the finger 220, where the finger 220 is in contact with the substrate 202. Thus, the intensity of light received by the light-receiving element 212 positioned directly below the depression is higher than the intensity of light received by the light-receiving element 212 positioned directly below the projection. Accordingly, an image of the fingerprint of the finger 220 can be captured.

When the arrangement interval between the light-receiving elements 212 is smaller than the distance between two projections of the fingerprint, preferably the distance between a depression and a projection adjacent to each other, a clear fingerprint image can be obtained. The distance between a depression and a projection of a human's fingerprint is approximately 200 μm; thus, the arrangement interval between the light-receiving elements 212 is, for example, less than or equal to 400 μm, preferably less than or equal to 200 μm, further preferably less than or equal to 150 μm, still further preferably less than or equal to 100 μm, even still further preferably less than or equal to 50 μm and greater than or equal to 1 μm, preferably greater than or equal to 10 μm, further preferably greater than or equal to 20 μm.

FIG. 14C shows an example of a fingerprint image captured with the display panel 200. In FIG. 14C, in an imaging range 223, the outline of the finger 220 is indicated by a dashed line and the outline of a contact portion 221 is indicated by a dashed-dotted line. In the contact portion 221, a high-contrast image of a fingerprint 222 can be captured by a difference in the amount of light incident on the light-receiving elements 212.

Even in the case where the finger 220 is not in contact with the substrate 202, a fingerprint image can be captured by capturing an image of projections and depressions of the fingerprint of the finger 220.

The display panel 200 can also function as a touch panel or a pen tablet, for example. FIG. 14D shows a state in which a tip of a stylus 225 slides in a direction indicated by a dashed arrow with the tip of the stylus 225 close to the substrate 202.

As shown in FIG. 14D, when diffusely reflected light that is diffused at the tip of the stylus 225 is incident on the light-receiving element 212 that overlaps with the tip, the position of the tip of the stylus 225 can be sensed with high accuracy.

FIG. 14E shows an example of a path 226 of the stylus 225 that is sensed by the display panel 200. The display panel 200 can sense the position of a sensing target such as the stylus 225 with high accuracy, so that high-definition drawing can be performed using a drawing application or the like. Unlike in the case of using a capacitive touch sensor, an electromagnetic induction touch pen, or the like, the display panel 200 can sense even the position of a highly insulating sensing target; hence, the material of a tip portion of the stylus 225 is not limited, and a variety of writing materials (e.g., a brush, a glass pen, or a quill pen) can be used.

Here, FIG. 14F to FIG. 14H show examples of pixels that can be used in the display panel 200.

The pixels shown in FIG. 14F and FIG. 14G each include the red (R) light-emitting element 211R, the green (G) light-emitting element 211G, the blue (B) light-emitting element 211B, and the light-receiving element 212. The pixels each include a pixel circuit for driving the light-emitting element 211R, the light-emitting element 211G, the light-emitting element 211B, and the light-receiving element 212.

FIG. 14F shows an example in which three light-emitting elements and one light-receiving element are arranged in a matrix of 2×2. FIG. 14G shows an example in which three light-emitting elements are laterally arranged in a line and one laterally long light-receiving element 212 is provided below the three light-emitting elements.

FIG. 14H shows an example in which the pixel includes a white (W) light-emitting element 211W. Here, four light-emitting elements are arranged in a line and the light-receiving element 212 is provided below the four light-emitting elements.

Note that the pixel structure is not limited to the above structure, and a variety of arrangement can be employed.

### Structure Example 1-2

An example of a structure including a light-emitting element emitting visible light, a light-emitting element emitting infrared light, and a light-receiving element will be described below.

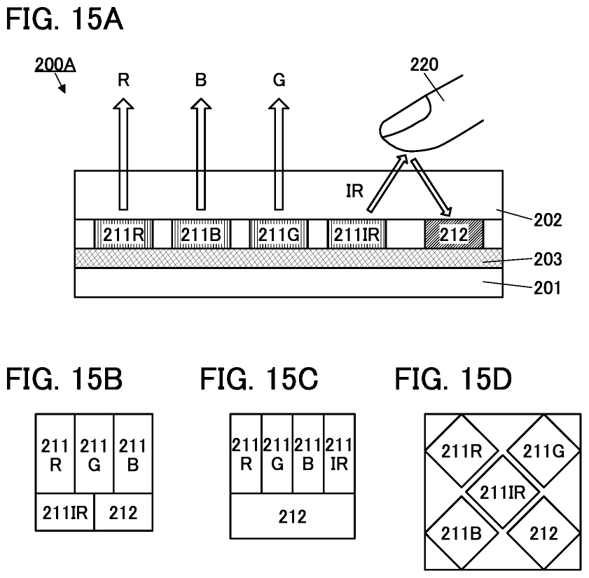

A display panel 200A shown in FIG. 15A includes a light-emitting element 211IR in addition to the components shown in FIG. 14A as an example. The light-emitting element 211IR is a light-emitting element emitting infrared light IR. Moreover, in that case, an element capable of receiving at least the infrared light IR emitted from the light-emitting element 211IR is preferably used as the light-receiving element 212. As the light-receiving element 212, an element capable of receiving both visible light and infrared light is further preferably used.

As shown in FIG. 15A, when the finger 220 approaches the substrate 202, the infrared light IR emitted from the light-emitting element 211IR is reflected by the finger 220 and part of the reflected light is incident on the light-receiving element 212, so that the positional information of the finger 220 can be obtained.

FIG. 15B to FIG. 15D show examples of pixels that can be used in the display panel 200A.

FIG. 15B shows an example in which three light-emitting elements are arranged in a line and the light-emitting element 211IR and the light-receiving element 212 are arranged laterally below the three light-emitting elements. FIG. 15C shows an example in which four light-emitting elements including the light-emitting element 2111R are arranged in a line and the light-receiving element 212 is provided below the four light-emitting elements.

FIG. 15D shows an example in which three light-emitting elements and the light-receiving element 212 arranged in four directions around the light-emitting element 2111R.

Note that in the pixels shown in FIG. 15B to FIG. 15D, the positions of the light-emitting elements are interchangeable, and the positions of the light-emitting element and the light-receiving element are interchangeable.

### Structure Example 1-3

An example of a structure including a light-emitting element that emits visible light and a light-emitting/receiving element that emits and receives visible light will be described below.

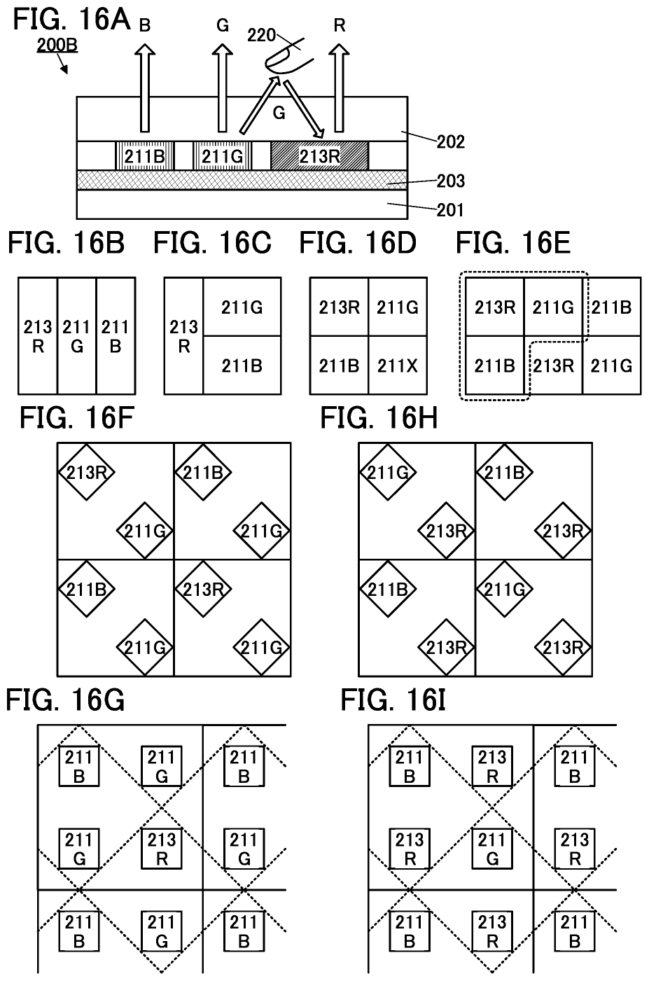

A display panel 200B shown in FIG. 16A includes the light-emitting element 211B, the light-emitting element 211G, and a light-emitting/receiving element 213R. The light-emitting/receiving element 213R has a function of a light-emitting element that emits red (R) light and a function of a photoelectric conversion element that receives visible light. FIG. 16A shows an example in which the light-emitting/receiving element 213R receives green (G) light emitted from the light-emitting element 211G. Note that the light-emitting/receiving element 213R may receive blue (B) light emitted from the light-emitting element 211B. Alternatively, the light-emitting/receiving element 213R may receive both green light and blue light.

For example, the light-emitting/receiving element 213R preferably receives light having a shorter wavelength than light emitted from itself. Alternatively, the light-emitting/receiving element 213R may receive light (e.g., infrared light) having a longer wavelength than light emitted from itself. The light-emitting/receiving element 213R may receive light having approximately the same wavelength as light emitted from itself; however, in that case, the light-emitting/receiving element 213R also receives light emitted from itself, whereby its emission efficiency might be decreased. Therefore, the peak of the emission spectrum and the peak of the absorption spectrum of the light-emitting/receiving element 213R preferably overlap as little as possible.

Here, light emitted from the light-emitting/receiving element is not limited to red light. Light emitted from the light-emitting elements is not limited to a combination of green light and blue light. For example, the light-emitting/receiving element can be an element that emits green light or blue light and receives light having a different wavelength from light emitted from itself.

The light-emitting/receiving element 213R serves as both a light-emitting element and a light-receiving element as described above, whereby the number of elements provided in one pixel can be reduced. Thus, higher definition, a higher aperture ratio, higher resolution, and the like can be easily achieved.

FIG. 16B to FIG. 16I show examples of pixels that can be used in the display panel 200B.

FIG. 16B shows an example in which the light-emitting/receiving element 213R, the light-emitting element 211G, and the light-emitting element 211B are arranged in a line. FIG. 16C shows an example in which the light-emitting element 211G and the light-emitting element 211B are alternately arranged in the vertical direction and the light-emitting/receiving element 213R is provided alongside the light-emitting elements.

FIG. 16D shows an example in which three light-emitting elements (the light-emitting element 211G, the light-emitting element 211B, and a light-emitting element 211X and one light-emitting/receiving element are arranged in matrix of 2×2. The light-emitting element 211X emits light of a color other than R, G, and B. Examples of light of a color other than R, G, and B include white (W) light, yellow (Y) light, cyan (C) light, magenta (M) light, infrared light (IR), and ultraviolet light (UV). In the case where the light-emitting element 211X emits infrared light, the light-emitting/receiving element preferably has a function of sensing infrared light or a function of sensing both visible light and infrared light. The wavelength of light that the light-emitting/receiving element senses can be determined depending on the application of a sensor.

FIG. 16E shows two pixels. A region that includes three elements and is enclosed by a dotted line corresponds to one pixel. Each of the pixels includes the light-emitting element 211G, the light-emitting element 211B, and the light-emitting/receiving element 213R. In the left pixel in FIG. 16E, the light-emitting element 211G is provided in the same row as the light-emitting/receiving element 213R, and the light-emitting element 211B is provided in the same column as the light-emitting/receiving element 213R. In the right pixel in FIG. 16E, the light-emitting element 211G is provided in the same row as the light-emitting/receiving element 213R, and the light-emitting element 211B is provided in the same column as the light-emitting element 211G. In the pixel layout in FIG. 16E, the light-emitting/receiving element 213R, the light-emitting element 211G, and the light-emitting element 211B are repeatedly arranged in both the odd-numbered row and the even-numbered row, and in each column, the light-emitting elements or the light-emitting element and the light-emitting/receiving element arranged in the odd-numbered row and the even-numbered row emit light of different colors.

FIG. 16F shows four pixels that employ pentile arrangement; two adjacent pixels have different combinations of light-emitting elements or a light-emitting element and a light-emitting/receiving element that emit light of two different colors. Note that FIG. 16F shows the top surface shape of the light-emitting element or the light-emitting/receiving element.

The upper left pixel and the lower right pixel in FIG. 16F each include the light-emitting/receiving element 213R and the light-emitting element 211G. The upper right pixel and the lower left pixel each include the light-emitting element 211G and the light-emitting element 211B. That is, in the example shown in FIG. 16F, the light-emitting element 211G is provided in each pixel.

The top surface shapes of the light-emitting elements and the light-emitting/receiving elements are not particularly limited and can be a circular shape, an elliptical shape, a polygonal shape, a polygonal shape with rounded corners, or the like. FIG. 16F and the like show examples in which the top surface shapes of the light-emitting elements and the light-emitting/receiving elements are each a square tilted at approximately 45° (a diamond shape). Note that the top surface shapes of the light-emitting elements and the light-emitting/receiving elements of different colors may vary, or the elements of some colors or all colors may have the same top surface shape.

The sizes of light-emitting regions (or light-emitting/receiving regions) of the light-emitting elements and the light-emitting/receiving elements of different colors may vary, or the regions of some colors or all colors may have the same size. For example, in FIG. 16F, the light-emitting region of the light-emitting element 211G provided in each pixel may have a smaller area than the light-emitting region (or the light-emitting/receiving region) of the other elements.

FIG. 16G is a variation example of the pixel arrangement shown in FIG. 16F. Specifically, the structure of FIG. 16G is obtained by rotating the structure of FIG. 16F by 45°. Although one pixel is shown as including two elements in FIG. 16F, one pixel can also be regarded as including four elements as shown in FIG. 16G.

FIG. 16H is a variation example of the pixel arrangement shown in FIG. 16F. The upper left pixel and the lower right pixel in FIG. 16H each include the light-emitting/receiving element 213R and the light-emitting element 211G. The upper right pixel and the lower left pixel each include the light-emitting/receiving element 213R and the light-emitting element 211B. That is, in the example shown in FIG. 16H, the light-emitting/receiving element 213R is provided in each pixel. The structure shown in FIG. 16H enables higher-resolution imaging than the structure shown in FIG. 16F because of including the light-emitting/receiving element 213R in each pixel. Thus, the accuracy of biometric authentication can be increased, for example.

FIG. 16I is a variation example of the pixel arrangement in FIG. 16H, which is obtained by rotating the pixel arrangement in FIG. 16H by 45°.

In FIG. 16I, one pixel is described as being composed of four elements (two light-emitting elements and two light-emitting/receiving elements). The pixel including a plurality of light-emitting/receiving elements having a light-receiving function allows high-resolution imaging. Thus, the accuracy of biometric authentication can be increased. For example, the resolution of imaging can be the square root of 2 times the resolution of display.

A display apparatus that employs the structure shown in FIG. 16H or FIG. 16I includes p (p is an integer greater than or equal to 2) first light-emitting elements, q (q is an integer greater than or equal to 2) second light-emitting elements, and r (r is an integer greater than p and q) light-emitting/receiving elements. As for p and r, r=2p is satisfied. As for p, q, and r, r=p+q is satisfied. Either the first light-emitting elements or the second light-emitting elements emit green light, and the other light-emitting elements emit blue light. The light-emitting/receiving elements emit red light and have a light-receiving function.

In the case where a touch operation is sensed using the light-emitting/receiving elements, for example, it is preferable that light emitted from a light source be less likely to be perceived by the user. Since blue light has lower visibility than green light, light-emitting elements that emit blue light are preferably used as a light source. Accordingly, the light-emitting/receiving elements preferably have a function of receiving blue light. Note that without limitation to the above, light-emitting elements used as a light source can be selected as appropriate depending on the sensitivity of the light-emitting/receiving elements.

As described above, the display apparatus of this embodiment can include pixels with a variety of arrangements.

### [Device Structure]

Next, detailed structures of a light-emitting element, a light-receiving element, and a light-emitting/receiving element that can be used in the display apparatus of one embodiment of the present invention will be described.

The display apparatus of one embodiment of the present invention can have any of the following structures: a top-emission structure in which light is emitted in a direction opposite to the substrate where the light-emitting element is formed, a bottom-emission structure in which light is emitted toward the substrate where the light-emitting element is formed, and a dual-emission structure in which light is emitted toward both surfaces.

In this embodiment, a top-emission display apparatus is described as an example.

In this specification and the like, unless otherwise specified, in describing a structure including a plurality of components (e.g., light-emitting elements or light-emitting layers), alphabets are omitted when a common part of the components is described. For example, the term “light-emitting layer 283” is sometimes used to describe a common part of a light-emitting layer 283R, a light-emitting layer 283G, and the like.

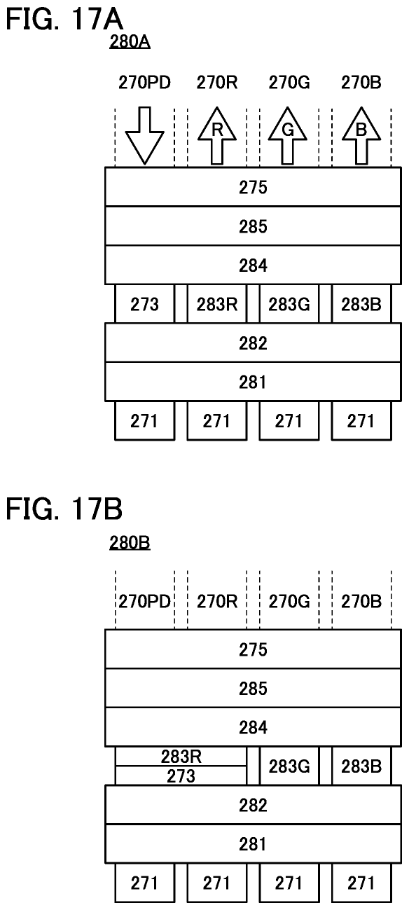

A display apparatus 280A shown in FIG. 17A includes a light-receiving element 270PD, a light-emitting element 270R that emits red (R) light, a light-emitting element 270G that emits green (G) light, and a light-emitting element 270B that emits blue (B) light.

Each of the light-emitting elements includes a pixel electrode 271, a hole-injection layer 281, a hole-transport layer 282, a light-emitting layer, an electron-transport layer 284, an electron-injection layer 285, and a common electrode 275 that are stacked in this order. The light-emitting element 270R includes the light-emitting layer 283R, the light-emitting element 270G includes the light-emitting layer 283G, and the light-emitting element 270B includes a light-emitting layer 283B. The light-emitting layer 283R includes a light-emitting substance that emits red light, the light-emitting layer 283G includes a light-emitting substance that emits green light, and the light-emitting layer 283B includes a light-emitting substance that emits blue light.

The light-emitting elements are electroluminescent elements that emit light to the common electrode 275 side by voltage application between the pixel electrodes 271 and the common electrode 275.

The light-receiving element 270PD includes the pixel electrode 271, the hole-injection layer 281, the hole-transport layer 282, an active layer 273, the electron-transport layer 284, the electron-injection layer 285, and the common electrode 275 that are stacked in this order.

The light-receiving element 270PD is a photoelectric conversion element that receives light entering from the outside of the display apparatus 280A and converts it into an electric signal.

This embodiment is described assuming that the pixel electrode 271 functions as an anode and the common electrode 275 functions as a cathode in both of the light-emitting element and the light-receiving element. In other words, the light-receiving element is driven by application of reverse bias between the pixel electrode 271 and the common electrode 275, whereby light incident on the light-receiving element can be sensed and electric charge can be generated and extracted as a current.

In the display apparatus of this embodiment, an organic compound is used for the active layer 273 of the light-receiving element 270PD. The light-receiving element 270PD can share the layers other than the active layer 273 with the light-emitting elements. Therefore, the light-receiving element 270PD can be formed concurrently with the formation of the light-emitting elements only by adding a step of forming the active layer 273 in the manufacturing process of the light-emitting elements. The light-emitting elements and the light-receiving element 270PD can be formed over one substrate. Accordingly, the light-receiving element 270PD can be incorporated into the display apparatus without a significant increase in the number of manufacturing steps.

The display apparatus 280A is an example in which the light-receiving element 270PD and the light-emitting elements have a common structure except that the active layer 273 of the light-receiving element 270PD and the light-emitting layers 283 of the light-emitting elements are separately formed. Note that the structures of the light-receiving element 270PD and the light-emitting elements are not limited thereto. The light-receiving element 270PD and the light-emitting elements may include separately formed layers in addition to the active layer 273 and the light-emitting layers 283. The light-receiving element 270PD and the light-emitting elements preferably include at least one layer used in common (common layer). Thus, the light-receiving element 270PD can be incorporated into the display apparatus without a significant increase in the number of manufacturing steps.

A conductive film that transmits visible light is used as the electrode through which light is extracted, which is either the pixel electrode 271 or the common electrode 275. A conductive film that reflects visible light is preferably used as the electrode through which light is not extracted.

The light-emitting elements included in the display apparatus of this embodiment preferably employ a micro-optical resonator (microcavity) structure. Therefore, one of the pair of electrodes of the light-emitting element is preferably an electrode having properties of transmitting and reflecting visible light (a transflective electrode), and the other is preferably an electrode having a property of reflecting visible light (a reflective electrode). When the light-emitting element has a microcavity structure, light obtained from the light-emitting layer can be resonated between the electrodes, whereby light emitted from the light-emitting element can be intensified.

Note that the transflective electrode can have a stacked-layer structure of a reflective electrode and an electrode having a property of transmitting visible light (also referred to as a transparent electrode).

The light transmittance of the transparent electrode is greater than or equal to 40%. For example, an electrode having a visible light (light with a wavelength greater than or equal to 400 nm and less than 750 nm) transmittance higher than or equal to 40% is preferably used in the light-emitting elements. The transflective electrode has a visible light reflectance higher than or equal to 10% and lower than or equal to 95%, preferably higher than or equal to 30% and lower than or equal to 80%. The reflective electrode has a visible light reflectance of higher than or equal to 40% and lower than or equal to 100%, preferably higher than or equal to 70% and lower than or equal to 100%. These electrodes preferably have a resistivity less than or equal to 1×10⁻² Ωcm. Note that in the case where any of the light-emitting elements emits near-infrared light (light with a wavelength greater than or equal to 750 nm and less than or equal to 1300 nm), the near-infrared light transmittance and reflectance of these electrodes preferably satisfy the above-described numerical ranges of the visible light transmittance and reflectance.

The light-emitting element includes at least the light-emitting layer 283. In addition to the light-emitting layer 283, the light-emitting element may further include a layer containing a substance with a high hole-injection property, a substance with a high hole-transport property, a hole-blocking material, a substance with a high electron-transport property, a substance with a high electron-injection property, an electron-blocking material, a substance with a bipolar property (a substance with a high electron- and hole-transport property), and the like.

For example, the light-emitting elements and the light-receiving element can share at least one of the hole-injection layer, the hole-transport layer, the electron-transport layer, and the electron-injection layer. Furthermore, at least one of the hole-injection layer, the hole-transport layer, the electron-transport layer, and the electron-injection layer can be separately formed for the light-emitting elements and the light-receiving element.

The hole-injection layer is a layer that injects holes from an anode to the hole-transport layer and contains a material with a high hole-injection property. As the material with a high hole-injection property, a composite material containing a hole-transport material and an acceptor material (electron-accepting material), an aromatic amine compound, or the like can be used.

In the light-emitting elements, the hole-transport layer is a layer that transports holes, which are injected from the anode by the hole-injection layer, to the light-emitting layer. In the light-receiving element, the hole-transport layer is a layer that transports holes, which are generated in the active layer on the basis of incident light, to the anode. The hole-transport layer is a layer that contains a hole-transport material. As the hole-transport material, a substance having a hole mobility greater than or equal to 1×10⁻⁶ cm²/Vs is preferable. Note that other substances can also be used as long as they have a property of transporting more holes than electrons. As the hole-transport material, materials having a high hole-transport property, such as a π-electron rich heteroaromatic compound (e.g., a carbazole derivative, a thiophene derivative, and a furan derivative) and an aromatic amine (a compound having an aromatic amine skeleton), are preferable.

In the light-emitting element, the electron-transport layer is a layer that transports electrons, which are injected from the cathode by the electron-injection layer, to the light-emitting layer. In the light-receiving element, the electron-transport layer is a layer that transports electrons, which are generated in the active layer on the basis of incident light, to the cathode. The electron-transport layer is a layer that contains an electron-transport material. As the electron-transport material, a substance having an electron mobility greater than or equal to 1×10⁻⁶ cm²/Vs is preferable. Note that other substances can also be used as long as they have a property of transporting more electrons than holes. As the electron-transport material, it is possible to use a material having a high electron-transport property, such as a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, or a 7c-electron deficient heteroaromatic compound such as a nitrogen-containing heteroaromatic compound.

The electron-injection layer is a layer that injects electrons from the cathode to the electron-transport layer and is a layer that contains a material with a high electron-injection property. As the material with a high electron-injection property, an alkali metal, an alkaline earth metal, or a compound thereof can be used. As the material with a high electron-injection property, a composite material containing an electron-transport material and a donor material (electron-donating material) can also be used.

The light-emitting layer 283 is a layer that contains a light-emitting substance. The light-emitting layer 283 can contain one or more kinds of light-emitting substances. As the light-emitting substance, a substance that exhibits an emission color of blue, purple, bluish purple, green, yellowish green, yellow, orange, red, or the like is used as appropriate. Alternatively, as the light-emitting substance, a substance that emits near-infrared light can be used.

Examples of the light-emitting substance include a fluorescent material, a phosphorescent material, a TADF material, and a quantum dot material.

Examples of the fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of the phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

The light-emitting layer 283 may contain one or more kinds of organic compounds (e.g., a host material and an assist material) in addition to the light-emitting substance (a guest material). As one or more kinds of organic compounds, one or both of the hole-transport material and the electron-transport material can be used. Alternatively, as one or more kinds of organic compounds, a bipolar material or a TADF material may be used.

The light-emitting layer 283 preferably includes a phosphorescent material and a combination of a hole-transport material and an electron-transport material that easily forms an exciplex. With such a structure, light emission can be efficiently obtained by ExTET (Exciplex-Triplet Energy Transfer), which is energy transfer from an exciplex to a light-emitting substance (a phosphorescent material). When a combination of materials is selected so as to form an exciplex that exhibits light emission whose wavelength overlaps with the wavelength of a lowest-energy-side absorption band of the light-emitting substance, energy can be transferred smoothly and light emission can be obtained efficiently. With this structure, high efficiency, low-voltage driving, and a long lifetime of the light-emitting element can be achieved at the same time.

In a combination of materials for forming an exciplex, the HOMO level (the highest occupied molecular orbital level) of the hole-transport material is preferably higher than or equal to the HOMO level of the electron-transport material. The LUMO level (the lowest unoccupied molecular orbital level) of the hole-transport material is preferably higher than or equal to the LUMO level of the electron-transport material. Note that the LUMO levels and the HOMO levels of the materials can be derived from the electrochemical characteristics (the reduction potentials and the oxidation potentials) of the materials that are measured by cyclic voltammetry (CV).

Note that the formation of an exciplex can be confirmed by a phenomenon in which the emission spectrum of a mixed film in which the hole-transport material and the electron-transport material are mixed is shifted to the longer wavelength side than the emission spectrum of each of the materials (or has another peak on the longer wavelength side), observed by comparison of the emission spectrum of the hole-transport material, the emission spectrum of the electron-transport material, and the emission spectrum of the mixed film of these materials, for example. Alternatively, the formation of an exciplex can be confirmed by a difference in transient response, such as a phenomenon in which the transient photoluminescence (PL) lifetime of the mixed film has longer lifetime components or has a larger proportion of delayed components than that of each of the materials, observed by comparison of the transient PL of the hole-transport material, the transient PL of the electron-transport material, and the transient PL of the mixed film of these materials. The transient PL can be rephrased as transient electroluminescence (EL). That is, the formation of an exciplex can also be confirmed by a difference in transient response observed by comparison of the transient EL of the hole-transport material, the transient EL of the electron-transport material, and the transient EL of the mixed film of these materials.

The active layer 273 includes a semiconductor. Examples of the semiconductor include an inorganic semiconductor such as silicon and an organic semiconductor including an organic compound. This embodiment shows an example in which an organic semiconductor is used as the semiconductor included in the active layer 273. An organic semiconductor is preferably used, in which case the light-emitting layer 283 and the active layer 273 can be formed by the same method (e.g., a vacuum evaporation method) and thus the same manufacturing apparatus can be used.

Examples of an n-type semiconductor material contained in the active layer 273 are electron-accepting organic semiconductor materials such as fullerene (e.g., C₆₀ and C₇₀) and a fullerene derivative. Fullerene has a soccer ball-like shape, which is energetically stable. Both the HOMO level and the LUMO level of fullerene are deep (low). Having a deep LUMO level, fullerene has an extremely high electron-accepting property (acceptor property). In general, when π-electron conjugation (resonance) spreads in a plane as in benzene, an electron-donating property (donor property) becomes high; however, since fullerene has a spherical shape, fullerene has a high electron-accepting property even when π-electrons widely spread. The high electron-accepting property efficiently causes rapid charge separation and is useful for a light-receiving element. Both C₆₀ and C₇₀ have a wide absorption band in the visible light region, and C₇₀ is especially preferable because of having a larger π-electron conjugation system and a wider absorption band in the long wavelength region than C₆₀.

Examples of the n-type semiconductor material include a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative, a benzoquinoline derivative, a quinoxaline derivative, a dibenzoquinoxaline derivative, a pyridine derivative, a bipyridine derivative, a pyrimidine derivative, a naphthalene derivative, an anthracene derivative, a coumarin derivative, a rhodamine derivative, a triazine derivative, and a quinone derivative.

Examples of a p-type semiconductor material contained in the active layer 273 include electron-donating organic semiconductor materials such as copper(II) phthalocyanine (CuPc), tetraphenyldibenzoperiflanthene (DBP), zinc phthalocyanine (ZnPc), tin phthalocyanine (SnPc), and quinacridone.

Examples of the p-type semiconductor material include a carbazole derivative, a thiophene derivative, a furan derivative, and a compound having an aromatic amine skeleton. Other examples of the p-type semiconductor material include a naphthalene derivative, an anthracene derivative, a pyrene derivative, a triphenylene derivative, a fluorene derivative, a pyrrole derivative, a benzofuran derivative, a benzothiophene derivative, an indole derivative, a dibenzofuran derivative, a dibenzothiophene derivative, an indolocarbazole derivative, a porphyrin derivative, a phthalocyanine derivative, a naphthalocyanine derivative, a quinacridone derivative, a polyphenylene vinylene derivative, a polyparaphenylene derivative, a polyfluorene derivative, a polyvinylcarbazole derivative, and a polythiophene derivative.

The HOMO level of the electron-donating organic semiconductor material is preferably shallower (higher) than the HOMO level of the electron-accepting organic semiconductor material. The LUMO level of the electron-donating organic semiconductor material is preferably shallower (higher) than the LUMO level of the electron-accepting organic semiconductor material.

Fullerene having a spherical shape is preferably used as the electron-accepting organic semiconductor material, and an organic semiconductor material having a substantially planar shape is preferably used as the electron-donating organic semiconductor material. Molecules of similar shapes tend to aggregate, and aggregated molecules of similar kinds, which have molecular orbital energy levels close to each other, can increase the carrier-transport property.

For example, the active layer 273 is preferably formed by co-evaporation of an n-type semiconductor and a p-type semiconductor. Alternatively, the active layer 273 may be formed by stacking an n-type semiconductor and a p-type semiconductor.

Either a low molecular compound or a high molecular compound can be used for the light-emitting element and the light-receiving element, and an inorganic compound may also be contained. Each of the layers included in the light-emitting element and the light-receiving element can be formed by an evaporation method (including a vacuum evaporation method), a transfer method, a printing method, an inkjet method, a coating method, or the like.

A display apparatus 280B shown in FIG. 17B is different from the display apparatus 280A in that the light-receiving element 270PD and the light-emitting element 270R have the same structure.

The light-receiving element 270PD and the light-emitting element 270R share the active layer 273 and the light-emitting layer 283R.

Here, it is preferable that the light-receiving element 270PD have the same structure as the light-emitting element that emits light with a wavelength longer than that of the light desired to be sensed. For example, the light-receiving element 270PD with a structure for sensing blue light can have the same structure as one or both of the light-emitting element 270R and the light-emitting element 270G. For example, the light-receiving element 270PD with a structure for sensing green light can have the same structure as the light-emitting element 270R.

When the light-receiving element 270PD and the light-emitting element 270R have a common structure, the number of deposition steps and the number of masks can be smaller than those for the structure in which the light-receiving element 270PD and the light-emitting element 270R include separately formed layers. As a result, the number of manufacturing steps and the manufacturing cost of the display apparatus can be reduced.

When the light-receiving element 270PD and the light-emitting element 270R have a common structure, a margin for misalignment can be narrower than that for the structure in which the light-receiving element 270PD and the light-emitting element 270R include separately formed layers. Accordingly, the aperture ratio of a pixel can be increased, so that the light extraction efficiency of the display apparatus can be increased. This can extend the life of the light-emitting element. Furthermore, the display apparatus can exhibit a high luminance. Moreover, the resolution of the display apparatus can also be increased.

The light-emitting layer 283R contains a light-emitting material that emits red light. The active layer 273 contains an organic compound that absorbs light with a wavelength shorter than that of red light (e.g., one or both of green light and blue light). The active layer 273 preferably contains an organic compound that does not easily absorb red light and that absorbs light with a wavelength shorter than that of red light. In that case, red light can be efficiently extracted from the light-emitting element 270R, and the light-receiving element 270PD can sense light with a wavelength shorter than that of red light with high accuracy.

Although the light-emitting element 270R and the light-receiving element 270PD have the same structure in an example of the display apparatus 280B, the light-emitting element 270R and the light-receiving element 270PD may include optical adjustment layers with different thicknesses.

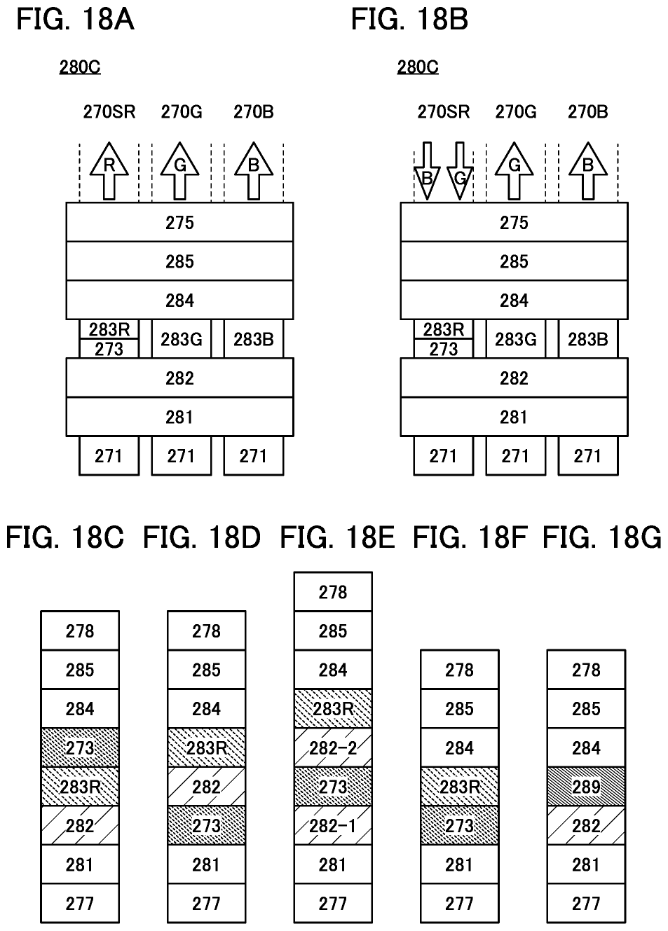

A display apparatus 280C shown in FIG. 18A and FIG. 18B includes a light-emitting/receiving element 270SR that emits red (R) light and has a light-receiving function, the light-emitting element 270G, and the light-emitting element 270B. The above description of the display apparatus 280A and the like can be referred to for the structures of the light-emitting element 270G and the light-emitting element 270B.

The light-emitting/receiving element 270SR includes the pixel electrode 271, the hole-injection layer 281, the hole-transport layer 282, the active layer 273, the light-emitting layer 283R, the electron-transport layer 284, the electron-injection layer 285, and the common electrode 275 which are stacked in this order. The light-emitting/receiving element 270SR has the same structure as the light-emitting element 270R and the light-receiving element 270PD in the display apparatus 280B.

FIG. 18A shows the case where the light-emitting/receiving element 270SR functions as a light-emitting element. FIG. 18A shows an example in which the light-emitting element 270B emits blue light, the light-emitting element 270G emits green light, and the light-emitting/receiving element 270SR emits red light.

FIG. 18B shows the case where the light-emitting/receiving element 270SR functions as a light-receiving element. FIG. 18B shows an example in which the light-emitting/receiving element 270SR receives blue light emitted by the light-emitting element 270B and green light emitted by the light-emitting element 270G.

The light-emitting element 270B, the light-emitting element 270G, and the light-emitting/receiving element 270SR each include the pixel electrode 271 and the common electrode 275. In this embodiment, the case where the pixel electrode 271 functions as an anode and the common electrode 275 functions as a cathode is described as an example. The light-emitting/receiving element 270SR is driven by application of reverse bias between the pixel electrode 271 and the common electrode 275, whereby light incident on the light-emitting/receiving element 270SR can be sensed and charge can be generated and extracted as a current.

It can be said that the light-emitting/receiving element 270SR has a structure in which the active layer 273 is added to the light-emitting element. That is, the light-emitting/receiving element 270SR can be formed concurrently with the light-emitting elements only by adding a step of forming the active layer 273 in the manufacturing process of the light-emitting element. The light-emitting element and the light-emitting/receiving element can be formed over one substrate. Thus, the display portion can be provided with one or both of an imaging function and a sensing function without a significant increase in the number of manufacturing steps.

The stacking order of the light-emitting layer 283R and the active layer 273 is not limited. FIG. 18A and FIG. 18B each show an example in which the active layer 273 is provided over the hole-transport layer 282 and the light-emitting layer 283R is provided over the active layer 273. The stacking order of the light-emitting layer 283R and the active layer 273 may be reversed.

The light-emitting/receiving element may exclude at least one layer of the hole-injection layer 281, the hole-transport layer 282, the electron-transport layer 284, and the electron-injection layer 285. Furthermore, the light-emitting/receiving element may include another functional layer such as a hole-blocking layer or an electron-blocking layer.

In the light-emitting/receiving element, a conductive film that transmits visible light is used as the electrode through which light is extracted. A conductive film that reflects visible light is preferably used as the electrode through which light is not extracted.

The functions and materials of the layers constituting the light-emitting/receiving element are similar to those of the layers constituting the light-emitting elements and the light-receiving element and are not described in detail.

FIG. 18C to FIG. 18G show examples of layered structures of light-emitting/receiving elements.

The light-emitting/receiving element shown in FIG. 18C includes a first electrode 277, the hole-injection layer 281, the hole-transport layer 282, the light-emitting layer 283R, the active layer 273, the electron-transport layer 284, the electron-injection layer 285, and a second electrode 278.

FIG. 18C shows an example in which the light-emitting layer 283R is provided over the hole-transport layer 282 and the active layer 273 is stacked over the light-emitting layer 283R.

As shown in FIG. 18A to FIG. 18C, the active layer 273 and the light-emitting layer 283R may be in contact with each other.

A buffer layer is preferably provided between the active layer 273 and the light-emitting layer 283R. In that case, the buffer layer preferably has a hole-transport property and an electron-transport property. For example, a substance with a bipolar property is preferably used for the buffer layer. Alternatively, as the buffer layer, at least one layer of a hole-injection layer, a hole-transport layer, an electron-transport layer, an electron-injection layer, a hole-blocking layer, an electron-blocking layer, and the like can be used. FIG. 18D shows an example in which the hole-transport layer 282 is used as the buffer layer.

The buffer layer provided between the active layer 273 and the light-emitting layer 283R can inhibit transfer of excitation energy from the light-emitting layer 283R to the active layer 273. Furthermore, the optical path length (cavity length) of the microcavity structure can be adjusted with the buffer layer. Thus, high emission efficiency can be obtained from the light-emitting/receiving element including the buffer layer between the active layer 273 and the light-emitting layer 283R.

FIG. 18E shows an example in which a hole-transport layer 282-1, the active layer 273, a hole-transport layer 282-2, and the light-emitting layer 283R are stacked in this order over the hole-injection layer 281. The hole-transport layer 282-2 functions as a buffer layer. The hole-transport layers 282-1 and the hole-transport layer 281-2 may contain the same material or different materials. Instead of the hole-transport layer 281-2, any of the above layers that can be used as the buffer layer may be used. The positions of the active layer 273 and the light-emitting layer 283R may be interchanged.

The light-emitting/receiving element shown in FIG. 18F is different from the light-emitting/receiving element shown in FIG. 18A in that the hole-transport layer 282 is not included. In this manner, the light-emitting/receiving element may exclude at least one of the hole-injection layer 281, the hole-transport layer 282, the electron-transport layer 284, and the electron-injection layer 285. The light-emitting/receiving element may include another functional layer such as a hole-blocking layer or an electron-blocking layer.

The light-emitting/receiving element shown in FIG. 18G is different from the light-emitting/receiving element shown in FIG. 18A in including a layer 289 serving as both a light-emitting layer and an active layer instead of including the active layer 273 and the light-emitting layer 283R.

As the layer serving as both a light-emitting layer and an active layer, it is possible to use, for example, a layer containing three materials which are an n-type semiconductor that can be used for the active layer 273, a p-type semiconductor that can be used for the active layer 273, and a light-emitting substance that can be used for the light-emitting layer 283R.

Note that an absorption band on the lowest energy side of an absorption spectrum of a mixed material of the n-type semiconductor and the p-type semiconductor and a maximum peak of an emission spectrum (PL spectrum) of the light-emitting substance preferably do not overlap with each other and are further preferably positioned fully apart from each other.

### [Structure Example 2 of Display Apparatus]

A detailed structure of the display apparatus of one embodiment of the present invention will be described below. Here, in particular, an example of the display apparatus including light-receiving elements and light-emitting elements will be described.

### Structure Example 2-1

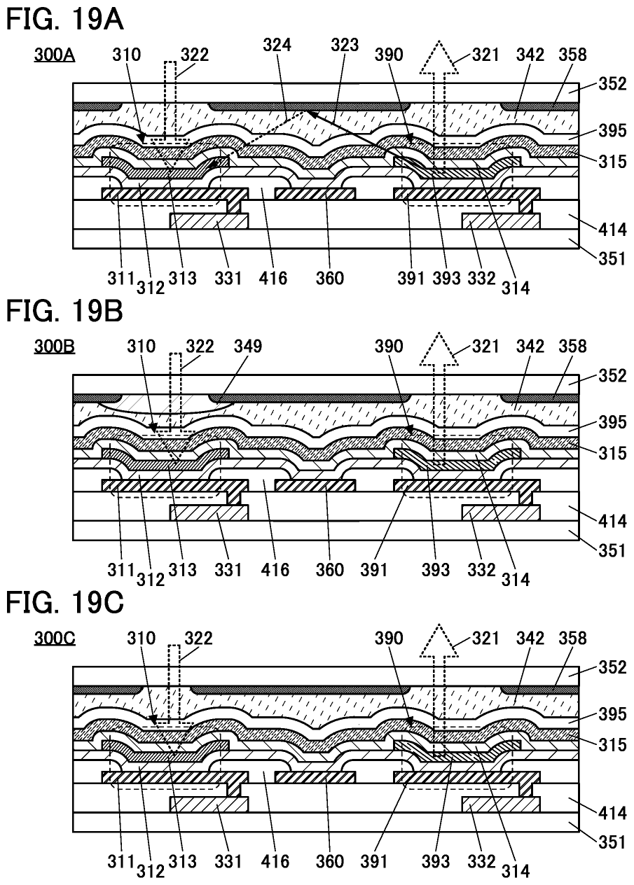

FIG. 19A is a cross-sectional view of a display apparatus 300A. The display apparatus 300A includes a substrate 351, a substrate 352, a light-receiving element 310, a conductive layer 360, and a light-emitting element 390.

The light-emitting element 390 includes a pixel electrode 391, a buffer layer 312, a light-emitting layer 393, a buffer layer 314, and a common electrode 315 which are stacked in this order. The buffer layer 312 can include one or both of a hole-injection layer and a hole-transport layer. The light-emitting layer 393 contains an organic compound. The buffer layer 314 can include one or both of an electron-injection layer and an electron-transport layer. The light-emitting element 390 has a function of emitting visible light 321. Note that the display apparatus 300A may also include a light-emitting element having a function of emitting infrared light.

The light-receiving element 310 includes a pixel electrode 311, the buffer layer 312, an active layer 313, the buffer layer 314, and the common electrode 315 which are stacked in this order. The active layer 313 contains an organic compound. The light-receiving element 310 has a function of sensing visible light. Note that the light-receiving element 310 may also have a function of sensing infrared light.

The buffer layer 312, the buffer layer 314, and the common electrode 315 are shared by the light-emitting element 390 and the light-receiving element 310 and provided across them. The buffer layer 312, the buffer layer 314, and the common electrode 315 each include a portion overlapping with the active layer 313 and the pixel electrode 311, a portion overlapping with the light-emitting layer 393 and the pixel electrode 391, and a portion overlapping with none of them.

This embodiment is described assuming that the pixel electrode functions as an anode and the common electrode 315 functions as a cathode in both of the light-emitting element 390 and the light-receiving element 310. In other words, the light-receiving element 310 is driven by application of reverse bias between the pixel electrode 311 and the common electrode 315, whereby light incident on the light-receiving element 310 can be sensed and electric charge can be generated and extracted as a current in the display apparatus 300A.

The pixel electrode 311, the pixel electrode 391, the buffer layer 312, the active layer 313, the buffer layer 314, the light-emitting layer 393, and the common electrode 315 may each have a single-layer structure or a stacked-layer structure.

The pixel electrode 311 and the pixel electrode 391 are each positioned over an insulating layer 414. The pixel electrodes can be formed using the same material in the same step. An end portion of the pixel electrode 311 and an end portion of the pixel electrode 391 are covered with an insulating layer 416. Two adjacent pixel electrodes are electrically insulated (electrically isolated) from each other by the insulating layer 416.

An organic insulating film is suitable for the insulating layer 416. Examples of materials that can be used for the organic insulating film include an acrylic resin, a polyimide resin, an epoxy resin, a polyamide resin, a polyimide-amide resin, a siloxane resin, a benzocyclobutene-based resin, a phenol resin, and precursors of these resins. The insulating layer 416 is a layer that transmits visible light. A partition that blocks visible light may be provided instead of the insulating layer 416.

The common electrode 315 is a layer shared by the light-receiving element 310 and the light-emitting element 390.

The material, thickness, and the like of the pair of electrodes in the light-receiving element 310 can be the same as those of the pair of electrodes in the light-emitting element 390. Accordingly, the manufacturing cost of the display apparatus can be reduced and the manufacturing process can be simplified.

The conductive layer 360 is positioned between the pixel electrode 391 and the pixel electrode 311 when seen from above. The conductive layer 360 is formed by processing the same conductive film as one or both of the pixel electrode 391 and the pixel electrode 311. The conductive layer 360 includes a region in contact with the buffer layer 312 in an opening portion of the insulating layer 416. In addition, in a region not shown, the conductive layer 360 is electrically connected to a wiring to which a predetermined potential is supplied.

The display apparatus 300A includes the light-receiving element 310, the light-emitting element 390, a transistor 331, a transistor 332, and the like between a pair of substrates (the substrate 351 and the substrate 352).

In the light-receiving element 310, the buffer layer 312, the active layer 313, and the buffer layer 314, which are positioned between the pixel electrode 311 and the common electrode 315, can each be referred to as an organic layer (a layer including an organic compound). The pixel electrode 311 preferably has a function of reflecting visible light. The common electrode 315 has a function of transmitting visible light. Note that in the case where the light-receiving element 310 is configured to sense infrared light, the common electrode 315 has a function of transmitting infrared light. Furthermore, the pixel electrode 311 preferably has a function of reflecting infrared light.

The light-receiving element 310 has a function of sensing light. Specifically, the light-receiving element 310 is a photoelectric conversion element that receives light 322 incident from the outside of the display apparatus 300A and converts it into an electric signal. The light 322 can also be expressed as light that is emitted from the light-emitting element 390 and then reflected by a target object. The light 322 may be incident on the light-receiving element 310 through a lens or the like provided in the display apparatus 300A.

In the light-emitting element 390, the buffer layer 312, the light-emitting layer 393, and the buffer layer 314, which are positioned between the pixel electrode 391 and the common electrode 315, can be collectively referred to as an EL layer. The EL layer includes at least the light-emitting layer 393. As described above, the pixel electrode 391 preferably has a function of reflecting visible light. The common electrode 315 has a function of transmitting visible light. Note that in the case where the display apparatus 300A includes a light-emitting element that emits infrared light, the common electrode 315 has a function of transmitting infrared light. Furthermore, the pixel electrode 391 preferably has a function of reflecting infrared light.

The light-emitting elements included in the display apparatus of this embodiment preferably employ a micro optical resonator (microcavity) structure. The light-emitting element 390 may include an optical adjustment layer between the pixel electrode 391 and the common electrode 315. The use of the micro resonator structure enables light of a specific color to be intensified and extracted from each of the light-emitting elements.

The light-emitting element 390 has a function of emitting visible light. Specifically, the light-emitting element 390 is an electroluminescent element that emits light (here, the visible light 321) to the substrate 352 side when voltage is applied between the pixel electrode 391 and the common electrode 315.

The pixel electrode 311 included in the light-receiving element 310 is electrically connected to a source or a drain of the transistor 331 through an opening provided in the insulating layer 414. The pixel electrode 391 included in the light-emitting element 390 is electrically connected to a source or a drain of the transistor 332 through an opening provided in the insulating layer 414.

The transistor 331 and the transistor 332 are on and in contact with the same layer (the substrate 351 in FIG. 19A).

At least part of a circuit electrically connected to the light-receiving element 310 and a circuit electrically connected to the light-emitting element 390 are preferably formed using the same material in the same step. In that case, the thickness of the display apparatus can be smaller and the manufacturing process can be simpler than those in the case where the two circuits are separately formed.

The light-receiving element 310 and the light-emitting element 390 are preferably covered with a protective layer 395. In FIG. 19A, the protective layer 395 is provided on and in contact with the common electrode 315. Providing the protective layer 395 can inhibit entry of impurities such as water into the light-receiving element 310 and the light-emitting element 390, so that the reliability of the light-receiving element 310 and the light-emitting element 390 can be increased. The protective layer 395 and the substrate 352 are bonded to each other with an adhesive layer 342.

A light-blocking layer 358 is provided on the surface of the substrate 352 on the substrate 351 side. The light-blocking layer 358 has openings in a position overlapping with the light-emitting element 390 and in a position overlapping with the light-receiving element 310.

Here, the light-receiving element 310 senses light that is emitted from the light-emitting element 390 and then reflected by a target object. However, in some cases, light emitted from the light-emitting element 390 is reflected inside the display apparatus 300A and is incident on the light-receiving element 310 without through a target object. The light-blocking layer 358 can reduce the influence of such stray light. For example, in the case where the light shielding layer 358 is not provided, light 323 emitted from the light-emitting element 390 is reflected by the substrate 352 and reflected light 324 enters the light-receiving element 310 in some cases. For example, in the case where the light-blocking layer 358 is not provided, light 323 emitted from the light-emitting element 390 is reflected by the substrate 352 and reflected light 324 is incident on the light-receiving element 310 in some cases. Providing the light-blocking layer 358 can inhibit the reflected light 324 to be incident on the light-receiving element 310. Providing the light-blocking layer 358 can inhibit the reflected light 324 to be incident on the light-receiving element 310. Consequently, noise can be reduced, and the sensitivity of a sensor using the light-receiving element 310 can be increased.

For the light-blocking layer 358, a material that blocks light emitted from the light-emitting element can be used. The light shielding layer 358 preferably absorbs visible light. As the light-blocking layer 358, a black matrix can be formed using a metal material or a resin material containing pigment (e.g., carbon black) or dye, for example. The light-blocking layer 358 may have a stacked-layer structure of a red color filter, a green color filter, and a blue color filter.

### Structure Example 2-2

A display apparatus 300B shown in FIG. 19B is different from the display apparatus 300A mainly in that a lens 349 is included.

The lens 349 is provided on a surface of the substrate 352 on the substrate 351 side. The light 322 from the outside is incident on the light-receiving element 310 through the lens 349. For each of the lens 349 and the substrate 352, a material that has high visible-light-transmitting property is preferably used.

When light is incident on the light-receiving element 310 through the lens 349, the range of light incident on the light-receiving element 310 can be narrowed. Thus, overlap of image-capturing ranges between a plurality of the light-receiving elements 310 can be inhibited, whereby a clear image with little blurring can be captured.

In addition, the lens 349 can condense incident light. Accordingly, the amount of light to be incident on the light-receiving element 310 can be increased. This can increase the photoelectric conversion efficiency of the light-receiving element 310.

### Structure Example 2-3

A display apparatus 300C shown in FIG. 19C is different from the display apparatus 300A mainly in the shape of the light-blocking layer 358.

The light-blocking layer 358 is provided such that an opening portion overlapping with the light-receiving element 310 is positioned on an inner side of a light-receiving region of the light-receiving element 310 when seen from above. The smaller the diameter of the opening portion overlapping with the light-receiving element 310 of the light-blocking layer 358 is, the narrower the range of light incident on the light-receiving element 310 becomes. Thus, overlap of image-capturing ranges between a plurality of the light-receiving elements 310 can be inhibited, whereby a clear image with little blurring can be captured.

For example, the area of the opening portion of the light-blocking layer 358 can be less than or equal to 80%, less than or equal to 70%, less than or equal to 60%, less than or equal to 50%, or less than or equal to 40% and greater than or equal to 1%, greater than or equal to 5%, or greater than or equal to 10% of the area of the light-receiving region of the light-receiving element 310. A clearer image can be captured as the area of the opening portion of the light-blocking layer 358 becomes smaller. By contrast, when the area of the opening portion is too small, the amount of light reaching the light-receiving element 310 might be reduced to reduce light sensitivity. Therefore, the area of the opening portion is preferably set within the above-described range. The above upper limits and lower limits can be combined freely. Furthermore, the light-receiving region of the light-receiving element 310 can be referred to as the opening portion of the insulating layer 416.

Note that the center of the opening portion of the light-blocking layer 358 that overlaps with the light-receiving element 310 may be shifted from the center of the light-receiving region of the light-receiving element 310 when seen from above. Moreover, a structure in which the opening portion of the light-blocking layer 358 does not overlap with the light-receiving region of the light-receiving element 310 when seen from above may be employed. Thus, only oblique light that has passed through the opening portion of the light-blocking layer 358 can be received by the light-receiving element 310. Accordingly, the range of light incident on the light-receiving element 310 can be limited more effectively, so that a clear image can be captured.

### Structure Example 2-4

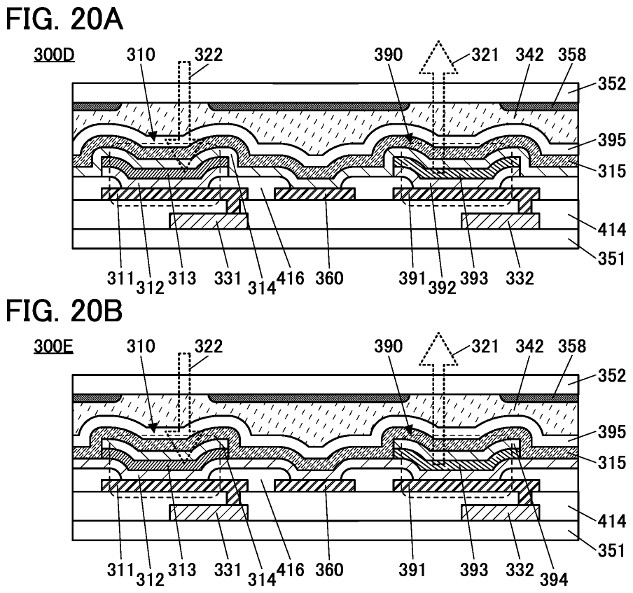

A display apparatus 300D shown in FIG. 20A is different from the display apparatus 300A mainly in that the buffer layer 312 is not a common layer.

The light-receiving element 310 includes the pixel electrode 311, the buffer layer 312, the active layer 313, the buffer layer 314, and the common electrode 315. The light-emitting element 390 includes the pixel electrode 391, a buffer layer 392, the light-emitting layer 393, the buffer layer 314, and the common electrode 315. Each of the active layer 313, the buffer layer 312, the light-emitting layer 393, and the buffer layer 392 has an island-shaped top surface.

The buffer layer 312 and the buffer layer 392 may contain different materials or the same material.

As described above, when the buffer layers are formed separately in the light-emitting element 390 and the light-receiving element 310, the degree of freedom for selecting materials of the buffer layers included in the light-emitting element 390 and the light-receiving element 310 can be increased, which facilitates optimization. In addition, the buffer layer 314 and the common electrode 315 are common layers, whereby the fabrication process can be simplified and manufacturing cost can be reduced as compared to the case where the light-emitting element 390 and the light-receiving element 310 are manufactured separately.

The conductive layer 360 includes a region in contact with the buffer layer 314 in an opening portion of the insulating layer 416. This can block a side leakage current that would flow between the pixel electrode 311 and the pixel electrode 391 through the buffer layer 314.

### Structure Example 2-5

A display apparatus 300E shown in FIG. 20B is different from the display apparatus 300A mainly in that the buffer layer 314 is not a common layer.

The light-receiving element 310 includes the pixel electrode 311, the buffer layer 312, the active layer 313, the buffer layer 314, and the common electrode 315. The light-emitting element 390 includes the pixel electrode 391, the buffer layer 312, the light-emitting layer 393, a buffer layer 394, and the common electrode 315. Each of the active layer 313, the buffer layer 314, the light-emitting layer 393, and the buffer layer 394 has an island-shaped top surface.

The buffer layer 314 and the buffer layer 394 may contain different materials or the same material.

As described above, when the buffer layers are formed separately in the light-emitting element 390 and the light-receiving element 310, the degree of freedom for selecting materials of the buffer layers included in the light-emitting element 390 and the light-receiving element 310 can be increased, which facilitates optimization. In addition, the buffer layer 312 and the common electrode 315 are common layers, whereby the fabrication process can be simplified and manufacturing cost can be reduced as compared to the case where the light-emitting element 390 and the light-receiving element 310 are manufactured separately.

### [Structure Example 3 of Display Apparatus]

A detailed structure of the display apparatus of one embodiment of the present invention will be described below. Here, in particular, an example of the display apparatus including light-emitting/receiving elements and light-emitting elements will be described.

Note that in the description below, the above description is referred to for portions similar to those described above and the portions are not described in some cases.

### Structure Example 3-1

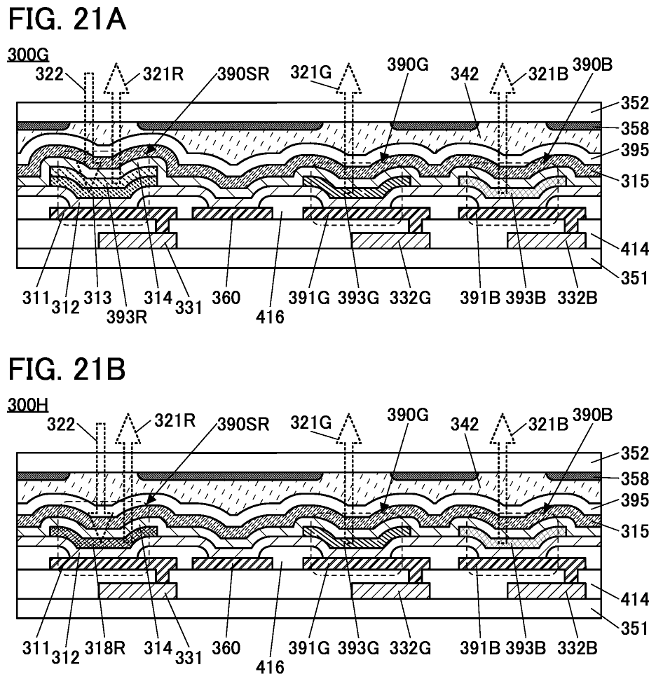

FIG. 21A is a cross-sectional view of a display apparatus 300G. The display apparatus 300G includes a light-emitting/receiving element 390SR, a light-emitting element 390G, a light-emitting element 390B, and a conductive layer 360.

The light-emitting/receiving element 390SR has a function of a light-emitting element that emits red light 321R and a function of a photoelectric conversion element that receives the light 322. The light-emitting element 390G can emit green light 321G. The light-emitting element 390B can emit blue light 321B.

The light-emitting/receiving element 390SR includes the pixel electrode 311, the buffer layer 312, the active layer 313, a light-emitting layer 393R, the buffer layer 314, and the common electrode 315. The light-emitting element 390G includes a pixel electrode 391G, the buffer layer 312, a light-emitting layer 393G, the buffer layer 314, and the common electrode 315. The light-emitting element 390B includes a pixel electrode 391B, the buffer layer 312, a light-emitting layer 393B, the buffer layer 314, and the common electrode 315.

The buffer layer 312, the buffer layer 314, and the common electrode 315 are common layers shared by the light-emitting/receiving element 390SR, the light-emitting element 390G, and the light-emitting element 390B and provided across them. Each of the active layer 313, the light-emitting layer 393R, the light-emitting layer 393G, and the light-emitting layer 393B has an island-shaped top surface. Note that although the stack including the active layer 313 and the light-emitting layer 393R, the light-emitting layer 393G, and the light-emitting layer 393B are provided separately from one another in the example shown in FIG. 21, adjacent two of them may include an overlap region.

Note that as in the case of the display apparatus 300D or the display apparatus 300E, a structure in which one of the buffer layer 312 and the buffer layer 314 is not used as a common layer can be employed.

The pixel electrode 311 is electrically connected to one of the source and the drain of the transistor 331. The pixel electrode 391G is electrically connected to one of a source and a drain of a transistor 332G. The pixel electrode 391B is electrically connected to one of a source and a drain of a transistor 332B.

The conductive layer 360 is positioned between the pixel electrode 391G and the pixel electrode 311 when seen from above. Although not shown, the conductive layer 360 can also be positioned between the pixel electrode 391B and the pixel electrode 311. The conductive layer 360 is formed by processing the same conductive film as one, two, or all of the pixel electrode 311, the pixel electrode 391G, and the pixel electrode 391B.

With such a structure, a display apparatus with higher resolution can be achieved.

### Structure Example 3-2

A display apparatus 300H shown in FIG. 21B is different from the display apparatus 300G mainly in the structure of the light-emitting/receiving element 390SR.

The light-emitting/receiving element 390SR includes a light-emitting/receiving layer 318R instead of the active layer 313 and the light-emitting layer 393R

The light-emitting/receiving layer 318R is a layer that has both a function of a light-emitting layer and a function of an active layer. For example, a layer including the above-described light-emitting substance, an n-type semiconductor, and a p-type semiconductor can be used.

With such a structure, the manufacturing process can be simplified, facilitating cost reduction.

### [Structure Example 4 of Display Apparatus]

A more specific structure of the display apparatus of one embodiment of the present invention will be described below.

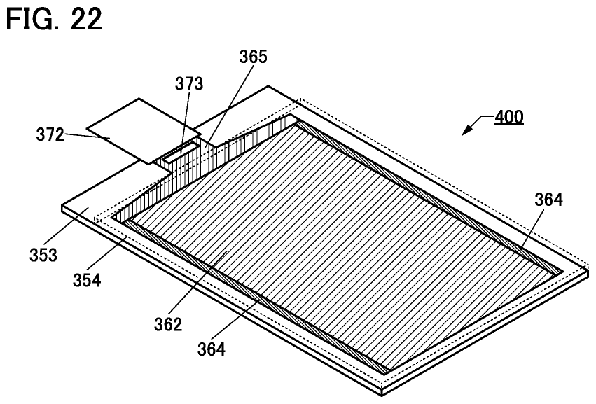

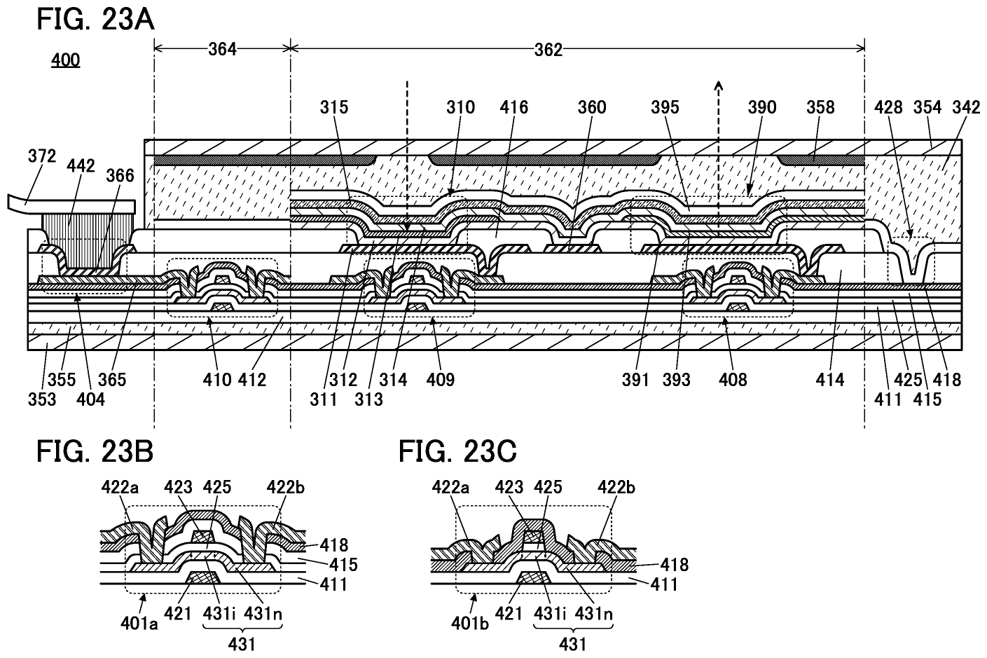

FIG. 22 is a perspective view of a display apparatus 400, and FIG. 23A is a cross-sectional view of the display apparatus 400.

In the display apparatus 400, a substrate 353 and a substrate 354 are bonded to each other. In FIG. 22, the substrate 354 is denoted by a dashed line.

The display apparatus 400 includes a display portion 362, a circuit 364, a wiring 365, and the like. FIG. 22 shows an example in which the display apparatus 400 is provided with an IC (integrated circuit) 373 and an FPC 372. Thus, the structure shown in FIG. 22 can be regarded as a display module including the display apparatus 400, the IC, and the FPC.

As the circuit 364, for example, a scan line driver circuit can be used.

The wiring 365 has a function of supplying a signal and power to the display portion 362 and the circuit 364. The signal and power are input to the wiring 365 from the outside through the FPC 372 or input to the wiring 365 from the IC 373.

FIG. 22 shows an example in which the IC 373 is provided over the substrate 353 by a COG (Chip On Glass) method, a COF (Chip On Film) method, or the like. An IC including a scan line driver circuit, a signal line driver circuit, or the like can be used as the IC 373, for example.

Note that the display apparatus 400 and the display module are not necessarily provided with an IC. The IC may be mounted on the FPC by a COF method or the like.

FIG. 23A shows examples of cross-sections of part of a region including the FPC 372, part of a region including the circuit 364, part of a region including the display portion 362, and part of a region including an end portion of the display apparatus 400 shown in FIG. 22.

The display apparatus 400 shown in FIG. 23A includes a transistor 408, a transistor 409, a transistor 410, the light-emitting element 390, the light-receiving element 310, the conductive layer 360 and the like between the substrate 353 and the substrate 354.

The substrate 354 and the protective layer 395 are bonded to each other with the adhesive layer 342, and a solid sealing structure is used for the display apparatus 400

The substrate 353 and an insulating layer 412 are bonded to each other with an adhesive layer 355.

In a method for manufacturing the display apparatus 400, first, a formation substrate provided with the insulating layer 412, the transistors, the light-receiving element 310, the light-emitting element 390, and the like is bonded to the substrate 354 provided with the light-blocking layer 358 and the like with the adhesive layer 342. Then, with the use of the adhesive layer 355, the substrate 353 is bonded to a surface exposed by separation of the formation substrate, whereby the components formed over the formation substrate are transferred onto the substrate 353. The substrate 353 and the substrate 354 preferably have flexibility. In that case, the flexibility of the display apparatus 400 can be increased.

The light-emitting element 390 has a stacked-layer structure in which the pixel electrode 391, the buffer layer 312, the light-emitting layer 393, the buffer layer 314, and the common electrode 315 are stacked in this order from the insulating layer 414 side. The pixel electrode 391 is electrically connected to one of a source and a drain of in the transistor 408 through an opening provided in the insulating layer 414. The transistor 408 has a function of controlling a current flowing through the light-emitting element 390.

The light-receiving element 310 has a stacked-layer structure in which the pixel electrode 311, the buffer layer 312, the active layer 313, the buffer layer 314, and the common electrode 315 are stacked in this order from the insulating layer 414 side. The pixel electrode 311 is connected to one of a source and a drain of the transistor 409 through an opening provided in the insulating layer 414. The transistor 409 has a function of controlling transfer of charge accumulated in the light-receiving element 310.

Light emitted by the light-emitting element 390 is emitted toward the substrate 354 side. Light is incident on the light-receiving element 310 through the substrate 354 and the adhesive layer 342. For the substrate 354, a material having a high visible-light-transmitting property is preferably used.

The conductive layer 360 is positioned between the pixel electrode 391 and the pixel electrode 311 when seen from above. The conductive layer 360 includes a region in contact with the buffer layer 312 in an opening portion of the insulating layer 416. In addition, in a region not shown, the conductive layer 360 is electrically connected to a wiring to which a predetermined potential is supplied.

The pixel electrode 311, the pixel electrode 391, and the conductive layer 360 can be formed using the same material in the same step. The buffer layer 312, the buffer layer 314, and the common electrode 315 are shared by the light-receiving element 310 and the light-emitting element 390. The light-receiving element 310 and the light-emitting element 390 can have common components except the active layer 313 and the light-emitting layer 393. Thus, the light-receiving element 310 and the conductive layer 360 can be incorporated into the display apparatus 400 without a significant increase in the number of manufacturing steps.

The light-blocking layer 358 is provided on a surface of the substrate 354 on the substrate 353 side. The light-blocking layer 358 includes openings in a position overlapping with the light-emitting element 390 and in a position overlapping with the light-receiving element 310. Providing the light-blocking layer 358 can control the range where the light-receiving element 310 senses light. As described above, it is preferable to control light to be incident on the light-receiving element 310 by adjusting the position and area of the opening of the light-blocking layer provided in the position overlapping with the light-receiving element 310. Furthermore, with the light-blocking layer 358, light can be inhibited from being incident on the light-receiving element 310 directly from the light-emitting element 390 without through an object. Hence, a sensor with less noise and high sensitivity can be achieved.

An end portion of the pixel electrode 311 and an end portion of the pixel electrode 391 are covered with the insulating layer 416. The pixel electrode 311 and the pixel electrode 391 each include a material that reflects visible light, and the common electrode 315 includes a material that transmits visible light.

The transistor 408, the transistor 409, and the transistor 410 are formed over the substrate 353. These transistors can be formed using the same material in the same step.

The insulating layer 412, an insulating layer 411, an insulating layer 425, an insulating layer 415, an insulating layer 418, and the insulating layer 414 are provided in this order over the substrate 353 with the adhesive layer 355 therebetween. Each of the insulating layer 411 and the insulating layer 425 partially functions as a gate insulating layer for the transistors. The insulating layer 415 and the insulating layer 418 are provided to cover the transistors. The insulating layer 414 is provided to cover the transistors and has a function of a planarization layer. Note that the number of gate insulating layers and the number of insulating layers covering the transistors are not limited and may each be one or two or more.

A material through which impurities such as water and hydrogen do not easily diffuse is preferably used for at least one of the insulating layers that covers the transistors. This allows the insulating layer to serve as a barrier layer. Such a structure can effectively inhibit diffusion of impurities into the transistors from the outside and increase the reliability of the display apparatus.

An inorganic insulating film is preferably used as each of the insulating layer 411, the insulating layer 412, the insulating layer 425, the insulating layer 415, and the insulating layer 418. As the inorganic insulating film, a silicon nitride film, a silicon oxynitride film, a silicon oxide film, a silicon nitride oxide film, an aluminum oxide film, or an aluminum nitride film can be used, for example. A hafnium oxide film, a hafnium oxynitride film, a hafnium nitride oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used. A stack including two or more of the above insulating films may also be used.

Here, an organic insulating film often has a lower barrier property than an inorganic insulating film. Therefore, the organic insulating film preferably has an opening in the vicinity of an end portion of the display apparatus 400. In a region 428 shown in FIG. 23A, an opening is formed in the insulating layer 414. This can inhibit entry of impurities from the end portion of the display apparatus 400 through the organic insulating film. Alternatively, the organic insulating film may be formed so that an end portion of the organic insulating film is positioned on the inner side compared to the end portion of the display apparatus 400, to prevent the organic insulating film from being exposed at the end portion of the display apparatus 400.

In the region 428 in the vicinity of the end portion of the display apparatus 400, the insulating layer 418 and the protective layer 395 are preferably in contact with each other through the opening in the insulating layer 414. In particular, the inorganic insulating film included in the insulating layer 418 and the inorganic insulating film included in the protective layer 395 are preferably in contact with each other. Thus, entry of impurities into the display portion 362 from the outside through an organic insulating film can be inhibited. Consequently, the reliability of the display apparatus 400 can be increased.

An organic insulating film is suitable for the insulating layer 414 functioning as a planarization layer. Examples of materials that can be used for the organic insulating film include an acrylic resin, a polyimide resin, an epoxy resin, a polyamide resin, a polyimide-amide resin, a siloxane resin, a benzocyclobutene-based resin, a phenol resin, and precursors of these resins.

Providing the protective layer 395 covering the light-emitting element 390 and the light-receiving element 310 can inhibit impurities such as water from entering the light-emitting element 390 and the light-receiving element 310 and increase the reliability of the light-emitting element 390 and the light-receiving element 310.

The protective layer 395 may have a single-layer structure or a stacked-layer structure. For example, the protective layer 395 may have a stacked-layer structure of an organic insulating film and an inorganic insulating film. In that case, an end portion of the inorganic insulating film preferably extends beyond an end portion of the organic insulating film.

FIG. 23B is a cross-sectional view of a transistor 401a that can be used as the transistor 408, the transistor 409, and the transistor 410.

The transistor 401a is provided over the insulating layer 412 (not shown) and includes a conductive layer 421 functioning as a first gate, the insulating layer 411 functioning as a first gate insulating layer, a semiconductor layer 431, the insulating layer 425 functioning as a second gate insulating layer, and a conductive layer 423 functioning as a second gate. The insulating layer 411 is positioned between the conductive layer 421 and the semiconductor layer 431. The insulating layer 425 is positioned between the conductive layer 423 and the semiconductor layer 431.

The semiconductor layer 431 includes a region 431i and a pair of regions 431n. The region 431i functions as a channel formation region. One of the pair of the regions 431n functions as a source and the other thereof functions as a drain. The regions 431n have higher carrier concentration and higher conductivity than the region 431i. The conductive layer 422a and the conductive layer 422b are connected to the regions 431n through openings provided in the insulating layer 418, the insulating layer 415, and the insulating layer 425.

FIG. 23C is a cross-sectional view of a transistor 401b that can be used as the transistor 408, the transistor 409, and the transistor 410. Furthermore, in the example shown in FIG. 23C, the insulating layer 415 is not provided. In the transistor 401b, the insulating layer 425 is processed in the same manner as the conductive layer 423, and the insulating layer 418 is in contact with the regions 431n.

Note that there is no particular limitation on the structure of the transistors included in the display apparatus of this embodiment. For example, a planar transistor, a staggered transistor, or an inverted staggered transistor can be used. A top-gate or a bottom-gate transistor structure may be employed. Alternatively, gates may be provided above and below a semiconductor layer where a channel is formed.

The structure in which the semiconductor layer where a channel is formed is provided between two gates is used for the transistor 408, the transistor 409, and the transistor 410. The two gates may be connected to each other and supplied with the same signal to drive the transistor. Alternatively, the threshold voltage of the transistor may be controlled by supplying a potential for controlling the threshold voltage to one of the two gates and a potential for driving to the other.

There is no particular limitation on the crystallinity of a semiconductor material used for the transistors; any of an amorphous semiconductor, a single crystal semiconductor, and a semiconductor having crystallinity (a microcrystalline semiconductor, a polycrystalline semiconductor, or a semiconductor partly including crystal regions) may be used. A semiconductor having crystallinity is preferably used, in which case deterioration of the transistor characteristics can be inhibited.

A semiconductor layer of a transistor preferably contains a metal oxide (also referred to as an oxide semiconductor). Alternatively, the semiconductor layer of the transistor may contain silicon. Examples of silicon include amorphous silicon and crystalline silicon (e.g., low-temperature polysilicon or single crystal silicon).

The semiconductor layer preferably contains indium, M (M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, M is preferably one or more kinds selected from aluminum, gallium, yttrium, and tin.

It is particularly preferable to use an oxide containing indium (In), gallium (Ga), and zinc (Zn) (also referred to as IGZO) for the semiconductor layer.

When the semiconductor layer is an In-M-Zn oxide, the atomic ratio of In is preferably greater than or equal to the atomic ratio of M in the In-M-Zn oxide. Examples of the atomic ratio of the metal elements in such an In-M-Zn oxide include In:M:Zn=1:1:1 or a composition in the vicinity thereof, In:M:Zn=1:1:1.2 or a composition in the neighborhood thereof, In:M:Zn=2:1:3 or a composition in the vicinity thereof, In:M:Zn=3:1:2 or a composition in the vicinity thereof, In:M:Zn=4:2:3 or a composition in the vicinity thereof, In:M:Zn=4:2:4.1 or a composition in the vicinity thereof, In:M:Zn=5:1:3 or a composition in the vicinity thereof, In:M:Zn=5:1:6 or a composition in the vicinity thereof, In:M:Zn=5:1:7 or a composition in the vicinity thereof, In:M:Zn=5:1:8 or a composition in the vicinity thereof, In:M:Zn=6:1:6 or a composition in the vicinity thereof, and In:M:Zn=5:2:5 or a composition in the vicinity thereof. Note that a composition in the vicinity includes the range of ±30% of an intended atomic ratio.

For example, in the case where the atomic ratio is described as In:Ga:Zn=4:2:3 or a composition in the vicinity thereof, the case is included where the atomic proportion of Ga is greater than or equal to 1 and less than or equal to 3 and the atomic proportion of Zn is greater than or equal to 2 and less than or equal to 4 with the atomic proportion of In being 4. In the case where the atomic ratio is described as In:Ga:Zn=5:1:6 or a composition in the vicinity thereof, the case is included where the atomic proportion of Ga is greater than 0.1 and less than or equal to 2 and the atomic proportion of Zn is greater than or equal to 5 and less than or equal to 7 with the atomic proportion of In being 5. In the case where the atomic ratio is described as In:Ga:Zn=1:1:1 or a composition in the vicinity thereof, the case is included where the atomic proportion of Ga is greater than 0.1 and less than or equal to 2 and the atomic proportion of Zn is greater than 0.1 and less than or equal to 2 with the atomic proportion of In being 1.

The transistor 410 included in the circuit 364 and the transistor 408 and the transistor 409 included in the display portion 362 may have the same structure or different structures. A plurality of transistors included in the circuit 364 may have the same structure or two or more kinds of structures. Similarly, a plurality of transistors included in the display portion 362 may have the same structure or two or more kinds of structures.

A connection portion 404 is provided in a region of the substrate 353 that does not overlap with the substrate 354. In the connection portion 404, the wiring 365 is electrically connected to the FPC 372 through a conductive layer 366 and a connection layer 442. The conductive layer 366 obtained by processing the same conductive film as the pixel electrode 311 and the pixel electrode 391 is exposed on a top surface of the connection portion 404. Thus, the connection portion 404 and the FPC 372 can be electrically connected to each other through the connection layer 442.

A variety of optical members can be arranged on the outer side of the substrate 354. Examples of the optical members include a polarizing plate, a retardation plate, a light diffusion layer (e.g., a diffusion film), an anti-reflective layer, and a light-condensing film. Furthermore, an antistatic film preventing the attachment of dust, a water repellent film inhibiting the attachment of stain, a hard coat film inhibiting generation of a scratch caused by the use, a shock absorption layer, or the like may be placed on the outer side of the substrate 354.

When a flexible material is used for the substrate 353 and the substrate 354, the flexibility of the display apparatus can be increased. The material is not limited thereto, and glass, quartz, ceramic, sapphire, resin, or the like can be used for each of the substrate 353 and the substrate 354.

For the adhesive layer, a variety of curable adhesives, e.g., a photocurable adhesive such as an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferred. Alternatively, a two-component resin may be used. Alternatively, an adhesive sheet or the like may be used.

As the connection layer, an anisotropic conductive film (ACF), an anisotropic conductive paste (ACP), or the like can be used.

Examples of materials that can be used for a gate, a source, and a drain of a transistor and conductive layers such as a variety of wirings and electrodes included in a display apparatus include metals such as aluminum, titanium, chromium, nickel, copper, yttrium, zirconium, molybdenum, silver, tantalum, and tungsten, and an alloy containing any of these metals as its main component. A film containing any of these materials can be used in a single layer or as a stacked-layer structure.

As a light-transmitting conductive material, a conductive oxide such as indium oxide, indium tin oxide, indium zinc oxide, zinc oxide, or zinc oxide containing gallium, or graphene can be used. Alternatively, a metal material such as gold, silver, platinum, magnesium, nickel, tungsten, chromium, molybdenum, iron, cobalt, copper, palladium, or titanium, an alloy material containing the metal material, or the like can be used. Further alternatively, a nitride of the metal material (e.g., titanium nitride) or the like may be used. Note that in the case of using the metal material or the alloy material (or the nitride thereof), the thickness is preferably set small enough to be able to transmit light. A stacked film of any of the above materials can be used as a conductive layer. For example, a stacked film of indium tin oxide and an alloy of silver and magnesium is preferably used, in which case the conductivity can be increased. These materials can also be used for conductive layers such as a variety of wirings and electrodes that constitute a display apparatus, and conductive layers (conductive layers functioning as a pixel electrode or a common electrode) and the like included in a light-emitting element and a light-receiving element (or a light-emitting/receiving element).

Examples of an insulating material that can be used for each insulating layer include a resin such as an acrylic resin and an epoxy resin, and an inorganic insulating material such as silicon oxide, silicon oxynitride, silicon nitride oxide, silicon nitride, and aluminum oxide.

At least part of this embodiment can be implemented in combination with the other embodiments described in this specification as appropriate.

### Embodiment 3

In this embodiment, a circuit that can be used in the display apparatus of one embodiment of the present invention will be described.

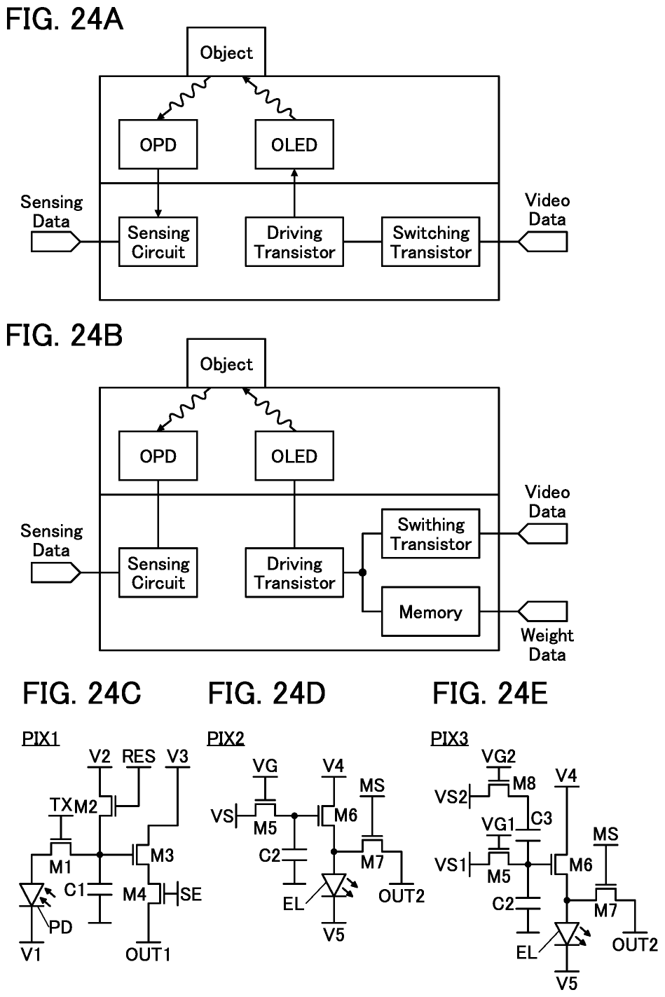

FIG. 24A is a block diagram of a pixel of a display apparatus of one embodiment of the present invention.

The pixel includes an OLED, an OPD (Organic Photo Diode), a sensing circuit (denoted as Sensing Circuit), a driving transistor (denoted as Driving Transistor), and a selection transistor (denoted as Switching Transistor).

Light emitted from the OLED is reflected by an object (denoted as Object), and the reflected light is received by the OPD, whereby an image of the object can be captured. One embodiment of the present invention can function as a touch sensor, an image sensor, an image scanner, and the like. With imaging for a fingerprint, a palm print, a blood vessel (e.g., a vein), or the like, one embodiment of the present invention can be applied to a biometric authentication. Furthermore, an image of a printed matter with a photograph, letters, and the like, or a surface of an article or the like can be captured to be obtained as image information.

The driving transistor and the selection transistor form a driver circuit for driving the OLED. The driving transistor has a function of controlling a current flowing to the OLED, and the OLED can emit light with a luminance according to the current. The selection transistor has a function of controlling selection/non-selection of the pixel. The amount of current flowing to the driving transistor and the OLED is controlled depending on the value (e.g., the voltage value) of video data (denoted as Video Data) that is input from the outside through the selection transistor, whereby the OLED can be emit light with a desired emission luminance.

The sensing circuit corresponds to a driver circuit for controlling the operation of the OPD. The sensing circuit can control operations such as a reset operation for resetting the potential of an electrode of the OPD, a light exposure operation for accumulating charge in the OPD in accordance with the amount of irradiation light, a transfer operation for transferring the charge accumulated in the OPD to a node in the sensing circuit, and a reading operation for outputting a signal (e.g., a voltage or a current) corresponding to the magnitude of the charge, to an external reading circuit as sensing data (denoted as Sensing Data).

A pixel shown in FIG. 24B differs from that described above mainly in including a memory portion (Memory) connected to the driving transistor.

Weight data (Weight Data) is supplied to the memory portion. Data obtained by adding video data input through the selection transistor and the weight data retained in the memory portion is supplied to the driving transistor. With the weight data retained in the memory portion, the luminance of the OLED can be changed from that of the case where only the video data is supplied. Specifically, it is possible to increase or decrease the luminance of the OLED. For example, increasing the luminance of the OLED can increase the light sensitivity of the sensor.

FIG. 24C shows an example of a pixel circuit that can be used for the sensing circuit.

A pixel circuit PIX1 shown in FIG. 24C includes a light-receiving element PD, a transistor M1, a transistor M2, a transistor M3, a transistor M4, and a capacitor C1. Here, an example in which a photodiode is used as the light-receiving element PD is shown.

A cathode of the light-receiving element PD is electrically connected to a wiring V1, and an anode thereof is electrically connected to one of a source and a drain of the transistor M1. A gate of the transistor M1 is electrically connected to a wiring TX, and the other of the source and the drain thereof is electrically connected to one electrode of the capacitor C1, one of a source and a drain of the transistor M2, and a gate of the transistor M3. A gate of the transistor M2 is electrically connected to a wiring RES, and the other of the source and the drain thereof is electrically connected to a wiring V2. One of a source and a drain of the transistor M3 is electrically connected to a wiring V3, and the other of the source and the drain thereof is electrically connected to one of a source and a drain of the transistor M4. A gate of the transistor M4 is electrically connected to a wiring SE, and the other of the source and the drain thereof is electrically connected to a wiring OUT1.

A constant potential is supplied to the wiring V1, the wiring V2, and the wiring V3. When the light-receiving element PD is driven with a reverse bias, a potential lower than the potential of the wiring V1 is supplied to the wiring V2. The transistor M2 is controlled by a signal supplied to the wiring RES and has a function of resetting the potential of a node connected to the gate of the transistor M3 to a potential supplied to the wiring V2. The transistor M1 is controlled by a signal supplied to the wiring TX and has a function of controlling the timing at which the charge accumulated in the light-receiving element PD is transferred to the node. The transistor M3 functions as an amplifier transistor for performing output in response to the potential of the node. The transistor M4 is controlled by a signal supplied to the wiring SE and functions as a selection transistor for reading an output corresponding to the potential of the node by an external circuit connected to the wiring OUT1.

Here, the light-receiving element PD corresponds to the above-described OPD. A potential or a current output from the wiring OUT1 corresponds to the above-described sensing data.

FIG. 24D shows an example of a pixel circuit for driving the above-described OLED.

A pixel circuit PIX2 shown in FIG. 24D includes a light-emitting element EL, a transistor M5, a transistor M6, a transistor M7, and a capacitor C2. Here, an example in which a light-emitting diode is used as the light-emitting element EL is shown. In particular, an organic EL element is preferably used as the light-emitting element EL.

The light-emitting element EL corresponds to the above-described OLED, the transistor M5 corresponds to the above-described selection transistor, and the transistor M6 corresponds to the above-described driving transistor. A wiring VS corresponds to a wiring to which the above-described video data is input.

A gate of the transistor M5 is electrically connected to a wiring VG, one of a source and a drain thereof is electrically connected to a wiring VS, and the other of the source and the drain thereof is electrically connected to one electrode of the capacitor C2 and a gate of the transistor M6. One of a source and a drain of the transistor M6 is electrically connected to a wiring V4, and the other of the source and the drain thereof is electrically connected to an anode of the light-emitting element EL and one of a source and a drain of the transistor M7. A gate of the transistor M7 is electrically connected to a wiring MS, and the other of the source and the drain thereof is electrically connected to a wiring OUT2. A cathode of the light-emitting element EL is electrically connected to a wiring V5.

A constant potential is supplied to the wiring V4 and the wiring V5. In the light-emitting element EL, the anode side can have a high potential and the cathode side can have a lower potential than the anode side. The transistor M5 is controlled by a signal supplied to the wiring VG and functions as a selection transistor for controlling a selection state of the pixel circuit PIX2. The transistor M6 functions as a driving transistor that controls a current flowing through the light-emitting element EL, in accordance with a potential supplied to the gate. When the transistor M5 is in an on state, a potential supplied to the wiring VS is supplied to the gate of the transistor M6, and the emission luminance of the light-emitting element EL can be controlled in accordance with the potential. The transistor M7 is controlled by a signal supplied to the wiring MS and has a function of making the potential between the transistor M6 and the light-emitting element EL a potential to be supplied to the wiring OUT2 and/or a function of outputting the potential between the transistor M6 and the light-emitting element EL to the outside through the wiring OUT2.

FIG. 24E show an example of a pixel circuit provided with a memory portion, which can be applied to the structure shown in FIG. 24B.

A pixel circuit PIX3 shown in FIG. 24E has a structure in which a transistor M8 and a capacitor C3 are added to the pixel circuit PIX2. The wiring VS and the wiring VG in the pixel circuit PIX2 are denoted as a wiring VS1 and a wiring VG1, respectively, in the pixel circuit PIX3.

A gate of the transistor M8 is electrically connected to a wiring VG2, one of a source and a drain of the transistor M8 is electrically connected to a wiring VS2, and the other thereof is electrically connected to one electrode of the capacitor C3. The other electrode of the capacitor C3 is electrically connected to the gate of the transistor M6, one electrode of the capacitor C2, and the other of the source and the drain of the transistor M5.

The wiring VS1 corresponds to the above-described wiring to which the video data is supplied. The wiring VS2 corresponds to a wiring to which the above-described weight data is supplied. A node to which the gate of the transistor M6 is connected corresponds to the above-described memory portion.

An example of a method for operating the pixel circuit PIX3 is described. First, a first potential is written from the wiring VS1 to the node to which the gate of the transistor M6 is connected, through the transistor M5. After that, the transistor M5 is turned off, whereby the node becomes in a floating state. Next, a second potential is written from the wiring VS2 to the one electrode of the capacitor C3 through the transistor M8. Accordingly, the potential of the node changes from the first potential in accordance with the second potential owing to capacitive coupling of the capacitor C3, thereby becoming a third potential. Then, a current corresponding to the third potential flows to the transistor M6 and the light-emitting element EL, whereby the light-emitting element EL emits light with a luminance corresponding to the potential.

Note that in the display apparatus of this embodiment, the light-emitting element may be made to emit light in a pulsed manner so as to display an image. A reduction in the driving time of the light-emitting element can reduce the power consumption of the display panel and suppress heat generation. An organic EL element is particularly preferable because of its favorable frequency characteristics. The frequency can be higher than or equal to 1 kHz and lower than or equal to 100 MHz, for example. Alternatively, a driving method in which the light-emitting element is made to emit light with the pulse width being varied, which is also referred to as Duty driving, may be used.

Here, a transistor including a metal oxide (an oxide semiconductor) in a semiconductor layer where a channels is formed is preferably used as each of the transistor M1, the transistor M2, the transistor M3, and the transistor M4 included in the pixel circuit PIX1, the transistor M5, the transistor M6, and the transistor M7 included in the pixel circuit PIX2, and the transistor M8 included in the pixel circuit PIX3.

Alternatively, a transistor including silicon as a semiconductor where a channel is formed can be used as each of the transistor M1 to the transistor M8. In particular, the use of silicon with high crystallinity, such as single crystal silicon or polycrystalline silicon, is preferable, in which case high field-effect mobility is achieved and higher-speed operation is possible.

Alternatively, a transistor including an oxide semiconductor may be used as one or more of the transistor M1 to the transistor M8, and transistors including silicon may be used as the other transistors.

For example, a transistor that includes an oxide semiconductor and has an extremely low off-state current is preferably used as each of the transistor M1, the transistor M2, the transistor M5, the transistor M7, and the transistor M8 that function as switches for retaining charge. In that case, a transistor including silicon can be used as one or more of the other transistors.

Although n-channel transistors are shown as the transistors in the pixel circuit PIX1, the pixel circuit PIX2, and the pixel circuit PIX3, p-channel transistors can also be used. Alternatively, a structure in which an n-channel transistor and a p-channel transistor are mixed may be employed.

At least part of this embodiment can be implemented in combination with the other embodiments described in this specification as appropriate.

### Embodiment 4

In this embodiment, a metal oxide (also referred to as an oxide semiconductor) that can be used in the transistors described in the above embodiment will be described.

The metal oxide preferably contains at least indium or zinc. In particular, indium and zinc are preferably contained. In addition, aluminum, gallium, yttrium, tin, or the like is preferably contained. Furthermore, one or more kinds selected from boron, silicon, titanium, iron, nickel, germanium, zirconium, molybdenum, lanthanum, cerium, neodymium, hafnium, tantalum, tungsten, magnesium, cobalt, and the like may be contained.

The metal oxide can be formed by a sputtering method, a chemical vapor deposition (CVD) method such as a metal organic chemical vapor deposition (MOCVD) method, an atomic layer deposition (ALD) method, or the like.

### <Classification of Crystal Structures>

Amorphous (including a completely amorphous structure), CAAC (c-axis-aligned crystalline), nc (nanocrystalline), CAC (cloud-aligned composite), single crystal, and polycrystalline (poly crystal) structures can be given as examples of a crystal structure of an oxide semiconductor.

Note that a crystal structure of a film or a substrate can be evaluated with an X-ray diffraction (XRD) spectrum. For example, evaluation is possible using an XRD spectrum obtained by GIXD (Grazing-Incidence XRD) measurement. Note that a GIXD method is also referred to as a thin film method or a Seemann-Bohlin method.

For example, the peak of the XRD spectrum of a quartz glass substrate has a substantially bilaterally symmetrical shape. On the other hand, the peak of the XRD spectrum of an IGZO film having a crystal structure has a bilaterally asymmetrical shape. The asymmetrical peak of the XRD spectrum clearly shows the existence of crystal in the film or the substrate. In other words, the crystal structure of the film or the substrate cannot be regarded as “amorphous” unless it has a bilaterally symmetrical peak in the XRD spectrum.

A crystal structure of a film or a substrate can also be evaluated with a diffraction pattern obtained by a nanobeam electron diffraction method (NBED) (such a pattern is also referred to as a nanobeam electron diffraction pattern). For example, a halo pattern is observed in the diffraction pattern of the quartz glass substrate, which indicates that the quartz glass substrate is in an amorphous state. Furthermore, not a halo pattern but a spot-like pattern is observed in the diffraction pattern of the IGZO film deposited at room temperature. Thus, it is presumed that the IGZO film formed at room temperature is in an intermediate state, which is neither a crystal state nor an amorphous state, and it cannot be concluded that the IGZO film is in an amorphous state.

### <<Structure of Oxide Semiconductor>>

Oxide semiconductors may be classified in a manner different from the above-described one when classified in terms of the structure. Oxide semiconductors are classified into a single crystal oxide semiconductor and a non-single-crystal oxide semiconductor, for example. Examples of the non-single-crystal oxide semiconductor include the above-described CAAC-OS and nc-OS. Other examples of the non-single-crystal oxide semiconductor include a polycrystalline oxide semiconductor, an amorphous-like oxide semiconductor (a-like OS), and an amorphous oxide semiconductor.

Here, the above-described CAAC-OS, nc-OS, and a-like OS are described in detail.

### [CAAC-OS]

The CAAC-OS is an oxide semiconductor that has a plurality of crystal regions each of which has c-axis alignment in a particular direction. Note that the particular direction refers to the film thickness direction of a CAAC-OS film, the normal direction of the surface where the CAAC-OS film is formed, or the normal direction of the surface of the CAAC-OS film. The crystal region refers to a region having a periodic atomic arrangement. When an atomic arrangement is regarded as a lattice arrangement, the crystal region also refers to a region with a uniform lattice arrangement. The CAAC-OS has a region where a plurality of crystal regions are connected in the a-b plane direction, and the region has distortion in some cases. Note that the distortion refers to a portion where the direction of a lattice arrangement changes between a region with a uniform lattice arrangement and another region with a uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions is formed of one or more fine crystals (crystals each of which has a maximum diameter of less than 10 nm). In the case where the crystal region is formed of one fine crystal, the maximum diameter of the crystal region is less than 10 nm. In the case where the crystal region is formed of a large number of fine crystals, the size of the crystal region may be approximately several tens of nanometers.

In the case of an In-M-Zn oxide (the element M is one or more kinds selected from aluminum, gallium, yttrium, tin, titanium, and the like), the CAAC-OS tends to have a layered crystal structure (also referred to as a layered structure) in which a layer containing indium (In) and oxygen (hereinafter, an In layer) and a layer containing the element M, zinc (Zn), and oxygen (hereinafter, an (M,Zn) layer) are stacked. Indium and the element M can be replaced with each other. Therefore, indium may be contained in the (M,Zn) layer. In addition, the element M may be contained in the In layer. Note that Zn may be contained in the In layer. Such a layered structure is observed as a lattice image in a high-resolution TEM (Transmission Electron Microscope) image, for example.

When the CAAC-OS film is subjected to structural analysis by out-of-plane XRD measurement with an XRD apparatus using θ/2θ scanning, for example, a peak indicating c-axis alignment is detected at 2θ of 31° or around 31°. Note that the position of the peak indicating c-axis alignment (the value of 2θ) may change depending on the kind, composition, or the like of the metal element contained in the CAAC-OS.

For example, a plurality of bright spots are observed in the electron diffraction pattern of the CAAC-OS film. Note that one spot and another spot are observed point-symmetrically with a spot of the incident electron beam passing through a sample (also referred to as a direct spot) as the symmetric center.

When the crystal region is observed from the particular direction, a lattice arrangement in the crystal region is basically a hexagonal lattice arrangement; however, a unit lattice is not always a regular hexagon and is a non-regular hexagon in some cases. A pentagonal lattice arrangement, a heptagonal lattice arrangement, and the like are included in the distortion in some cases. Note that a clear crystal grain boundary (grain boundary) cannot be observed even in the vicinity of the distortion in the CAAC-OS. That is, formation of a crystal grain boundary is inhibited by the distortion of lattice arrangement. This is probably because the CAAC-OS can tolerate distortion owing to a low density of arrangement of oxygen atoms in the a-b plane direction, an interatomic bond distance changed by substitution of a metal atom, and the like.

A crystal structure in which a clear crystal grain boundary is observed is what is called polycrystal. It is highly probable that the crystal grain boundary becomes a recombination center and captures carriers and thus decreases the on-state current and field-effect mobility of a transistor, for example. Thus, the CAAC-OS in which no clear crystal grain boundary is observed is one of crystalline oxides having a crystal structure suitable for a semiconductor layer of a transistor. Note that Zn is preferably contained to form the CAAC-OS. For example, an In—Zn oxide and an In—Ga—Zn oxide are suitable because they can inhibit generation of a crystal grain boundary as compared with an In oxide.

The CAAC-OS is an oxide semiconductor with high crystallinity in which no clear crystal grain boundary is observed. Thus, in the CAAC-OS, reduction in electron mobility due to the crystal grain boundary is less likely to occur. Moreover, since the crystallinity of an oxide semiconductor might be decreased by entry of impurities, formation of defects, or the like, the CAAC-OS can be regarded as an oxide semiconductor that has a small amount of impurities and defects (e.g., oxygen vacancies). Thus, an oxide semiconductor including the CAAC-OS is physically stable. Therefore, the oxide semiconductor including the CAAC-OS is resistant to heat and has high reliability. In addition, the CAAC-OS is stable with respect to high temperatures in the manufacturing process (what is called thermal budget). Accordingly, the use of the CAAC-OS for the OS transistor can extend the degree of freedom of the manufacturing process.

[nc-OS]

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a fine crystal. Note that the size of the fine crystal is, for example, greater than or equal to 1 nm and less than or equal to 10 nm, particularly greater than or equal to 1 nm and less than or equal to 3 nm; thus, the fine crystal is also referred to as a nanocrystal. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor by some analysis methods. For example, when an nc-OS film is subjected to structural analysis using out-of-plane XRD measurement with an XRD apparatus using θ/2θ scanning, a peak indicating crystallinity is not detected. Furthermore, a diffraction pattern like a halo pattern is observed when the nc-OS film is subjected to electron diffraction (also referred to as selected-area electron diffraction) using an electron beam with a probe diameter greater than the diameter of a nanocrystal (e.g., greater than or equal to 50 nm). Meanwhile, in some cases, a plurality of spots in a ring-like region with a direct spot as the center are observed in the obtained electron diffraction pattern when the nc-OS film is subjected to electron diffraction (also referred to as nanobeam electron diffraction) using an electron beam with a probe diameter nearly equal to or less than the diameter of a nanocrystal (e.g., greater than or equal to 1 nm and less than or equal to 30 nm).

[a-Like OS]

The a-like OS is an oxide semiconductor having a structure between those of the nc-OS and the amorphous oxide semiconductor. The a-like OS includes a void or a low-density region. That is, the a-like OS has low crystallinity as compared with the nc-OS and the CAAC-OS. Moreover, the a-like OS has higher hydrogen concentration in the film than the nc-OS and the CAAC-OS.

### <<Composition of Oxide Semiconductor>>

Next, the above-described CAC-OS will be described in detail. Note that the CAC-OS relates to the material composition.

### [CAC-OS]

The CAC-OS refers to one composition of a material in which elements constituting a metal oxide are unevenly distributed with a size greater than or equal to 0.5 nm and less than or equal to 10 nm, preferably greater than or equal to 1 nm and less than or equal to 3 nm, or a similar size, for example. Note that a state in which one or more metal elements are unevenly distributed and regions including the metal element(s) are mixed with a size greater than or equal to 0.5 nm and less than or equal to 10 nm, preferably greater than or equal to 1 nm and less than or equal to 3 nm, or a similar size in a metal oxide is hereinafter referred to as a mosaic pattern or a patch-like pattern.

In addition, the CAC-OS has a composition in which materials are separated into a first region and a second region to form a mosaic pattern, and the first regions are distributed in the film (this composition is hereinafter also referred to as a cloud-like composition). That is, the CAC-OS is a composite metal oxide having a composition in which the first regions and the second regions are mixed.

Note that the atomic ratios of In, Ga, and Zn to the metal elements contained in the CAC-OS in an In—Ga—Zn oxide are denoted by [In], [Ga], and [Zn], respectively. For example, the first region in the CAC-OS in the In—Ga—Zn oxide has [In] higher than [In] in the composition of the CAC-OS film. Moreover, the second region has [Ga] higher than [Ga] in the composition of the CAC-OS film. For example, the first region has higher [In] than the second region and has lower [Ga] than the second region. Moreover, the second region has higher [Ga] than the first region and has lower [In] than the first region.

Specifically, the first region includes indium oxide, indium zinc oxide, or the like as its main component. The second region includes gallium oxide, gallium zinc oxide, or the like as its main component. That is, the first region can be referred to as a region containing In as its main component. The second region can be referred to as a region containing Ga as its main component.

Note that a clear boundary between the first region and the second region cannot be observed in some cases.

In a material composition of a CAC-OS in an In—Ga—Zn oxide that contains In, Ga, Zn, and O, regions containing Ga as a main component are observed in part of the CAC-OS and regions containing In as a main component are observed in part thereof. These regions are randomly present to form a mosaic pattern. Thus, it is suggested that the CAC-OS has a structure in which metal elements are unevenly distributed.

The CAC-OS can be formed by a sputtering method under a condition where a substrate is not heated, for example. Moreover, in the case of forming the CAC-OS by a sputtering method, any one or more selected from an inert gas (typically, argon), an oxygen gas, and a nitrogen gas are used as a deposition gas. The ratio of the flow rate of an oxygen gas to the total flow rate of the deposition gas in deposition is preferably as low as possible, and for example, the ratio of the flow rate of an oxygen gas to the total flow rate of the deposition gas in deposition is preferably higher than or equal to 0% and less than 30%, further preferably higher than or equal to 0% and less than or equal to 10%.

For example, energy dispersive X-ray spectroscopy (EDX) is used to obtain EDX mapping, and according to the EDX mapping, the CAC-OS in the In—Ga—Zn oxide has a structure in which the region containing In as its main component (the first region) and the region containing Ga as its main component (the second region) are unevenly distributed and mixed.

Here, the first region has a higher conductivity than the second region. In other words, when carriers flow through the first region, the conductivity of a metal oxide is exhibited. Accordingly, when the first regions are distributed in a metal oxide as a cloud, high field-effect mobility (μ) can be achieved.

The second region has a higher insulating property than the first region. In other words, when the second regions are distributed in a metal oxide, a leakage current can be inhibited.

Thus, in the case where the CAC-OS is used for a transistor, a switching function (on/off switching function) can be given to the CAC-OS owing to the complementary action of the conductivity derived from the first region and the insulating property derived from the second region. That is, the CAC-OS has a conducting function in part of the material and has an insulating function in another part of the material; as a whole, the CAC-OS has a function of a semiconductor. Separation of the conducting function and the insulating function can maximize each function. Accordingly, when the CAC-OS is used for a transistor, high on-state current (Ion), high field-effect mobility (μ), and excellent switching operation can be achieved.

A transistor using a CAC-OS has high reliability. Thus, the CAC-OS is most suitable for a variety of semiconductor devices such as display apparatuses.

An oxide semiconductor has various structures with different properties. Two or more kinds among the amorphous oxide semiconductor, the polycrystalline oxide semiconductor, the a-like OS, the CAC-OS, the nc-OS, and the CAAC-OS may be included in the oxide semiconductor of one embodiment of the present invention.

### <Transistor Including Oxide Semiconductor>

Next, the case where the above oxide semiconductor is used for a transistor will be described.

When the above oxide semiconductor is used for a transistor, a transistor with high field-effect mobility can be achieved. In addition, a transistor having high reliability can be achieved.

An oxide semiconductor having a low carrier concentration is preferably used for the transistor. For example, the carrier concentration of an oxide semiconductor is lower than or equal to 1×10¹⁷ cm⁻³, preferably lower than or equal to 1×10¹⁵ cm⁻³, further preferably lower than or equal to 1×10¹³ cm⁻³, still further preferably lower than or equal to 1×10¹¹ cm⁻³, yet further preferably lower than 1×10¹⁰ cm⁻³ and higher than or equal to 1×10 cm⁻³. In order to reduce the carrier concentration in an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and accordingly has a low density of trap states in some cases.

Electric charge trapped by the trap states in the oxide semiconductor takes a long time to disappear and might behave like fixed electric charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the concentration of impurities in the oxide semiconductor, the concentration of impurities in an adjacent film is also preferably reduced. Examples of impurities include hydrogen, nitrogen, an alkali metal, an alkaline earth metal, iron, nickel, and silicon.

### <Impurity>

Here, the influence of each impurity in the oxide semiconductor is described.

When silicon, carbon, or the like, which is one of Group 14 elements, is contained in the oxide semiconductor, defect states are formed in the oxide semiconductor. Thus, the concentration of silicon or carbon in the oxide semiconductor and the concentration of silicon or carbon in the vicinity of an interface with the oxide semiconductor (the concentration measured by secondary ion mass spectrometry (SIMS)) are lower than or equal to 2×10¹⁸ atoms/cm³, preferably lower than or equal to 2×10¹⁷ atoms/cm³.

When the oxide semiconductor contains an alkali metal or an alkaline earth metal, defect states are formed and carriers are generated in some cases. Accordingly, a transistor including an oxide semiconductor that contains an alkali metal or an alkaline earth metal tends to have normally-on characteristics. Thus, the concentration of an alkali metal or an alkaline earth metal in the oxide semiconductor, which is obtained by SIMS, is lower than or equal to 1×10¹⁸ atoms/cm³, preferably lower than or equal to 2×10¹⁶ atoms/cm³.

Furthermore, when the oxide semiconductor contains nitrogen, the oxide semiconductor easily becomes n-type by generation of electrons serving as carriers and an increase in carrier concentration. As a result, a transistor using an oxide semiconductor containing nitrogen as a semiconductor is likely to have normally-on characteristics. When nitrogen is contained in the oxide semiconductor, a trap state is sometimes formed. This might make the electrical characteristics of the transistor unstable. Thus, the nitrogen concentration in the oxide semiconductor, which is obtained by SIMS, is lower than 5×10¹⁹ atoms/cm³, preferably lower than or equal to 5×10¹⁸ atoms/cm³, further preferably lower than or equal to 1×10¹⁸ atoms/cm³, still further preferably lower than or equal to 5×10¹⁷ atoms/cm³.

Hydrogen contained in the oxide semiconductor reacts with oxygen bonded to a metal atom to be water, and thus causes an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor using an oxide semiconductor containing hydrogen is likely to have normally-on characteristics. For this reason, hydrogen in the oxide semiconductor is preferably reduced as much as possible. Specifically, the hydrogen concentration in the oxide semiconductor, which is obtained by SIMS, is set lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm³.

When an oxide semiconductor with sufficiently reduced impurities is used for the channel formation region of the transistor, stable electrical characteristics can be given.

At least part of this embodiment can be implemented in combination with the other embodiments described in this specification as appropriate.

### Embodiment 5

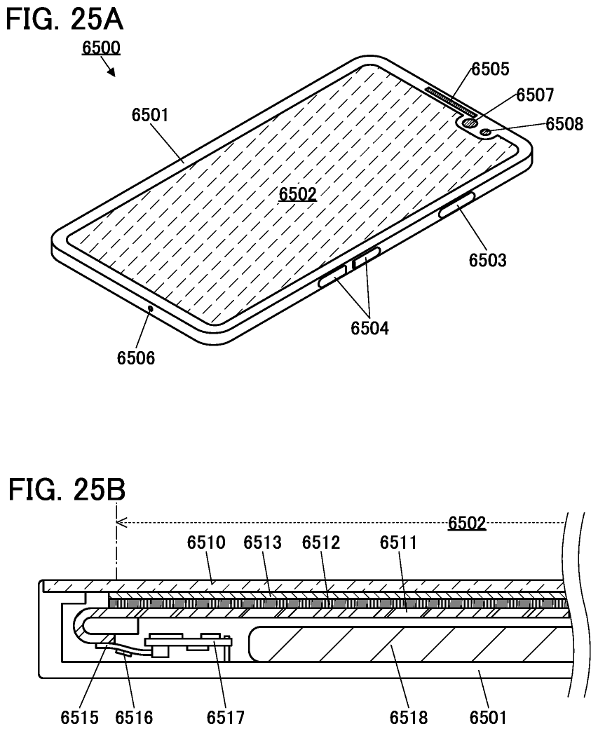

In this embodiment, electronic devices of embodiments of the present invention will be described with reference to FIG. 25 to FIG. 27.

The electronic device of one embodiment of the present invention can capture an image and sense touch operation in a display portion, for example. Consequently, the electronic device can have improved functionality and convenience, for example.

Examples of electronic devices of embodiments of the present invention include a digital camera, a digital video camera, a digital photo frame, a mobile phone, a portable game console, a portable information terminal, and an audio reproducing device, in addition to electronic devices with a relatively large screen, such as a television device, a desktop or laptop personal computer, a monitor of a computer or the like, digital signage, and a large game machine such as a pachinko machine.

The electronic device of one embodiment of the present invention may include a sensor (a sensor having a function of measuring force, displacement, position, speed, acceleration, angular velocity, rotational frequency, distance, light, liquid, magnetism, temperature, a chemical substance, sound, time, hardness, an electric field, current, voltage, power, radioactive rays, flow rate, humidity, a gradient, oscillation, odor, or infrared rays).

The electronic device of one embodiment of the present invention can have a variety of functions. For example, the electronic device can have a function of displaying a variety of data (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

An electronic device 6500 shown in FIG. 25A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display apparatus described in Embodiment 1 or Embodiment 2 can be used in the display portion 6502.

FIG. 25B is a schematic cross-sectional view including an end portion of the housing 6501 on the microphone 6506 side.

A protection member 6510 having a light-transmitting property is provided on the display surface side of the housing 6501, and a display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not shown).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display panel 6511. Thus, an extremely lightweight electronic device can be achieved. Since the display panel 6511 is extremely thin, the battery 6518 with high capacity can be mounted without an increase in the thickness of the electronic device. An electronic device with a narrow frame can be achieved when part of the display panel 6511 is folded back so that the portion connected to the FPC 6515 is provided on the rear side of a pixel portion.

Using the display apparatus described in Embodiment 1 or Embodiment 2 as the display panel 6511 allows imaging on the display portion 6502. For example, an image of a fingerprint is captured by the display panel 6511; thus, fingerprint authentication can be performed.

When the display portion 6502 further includes the touch sensor panel 6513, the display portion 6502 can be provided with a touch panel function. A variety of types such as a capacitive type, a resistive type, a surface acoustic wave type, an infrared type, an optical type, and a pressure-sensitive type can be used for the touch sensor panel 6513. Alternatively, the display panel 6511 may function as a touch sensor; in such a case, the touch sensor panel 6513 is not necessarily provided.

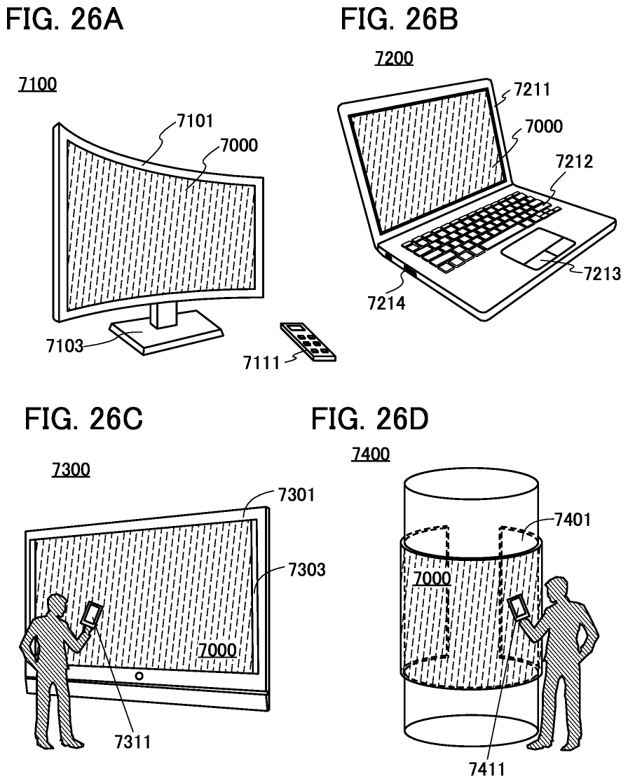

FIG. 26A shows an example of a television device. In a television device 7100, a display portion 7000 is incorporated in a housing 7101. Here, a structure in which the housing 7101 is supported by a stand 7103 is shown.

The display apparatus described in Embodiment 1 or Embodiment 2 can be used in the display portion 7000.

Operation of the television device 7100 shown in FIG. 26A can be performed with an operation switch provided in the housing 7101 or a separate remote controller 7111. Alternatively, the display portion 7000 may include a touch sensor, and the television device 7100 may be operated by a touch on the display portion 7000 with a finger or the like. The remote controller 7111 may include a display portion for displaying information output from the remote controller 7111. With operation keys or a touch panel provided in the remote controller 7111, channels and volume can be controlled, and videos displayed on the display portion 7000 can be controlled.

Note that the television device 7100 is provided with a receiver, a modem, and the like. A general television broadcast can be received with the receiver. When the television device is connected to a communication network with or without wires via the modem, one-way (from a transmitter to a receiver) or two-way (between a transmitter and a receiver or between receivers, for example) data communication can be performed.

FIG. 26B shows an example of a laptop personal computer. A laptop personal computer 7200 includes a housing 7211, a keyboard 7212, a pointing device 7213, an external connection port 7214, and the like. The display portion 7000 is incorporated in the housing 7211.

The display apparatus described in Embodiment 1 or Embodiment 2 can be used in the display portion 7000.

FIG. 26C and FIG. 26D show examples of digital signage.

Digital signage 7300 shown in FIG. 26C includes a housing 7301, the display portion 7000, a speaker 7303, and the like. Furthermore, the digital signage can include an LED lamp, operation keys (including a power switch or an operation switch), a connection terminal, a variety of sensors, a microphone, and the like.

FIG. 26D shows digital signage 7400 attached to a cylindrical pillar 7401. The digital signage 7400 includes the display portion 7000 provided along a curved surface of the pillar 7401.

A larger area of the display portion 7000 can increase the amount of information that can be provided at a time. The larger display portion 7000 attracts more attention, so that the advertising effectiveness can be enhanced, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As shown in FIG. 26C and FIG. 26D, it is preferable that the digital signage 7300 or the digital signage 7400 can work with an information terminal 7311 or an information terminal 7411, such as a smartphone a user has, through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

The display apparatus described in Embodiment 1 or Embodiment 2 can be used in the display portion of the information terminal 7311 or the information terminal 7411 in FIG. 26C and FIG. 26D.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

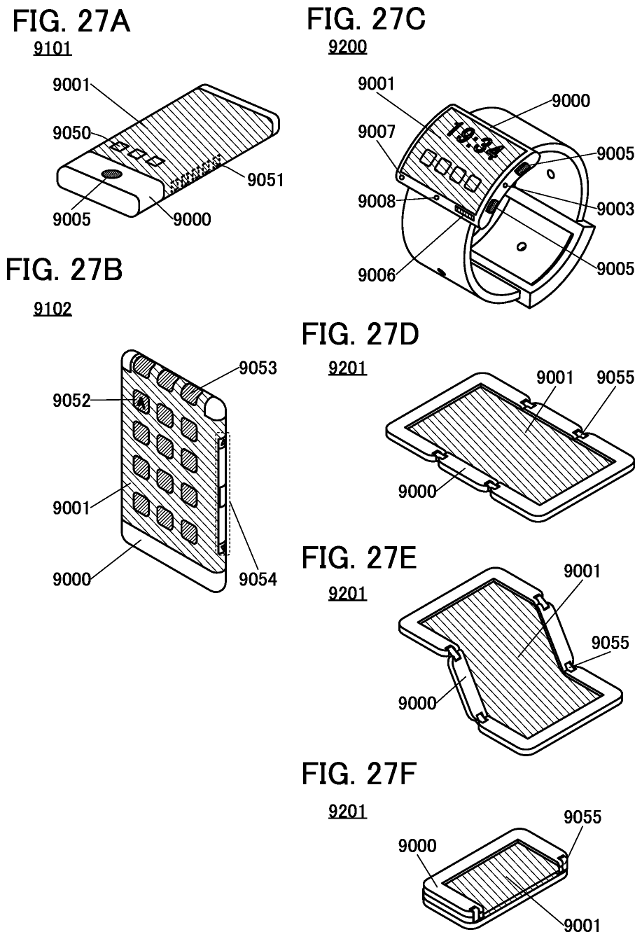

Electronic devices shown in FIG. 27A to FIG. 27F include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

The electronic devices shown in FIG. 27A to FIG. 27F have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may include a plurality of display portions. The electronic devices may each include a camera or the like and have a function of taking a still image or a moving image and storing the captured image in a recording medium (an external recording medium or a recording medium incorporated in the camera), a function of displaying the captured image on the display portion, or the like.

The details of the electronic devices shown in FIG. 27A to FIG. 27F will be described below.

FIG. 27A is a perspective view showing a portable information terminal 9101. The portable information terminal 9101 can be used as a smartphone, for example. Note that the portable information terminal 9101 may be provided with the speaker 9003, the connection terminal 9006, the sensor 9007, or the like. The portable information terminal 9101 can display letters, image information, or the like on its plurality of surfaces. FIG. 27A shows an example in which three icons 9050 are displayed. Information 9051 indicated by dashed rectangles can be displayed on another surface of the display portion 9001. Examples of the information 9051 include notification of reception of an e-mail, SNS, an incoming call, or the like, the title and sender of an e-mail, SNS, or the like, the date, the time, remaining battery, and the reception strength of an antenna. Alternatively, the icon 9050 or the like may be displayed at the position where the information 9051 is displayed.

FIG. 27B is a perspective view showing a portable information terminal 9102. The portable information terminal 9102 has a function of displaying information on three or more surfaces of the display portion 9001. Here, an example in which information 9052, information 9053, and information 9054 are displayed on different surfaces is shown. For example, a user can check the information 9053 displayed at a position that can be observed from above the portable information terminal 9102, with the portable information terminal 9102 put in a breast pocket of his/her clothes. The user can see the display without taking out the portable information terminal 9102 from the pocket and decide whether to answer the call, for example.

FIG. 27C is a perspective view showing a watch-type portable information terminal 9200. The display surface of the display portion 9001 is curved and provided, and display can be performed along the curved display surface. Mutual communication between the portable information terminal 9200 and, for example, a headset capable of wireless communication enables hands-free calling. With the connection terminal 9006, the portable information terminal 9200 can perform mutual data transmission with another information terminal or charging. Note that the charging operation may be performed by wireless power feeding.

FIG. 27D to FIG. 27F are perspective views showing a foldable portable information terminal 9201. FIG. 27D is a perspective view of an opened state of the portable information terminal 9201, FIG. 27F is a perspective view of a folded state thereof, and FIG. 27E is a perspective view of a state in the middle of change from one of FIG. 27D and FIG. 27F to the other. The portable information terminal 9201 is highly portable in the folded state and is highly browsable in the opened state because of a seamless large display region. The display portion 9001 of the portable information terminal 9201 is supported by three housings 9000 joined by hinges 9055. For example, the display portion 9001 can be curved with a radius of curvature greater than or equal to 0.1 mm and less than or equal to 150 mm.

At least part of this embodiment can be implemented in combination with the other embodiments described in this specification as appropriate.

### REFERENCE NUMERALS

10A, 10B, 110A, 110B, 110C, 110D, 110E, 110F, 110G, 110H, 110J, 110K, 110L, 110M, 110N, 110P, 110Q, 110R, 110S, 110T, 110U, 110W: display apparatus, 11, 12: substrate, 13: insulating layer, 14: partition, 20: light-receiving element, 21: light-receiving layer, 30: light-emitting element, 31: light-emitting layer, 40, 40a, 40b, 40X, 40Y: conductive layer, 41, 42: pixel electrode, 50, 50X, 50Y: wiring, 51, 52: transistor, 55: connection portion, 60: common electrode, 61, 62: common layer, 63: protective layer, 80, 90: light, 120: display portion, 121: non-display portion

1. A display apparatus comprising:
a light-receiving element;
a light-emitting element;
a conductive layer; and
a first wiring,
wherein the light-receiving element comprises a first pixel electrode, a common layer over the first pixel electrode, an active layer over the common layer, and a common electrode over the active layer,
wherein the light-emitting element comprises a second pixel electrode, the common layer over the second pixel electrode, a light-emitting layer over the common layer, and the common electrode over the light-emitting layer,
wherein the conductive layer is provided over the same surface as the first pixel electrode and the second pixel electrode, is positioned between the first pixel electrode and the second pixel electrode, is electrically connected to the common layer, and is electrically connected to the first wiring to which a first potential is supplied,
wherein the common layer comprises a portion overlapping with the first pixel electrode, a portion overlapping with the second pixel electrode, and a portion overlapping with the conductive layer,
wherein the common electrode comprises a portion overlapping with the first pixel electrode and a portion overlapping with the second pixel electrode, and
wherein the first wiring is provided over a surface different from the surface where the conductive layer is provided.

2. The display apparatus according to claim 1, further comprising:
a first transistor and a second transistor,
wherein the first pixel electrode is supplied with a second potential lower than or equal to the first potential through the first transistor, and
wherein the second pixel electrode is supplied with a third potential higher than or equal to the first potential through the second transistor.

3. The display apparatus according to claim 1,
wherein the common electrode is supplied with the first potential.

4. The display apparatus according to claim 1, further comprising:
a first transistor and a second transistor,
wherein the first pixel electrode is supplied with a fourth potential higher than or equal to the first potential through the first transistor,
wherein the second pixel electrode is supplied with a fifth potential higher than or equal to the first potential through the second transistor, and
wherein the fifth potential is higher than the fourth potential.

5. The display apparatus according to claim 1,
wherein the conductive layer comprises a first portion with a ring shape, and
wherein the first pixel electrode is positioned inside the first portion when seen from above.

6. The display apparatus according to claim 1,
wherein the conductive layer comprises a first portion with a ring shape, and
wherein the second pixel electrode is positioned inside the first portion when seen from above.

7. The display apparatus according to claim 1, further comprising:
a plurality of the first pixel electrodes and a plurality of the second pixel electrodes,
wherein the conductive layer comprises a first portion with a ring shape, a second portion with a ring shape, and a third portion,
wherein one of the plurality of the first pixel electrodes is positioned inside the first portion when seen from above,
wherein another of the plurality of the first pixel electrodes is positioned inside the second portion when seen from above, and
wherein the third portion is positioned between the first portion and the second portion when seen from above.

8. The display apparatus according to claim 1, further comprising:
a plurality of the first pixel electrodes and a plurality of the second pixel electrodes,
wherein the conductive layer comprises a first portion with a ring shape, a second portion with a ring shape, and a third portion,
wherein one of the plurality of the second pixel electrodes is positioned inside the first portion when seen from above,
wherein another of the plurality of the second pixel electrodes is positioned inside the second portion when seen from above, and
wherein the third portion is positioned between the first portion and the second portion when seen from above.

9. The display apparatus according to claim 1, further comprising:
a plurality of the first pixel electrodes and a plurality of the second pixel electrodes,
wherein the plurality of the first pixel electrodes are arranged in a first direction,
wherein the plurality of the second pixel electrodes are arranged in the first direction, and
wherein the conductive layer is extended in the first direction and comprises portions positioned between the plurality of the first pixel electrodes and the plurality of the second pixel electrodes.

10. The display apparatus according to claim 7, further comprising:
a display region and a non-display region,
wherein the plurality of the first pixel electrodes and the plurality of the second pixel electrodes are provided in the display region,
wherein the conductive layer is provided across the display region and the non-display region, and
wherein the conductive layer is electrically connected to the first wiring in the non-display region.

11. The display apparatus according to claim 10,
wherein the conductive layer is electrically connected to the first wiring in the display region.

12. The display apparatus according to claim 1, further comprising:
a display region and a non-display region,
wherein the first pixel electrode and the second pixel electrode are provided in the display region,
wherein the conductive layer is provided in the display region, and
wherein the conductive layer is electrically connected to the first wiring in the display region.

13. The display apparatus according to claim 11,
wherein the first wiring comprises a portion overlapping with the first pixel electrode and a portion overlapping with the second pixel electrode.

14. The display apparatus according to claim 11,
wherein the first wiring comprises a portion positioned between the first pixel electrode and the second pixel electrode.

15. A display module comprising the display apparatus according to claim 1 to and a connector or an integrated circuit.

16. An electronic device comprising:
the display module according to claim 15; and
at least one of an antenna, a battery, a housing, a camera, a speaker, a microphone, and an operation button.

17. A display apparatus comprising:
a light-receiving element;
a light-emitting element;
a conductive layer;
a first wiring;
a first transistor; and
a second transistor,
wherein the light-receiving element comprises a first pixel electrode, a common layer over the first pixel electrode, an active layer over the common layer, and a common electrode over the active layer,
wherein the light-emitting element comprises a second pixel electrode, the common layer over the second pixel electrode, a light-emitting layer over the common layer, and the common electrode over the light-emitting layer,
wherein the conductive layer is provided over the same surface as the first pixel electrode and the second pixel electrode, is positioned between the first pixel electrode and the second pixel electrode, is electrically connected to the common layer, and is electrically connected to the first wiring to which a first potential is supplied,
wherein the common layer comprises a portion overlapping with the first pixel electrode, a portion overlapping with the second pixel electrode, and a portion overlapping with the conductive layer,
wherein the common electrode comprises a portion overlapping with the first pixel electrode and a portion overlapping with the second pixel electrode,
wherein the first wiring is provided over a surface different from the surface where the conductive layer is provided,
wherein the first pixel electrode is supplied with a second potential lower than or equal to the first potential through the first transistor,
wherein the second pixel electrode is supplied with a third potential higher than or equal to the first potential through the second transistor, and
wherein the common electrode is supplied with the first potential.

18. The display apparatus according to claim 17,
wherein the conductive layer comprises a first portion with a ring shape, and
wherein the first pixel electrode is positioned inside the first portion when seen from above.

19. The display apparatus according to claim 17,
wherein the conductive layer comprises a first portion with a ring shape, and
wherein the second pixel electrode is positioned inside the first portion when seen from above.

20. The display apparatus according to claim 17, further comprising:
a plurality of the first pixel electrodes and a plurality of the second pixel electrodes,
wherein the conductive layer comprises a first portion with a ring shape, a second portion with a ring shape, and a third portion,
wherein one of the plurality of the first pixel electrodes is positioned inside the first portion when seen from above,
wherein another of the plurality of the first pixel electrodes is positioned inside the second portion when seen from above, and
wherein the third portion is positioned between the first portion and the second portion when seen from above.
